(19) United States
(12) Patent Application Publication
(10) Pub. No.: US 2018/0143246 A1
(43) Pub. Date: May 24, 2018

(54) HIGHLY EFFICIENT DOUBLE-SAMPLING ARCHITECTURES

(71) Applicant: Michel NICOLAIDIS, Saint Egrève (FR)

(72) Inventor: Michel NICOLAIDIS, Saint Egrève (FR)

(21) Appl. No.: 15/858,205

(22) Filed: Dec. 29, 2017

Related U.S. Application Data
(63) Continuation of application No. 15/393,035, filed on Dec. 28, 2016, now abandoned.
(60) Provisional application No. 62/271,778, filed on Dec. 28, 2015.

(51) Int. Cl. G01R 31/317; H03K 19/003

(52) U.S. Cl. CPC G01R 31/3172; H03K 19/003; G01R 31/31727; G01R 31/31725; G01R 31/31703

(57) ABSTRACT

Aggressive technology scaling impacts parametric yield, life span, and reliability of circuits fabricated in advanced nanometric nodes. These issues may become showstoppers when scaling deeper to the sub-10 nm domain. To mitigate them various approaches have been proposed including increasing guard-bands, fault-tolerant design, and canary circuits. Each of them is subject to several of the following drawbacks; large area, power, or performance penalty; false positives; false negatives; and in sufficient coverage of the failures encountered in the deep nanometric domain. The invention presents a highly efficient double-sampling architecture, which allow mitigating all these failures at low area and performance penalties, and also enable significant power reduction.

This application is a continuation of U.S. patent application Ser. No. 15/393,035 filed Dec. 28, 2016, which in turn is a non-provisional application of U.S. Provisional Patent Application No. 62/271,778 filed Dec. 28, 2015. The entire disclosures of these applications are incorporated herein by reference.

### BACKGROUND OF THE INVENTION

The present invention relates to double-sampling architectures, which reduces the cost for detecting errors produced by temporary faults, such as delay faults, clock skews, single-event transients (SETs), and single-event upsets (SEUs), by avoiding circuit replication and using instead the comparison of the values present on the outputs of a circuit at two different instants.

### STATE OF THE ART

Aggressive technology scaling has dramatic impact on: process, voltage, and temperature (PVT) variations; circuit aging and wearout induced by failure mechanisms such as NBTI, HCl; clock skews; sensitivity to EMI (e.g. cross-talk and ground bounce); sensitivity to radiation-induced single-event effects (SEUs, SETs); and power dissipation and thermal constraints. The resulting high defect levels affect adversely fabrication yield and reliability.

These problems can be mitigating by using dedicated mechanism able to detect the errors produced by these failure mechanisms. Traditionally this is done by the so-called DMR (double modular redundancy) scheme, which duplicates the operating circuit and compares the outputs of the two copies. However, area and power penalties exceed 100% and are inacceptable for a large majority of applications.

Thus, there is a need for new low-cost error detecting schemes. This goal was accomplished by the double-sampling scheme introduced in [5][6]. Instead of using hardware duplication, this scheme observes at two different instants the outputs of the pipeline stages. Thus, it allows detecting temporary faults (timing faults, transients, upsets) at very low cost.

The implementation of this scheme is shown in FIG. 1. In FIG. 1.a, each output (Out) of the combinational circuit 10 is captured at the rising edge of clock signal Ck by a flip-flop 20 (referred hereafter as regular flip-flop). The output of this flip-flop provides an input to the next pipe-line stage. The detection of temporary faults, is performed by:
Adding a redundant sampling element 22, implemented by a latch or a flip-flop, to each output of the combinational logic;
Clocking the redundant sampling-element by means of a delayed clock signal (Ck+6), which represents the signal Ck delayed by a delay δ.
Using a comparator to check the state of the regular flip-flops against the state of the redundant sampling elements.

If we have to check just one output of the combinational circuit, the comparator in FIG. 1 consists in a two-input XOR gate comparing the outputs of the regular flip-flop and of the redundant sampling element, and providing on its output an error detection signal E.I. On the other had, if we have to check a plurality of outputs of the combinational circuit, the comparator comprises a plurality of XOR gates comparing each a pair of regular flip-flips and redundant sampling element, and of an OR gate (to be referred hereafter as OR-tree because it is usually implemented as a tree of logic gates) receiving on its inputs the outputs of the XOR gates, and providing a single output which compresses the plurality of error detection signals produced by the plurality of the XOR gates into a single global error indication signal E.I., as shown in FIG. 1.b. Note that the comparator can also be implemented by using XNOR gates instead of XOR gates and an AND tree instead of the OR tree; as well as that the OR tree can be implemented by using stages of NOR gates and inverters, or by alternating stages of NOR and NAND gates, and the AND tree can be implemented by using stages of NAND gates and inverters, or alternating stages of NAND and NOR gates. Hereafter, we describe the proposed invention by using as illustration a comparator consisting in a stage of XOR gates and an OR tree. However, those skilled in the art will readily see that all the described embodiments related with the present invention are also compatible with the different other implementations of the comparator.

The efficiency of the double-sampling scheme is demonstrated by numerous studies, including work from ARM and Intel [9][10][13]. In addition to its high efficiency in improving reliability by detecting errors produced by the most prominent failure mechanisms affecting modern technologies (process, voltage, and temperature (PVT) variations; circuit aging and wearout induced by failure mechanisms such as NBTI, HCl; clock skews; sensitivity to EMI like cross-talk and ground bounce; radiation-induced single-event effects like SEUs and SETs), references [9][10] have also demonstrated that the timing-fault detection capabilities of the double-sampling scheme can be used for reducing drastically power dissipation. This is done by reducing aggressively the supply voltage, and using the double sampling scheme to detect the resulting timing faults, and an additional mechanism for correcting them. Thus, the double-sampling scheme is becoming highly efficient in a wide range of application domains, including automotive (mostly for improving reliability), portable devices (mostly for low power purposes), avionics (mostly for improving reliability), and networking (for both improving reliability and reducing power).

Though the double sampling scheme was shown to be a highly efficient scheme in terms of area and power cost and error detection efficiency, and intensive researches were conducted for improving it in both the industry and academia (motivated in particular by the results in [9][10]), there is still space for further improvements. There are three sources of area and power cost in the double-sampling scheme of FIG. 1. The two of them are the redundant sampling element 22, and the comparator 30. The other source of area and power cost is the enforcement of the short path constraint. This constraint imposes the minimum delay of the pipeline stage to be shorter than δ+t_{RSh} (where t_{RSh} is the hold time of the redundant sampling element). This constraint is necessary because the redundant sampling element 22 captures its input at a time δ after the rising edge of the clock signal Ck, and if some circuit path has delay shorter than δ+tₕ, the new values captured at the rising edge of the clock signal Ck by the flip-flops providing inputs to the Combinational Circuit 10, will reach the input of the redundant sampling element before the end of its hold time. Thus, this element will capture data different than those captured by the regular flip-flop and will produce false error detection. Enforcing this constraint will require adding buffers in some short paths to increase their delays at a value larger than δ+tₕ, inducing area and power cost.

The use of redundant sampling elements is one of the two major sources of area cost and more importantly of power cost, as sequential elements are the most power consuming elements of a design. To reduce this cost, [7] proposes a double-sampling implementation in which the redundant sampling element has been eliminated, as shown in FIG. 2.

According to [7], in FIG. 2 the comparator 30 compares the output of the regular flip-flop 20 against its input, and the output of the comparator 30 is latched at the rising edge of a clock signal Ck+δ+Dcomp by an Error Latch 40 rated by this clock signal, where the clock signal Ck+δ+Dcomp is delayed by a time δ+Dcomp with respect to the clock signal Ck rating the regular flip-flop 20. Reference [7], claims that the scheme of FIG. 2 is equivalent to the scheme of FIG. 1, based to the following arguments. The error detection capabilities of this design are justified in [7] in the following manner: Let Dcomp be the delay of the comparator 30, and tᵣ be the instant of the rising edge of the clock signal Ck. Then, as the output value of the comparator is latched by the Error Latch 40 at time tᵣ+δ+Dcomp, this value is the result of the comparison of the values present on the inputs of the comparator at time tᵣ+δ. These values are: on the one hand the content of regular flip-flop 20, which is holding the value present on the output (Out) of the combinational circuit 10 at the instant tᵣ; and on the other hand the value present on the output (Out) of the combinational circuit 10 at the instant tᵣ+δ.

We note that from the above arguments the scheme of FIG. 2 enables detection of timing faults of duration up to δ. However, the analysis in [7] is incomplete, and does not guarantee the system to operate flawlessly. This issue is one of the motivations of the present invention. Also, as illustrated next the architecture of FIG. 2 is non-conventional as it violates a fundamental constraint of synchronous designs. Thus, the timing constraints required for the flawless operation of this architecture cannot be enforced by existing design automation tools. Hence, a second motivation of this invention is to provide in exhaustive manner the timing constraints guarantying its flawless operation. A third motivation is related to the reduction of the implementation cost of the Combinational Circuit 10 and a fourth motivation is the reduction of the delay of the error detection signal. A fifth invention is to provide low cost metastability detection circuitry, and a last motivation is to provide efficient double-sampling implementation for single event upset detection capabilities (SEU) in space applications.

Concerning the generation of the clock signal Ck+δ+Dcomp rating the Error Latch 40, one option is to generate centrally both the Ck and Ck+δ+Dcomp signals by the clock generator circuit and distribute them in the design by independent clock trees. However, employing two clock trees will induce significant area and power cost. Thus, it is most convenient to generate it locally in the Error Latch 40, by adding a delay δ+Dcomp on the clock signal Ck. However, if the delay Dcomp+δ is large, it can be subject to non-negligible variations that may affect flawless operation. Two other implementations for the clock of the Error latch are proposed in [7]. The first implementation uses the falling edge of the clock signal Ck as latching event of the Error latch. However, in this case reference [7] adds on every input of the Comparator 30 coming from the input of a regular flip-flop 20 a delay equal to T_{H}-δ-Dcomp (where T_{H} is the duration of the high level of the clock signal Ck), as described in page 6, first column of reference [7]. The second implementation proposed in [7] uses the rising edge of the clock signal Ck as latching event of the Error latch. In this case it adds on every input of the Comparator 30 coming from the input of a regular flip-flop 20 a delay equal to T_{CK}-δ-Dcomp (where T_{CK} is the period of clock signal Ck), as described in page 6, first column of reference [7]. As the Comparator 30 may check a large number of regular flip-flops, adding such delays will induce significant area and power penalties. Eliminating this cost is the fourth motivation of the present invention.

The double-sampling scheme of FIG. 2 is also considered in [17]. However, for the non-conventional synchronous design of this Fig., the author wrongly sets the short path constraint by means of maximum circuit delays. Indeed, the author in [17] defines this constraint as “Setting deliberately the delay between the flip-flops of pipeline stage i and the error indication flip-flop of stage i+1 larger than the time separating their respective latching instants.”, by using the term “delay”, which, whenever is used without further specification in technical documents, designates the maximum circuit delay. However, the pertinent short-path constraint derived in this invention (see constraint (C) presented later), involves the minimum delays of the Combinational Circuit 10 and the Comparator 30, as well as the hold time of the Error Latch 40.

The implementation of the double-sampling scheme eliminating the redundant sampling element is also presented in [18]. Similarly to FIG. 2, no redundant sampling element is used, and the comparator compares the input and the output of the regular flip-flop. Then, the Error Latch is rated by a clock delayed by a delay τ with respect to the clock signal of the regular flip-flop. Thus, the regular flip-flop is latching its inputs at the rising edge of its clock, and the Error Latch latches the output of the comparator at a time τ later. To guaranty flawless operation of this scheme this reference [18] imposes that the “minimum path delay of the combinational circuit is greater than τ”. Please note that, as this short-path constraint has to be enforced to all paths of the combinational circuit, we need to add buffers in those paths not satisfying it. Then, the higher is the value of τ, the higher is the area and power cost required for enforcing this constraint. As we will show later, the short path constraint imposed by [18] is too strong increasing unnecessary area and power costs. In fact, it is even stronger than the short-path constraint required for the scheme of FIG. 1, as τ accounts for the duration δ of detectable faults, plus the delay Dcomp of the comparator. Thus, relaxing this constraint to, account only for the value of δ, and reduce the related costs, is one of the motivations of the present invention, and then, reducing it further is another motivation. We will also show that, the implementation proposed in [18] does not guarantee flawless operation, as some other constraints concerning long paths are also necessary for guarantying it.

Hence, the existing state of the art specifies the conditions required for the flawless operation of the architecture of FIG. 2 incorrectly and incompletely and can not be used to implement designs operating flawlessly. The major difficulty for specifying correctly these conditions is that this design is non-conventional, because it does not satisfy a fundamental constraint in synchronous designs: the propagation delays between to consecutive pipeline stages should be lesser than the clock period. This invention overcome this problem by means a dedicated analysis of the operation of this design illustrated later in relation with FIG. 7.

### BRIEF DESCRIPTION OF THE DRAWINGS

FIG. 1 illustrates a double-sampling architecture and a comparator implementation.

FIGS. 2 and 3 illustrate a double-sampling architecture where the redundant sampling element has been removed, and the sampling event of the sampling element (Error Latch) that captures the output of the comparator is the rising edge of a delayed version of the circuit clock.

FIG. 4 illustrates a double-sampling architecture where the redundant sampling element has been removed, and the sampling event of the sampling element (Error Latch) that captures the output of the comparator is the rising edge of the circuit clock.

FIG. 5 illustrates a double-sampling architecture where the redundant sampling element has been removed, and the sampling event of the sampling element (Error Latch) that captures the output of the comparator is the falling edge of a delayed version of the circuit clock.

FIG. 6 illustrates a double-sampling architecture where the redundant sampling element has been removed, and the sampling event of the sampling element (Error Latch) that captures the output of the comparator is the falling edge of the circuit clock.

FIG. 7 illustrates the non-conventional operation of the double-sampling architecture where the redundant sampling element has been removed.

FIGS. 8 and 9 illustrate the double-sampling architecture of FIGS. 6 and 4, where a delay is added on the output of the comparator.

FIG. 10 illustrates an implementation of an OR tree using stages of NOR gates and inverters (a), and an implementation of an OR tree using stages of NOR gates NAND gates (b).

FIG. 11 illustrates an implementation of a comparator, which does not use XOR gates.

FIG. 12 illustrates a pipelined implementation of a comparator.

FIG. 13 illustrates the implementation of dynamic XOR and OR gates.

FIG. 14 illustrates the implementation of a) Latch resetting its output when Ck_{d}=0, setting it when Ck_{d}=1 and x=1, and preserving it when Ck_{d}=1 and x=0, b) its truth table; c) Latch setting its output when Ck_{d}=0, resetting it when Ck_{d}=1 and x=0, and preserving it when Ck_{d}=1 and x=1, d) its truth table.

FIG. 15 illustrates an implementation of a comparator, using dynamic XOR gates.

FIG. 16 illustrates an implementation of a comparator, using a stage of dynamic OR gates.

FIG. 17 illustrates the clock signal Ckd used for clocking the dynamic XOR gates of the comparator.

FIG. 18 illustrates the clock signal Ckd used for clocking the dynamic OR or AND gates of the comparator.

FIG. 19 illustrates the OR-tree implementation used in standard double-sampling architectures.

FIG. 20 illustrates improved OR-tree implementation that can be used in double-sampling architectures where the redundant sampling element has been removed.

FIGS. 21 and 22 illustrate implementations mitigating metastability

FIG. 23 illustrates a comparator implemented by a single dynamic gate

FIGS. 24 and 25 illustrate a double-sampling architecture suitable detecting SETs of large duration. Both figures show the same architecture, but in FIG. 24 is missed the circuitry (redundant sampling element and connections to the comparator) checking the regular flip-flops FF1 21

FIG. 26 illustrates the implementation a hazards-blocking static gate using an OR-AND-Invert gate.

FIG. 27 illustrates the double-sampling architecture for latch-based designs using non-overlapping clocks.

### SUMMARY OF THE INVENTION

This Invention presents innovations improving the efficiency of double-sampling architectures in terms of are and power cost, and error detection efficiency. In particularly, it presents:
A double-sampling architecture together with its associated timing constraints and their enforcement procedures, which reduces area and power cost by eliminating the redundant sampling elements.
Unbalanced comparator implementation approach that reduces the number of buffers required for enforcing the short-paths constraints and increases the comparator speed, in double-sampling architectures, which do not use redundant sampling elements.
Architectures accelerating the speed of comparators by introducing hazards-blocking cells.
A generic approach improving the efficiency of double-sampling architectures with respect to single-event upsets, and its specification for several double-sampling architectures.
Low-cost approach for metastability mitigation of error detecting designs. —Cost reduction of latch-based double-sampling architectures targeting delay faults, by reducing the number of latches checked by the double-sampling scheme.

### DETAILED DESCRIPTION OF THE INVENTION

The goal of the present invention is to propose implementations minimizing the cost of the double-sampling scheme of FIG. 2; derive the conditions guarantying its flawless operation; provide a methodology allowing enforcing these conditions by means of manual implementation or for developing dedicated automation tools; implement these constraints conjointly for the combinational circuit and the comparator in a manner that reduces cost and increases speed; propose fast comparator designs by exploiting the specificities of the error detection circuitry; enhance double-sampling to mitigate single-event upsets without increasing cost. In the following, we first present a systematic theory, which is a fundamental support for describing these enhancements. Certain parts of this analysis and some of the related improvements are based on our previous publication [22].

### Elimination of Redundant Sampling Elements and Related Timing Constraints

In the double sampling scheme of FIG. 3, the regular flip-flops 21 20 are rated by the clock signal Ck, and they latch the values present on their inputs at the rising edge of this clock. On the other hand, the Error Latch 40 is rated by the clock signal Ck+τ and latches the value present on its input at the rising edge of this clock signal, which is delayed by a delay τ with respect to the rising edge of the clock signal Ck. Note that, for simplifying the Fig., we show only one input flip-flop FF1 21, and only one output flip-flop FF2 20 of the Combinational Circuit 10. However, the analysis presented next concerns implicitly also the case where the Combinational Circuit 10 has a plurality of input flip-flops FF1 21 and output flip-flops FF2 20, and the Comparator 30 will compare a plurality of pairs coming from the input and the output of the flip-flops FF2 20. Also, it is worth noting that the element referred in FIG. 3 as Error Latch 40, can be realized by a latch or by a flip-flop, which receives on its input D the output of the comparator. What is important is that this element latches at the rising edge of the clock signal Ck+τ the value present on its input D. However, the preferable realization of the Error Latch will use a flip-flop, to avoid propagating the value present on its input to its output before its latching event, which can happen if the Error Latch is realized by a latch, as latches are transparent during their latching event. This is the case not only for the for the Error Latch used in the architecture of FIG. 3, but for the Error Latch used in the other architectures presented in this text We will also see later that, for treating metastability issues, it can be useful realizing the Error Latch by means of a reset-dominant latch, and also using dynamic gates in the implementation of the comparator.

To analyze the operation of the scheme of FIG. 3, we need to consider the duration δ of detectable faults; the period T_{CK} of the clock signals Ck and Ck+τ; the maximum Ck-to-Q propagation delay D_{FFmax} of the regular flip-flops 20 21; the setup time t_{ELsu} and the hold time t_{ELh} of the Error Latch 40; the minimum delay Dmin of signal propagation through a regular flip-flop FF1 21 and the Combinational Circuit 10 (i.e. sum of the minimum Clk-to-Q delay D_{FFmin} of the regular flip-flop FF1 21 plus the minimum delay of the combinational circuit 10); and the maximum delay Dmax of signal propagation through the regular flip-flop FF1 21 and the Combinational Circuit 10 (i.e. the maximum Clk-to-Q delay D_{FFmax} of the regular flip-flop FF1 21 plus the maximum delay of the combinational circuit 10). We also have to consider the delay of the comparator. In [7], the delay of the comparator is considered constant for all paths, and in case the OR tree is asymmetric (i.e. having paths of different lengths) it adds delays in some paths to balance them and have equal delays for all paths. In this invention using OR-trees with balanced delays is one of the possible options. However, even if all paths of the OR-tree are balanced, their delays are not all the time identical, as the low-to-high and high-to-low transitions of the same logic gate are generally different. Also, different routings may modify the delay of the different paths. Then, the maximum and minimum delays of the Comparator 30 for all these paths will be designated as D_{CMPmax} and D_{CMPmin}.

In FIG. 3, let D_{CMPmini} and D_{CMPmaxi} be the minimum and the maximum delay of the path of the Comparator 30 connecting the input of the ith flip-flop FF2 20 to the input of the Error Latch 40. Also, let D_{CCmini} be the minimum delay and D_{CCmaxi} the maximum delay of the paths connecting the outputs of the regular flip flops FF1 21 to the input of the ith regular flip flop FF2 20. We set Dmini=D_{FFmin}+D_{CCmini}, and Dmaxi=D_{FFmax}+D_{CCmaxi}. Then, (Dₘᵢₙᵢ+D_{CMPmini})ₘᵢₙ will designate the minimum value of the sum Dₘᵢₙᵢ+D_{CMPmini}, and (Dₘₐₓᵢ+D_{CMPmaxi})ₘₐₓ will designate the maximum value of the sum Dₘₐₓᵢ+D_{CMPmaxi}, for the set of regular flip-flops FF2 20 checked by the Comparator 30.

Before analyzing the operation of the architecture of FIG. 3, let us note that, two values of τ differing by a multiple of T_{CK} give the same clock signal Ck+τ (i.e. n cycles after Ck is activated, the rising and falling edges of two clock signals Ck+τ and Ck+τ′, with τ′=τ+nT_{CK}, will always coincide). Thus, we only need considering values of τ in the interval 0≤τ≤T_{CK}.

The double-sampling scheme of FIG. 3 is composed of several elements (flip-flops FF1 21, Combinational Circuit 10, and flip-flops FF2 20) constituting a standard synchronous design (functional part); plus some elements (Comparator 30 and Error Latch 40), constituting the error detection circuitry of the double-sampling scheme. For the standard synchronous-design part of FIG. 3, we consider that the conditions necessary for achieving flawless operation in standard synchronous designs (i.e. the condition Dmax<T_{CK} necessary for avoiding setup time violations and the condition Dmin>t_{FFh} necessary for avoiding hold time violations for the regular flip-flops 2120, where t_{FFh} is the hold time of these flip-flops), are enforced similarly to any synchronous design. Thus, in the following we derive the conditions necessary to enforce the flawless operation for the error detection circuitry of FIG. 3.

Let D1ᵢ be the data captured by the regular flip-flops FF1 21 at the rising edge of cycle i of clock signal Ck. Let D2ᵢ₊₁ be the data applied at the inputs of the regular flip-flops FF2 20 as the result of the propagation of the data D1ᵢ through the combinational circuit 10 when sufficient time is done to this propagation, and D2′ᵢ₊₁ be the data captured by the regular flip-flops FF2 20 at the rising edge of cycle i+1 of clock signal Ck. In correct operation we will have D2′ᵢ₊₁=D2ᵢ₊₁.

The rising edge of the clock signal Ck+τ at which the Error Latch 40 will latch the result of the comparison of D2ᵢ₊₁ against D2′ᵢ₊₁ is determined by the temporal characteristic of the design. When the conditions (A) and (B) derived bellow are satisfied, the Error Latch 40 will capture the result of the comparison of D2ᵢ₊₁ against D2′ᵢ₊₁, at a latching instant t_{ELk}, which: for the case 0<τ<T_{CK}, is the k-th rising edge of the clock signal Ck+τ that follows the rising edge of cycle i+1 of Ck; and for the case τ=0, is the k-th rising edge of the clock signal Ck (as Ck+τ coincides with Ck for τ=0) that follows the rising edge of cycle i of Ck (where k can take values≥1 in the case 0<τ<T_{CK}, and values≥2 in the case τ=0). This way to define t_{ELk} and k allows for both these cases to use the same relation (t_{ELk}=tᵣᵢ₊₁+(k−1)T_{CK}+τ) for expressing the instant t_{ELk} with respect to the instant tᵣᵢ₊₁ of the rising edge of clock signal Ck at cycle i+1.

To avoid setup time violations for the Error Latch 40 we find:
A. Data latched by FF1 21 at the rising edge of cycle i of the clock signal Ck, should reach the Error Latch 40 earlier than a time interval t_{ELsu} before the instant t_{ELk}
B. Data latched by FF2 20 at the rising edge of clock cycle i+1, should reach the Error Latch 40 earlier than a time t_{ELsu} before the instant t_{ELk}.

Using the relation t_{ELk}=tᵣᵢ₊₁+(k−1)T_{CK}+τ given above for both cases 0<τ<T_{CK} and τ=0, conditions A and B can be written for both these cases as:

(Dₘₐₓᵢ+D_{CMPmaxi})max<kT_{CK}+τ−t_{ELsu} (A)

D_{FFmax}+D_{CMPmax}<(k−1)T_{CK}+τ−t_{ELsu} (B)

Furthermore, to avoid hold time violations, data captured by FF2 20 at the rising edge of clock cycle i+1 should not reach the input of the Error Latch 40 before the end of its hold time related to the k-th rising edge of clock signal Ck+τ that follows the rising edge of cycle i+1 of Ck. Using the relation t_{ELk}=tᵣᵢ₊₁+(k−1)T_{CK}+τ given above for both cases 0<τ<T_{CK} and τ=0, this condition can be written for both these cases as:

(Dₘᵢₙᵢ+D_{CMPmini})ₘᵢₙ>(k−1)T_{CK}+τ+t_{ELh} (C)

Note that the inequalities in relations (A) and (B) are required in order to provide some margin M_{EARLY} that can be set by the designer to account for clock skews and jitter, which may reduce the time separating the rising edge of clock signal Ck+τ from the rising edge of the clock signal Ck sampling some regular flip-flop checked by the double sampling scheme. For instance, considering this margin, relations (B) becomes:

D_{FFmax}+D_{CMPmax}+M_{EARLY}=(k−1)T_{CK}+τ−t_{ELsu} (B′)

Similarly, the inequality in relation (C) is required in order to provide some margin M_{LATE} that can be set by the designer to account for clock skews and jitter, which may increase the time separating the rising edge of clock signal Ck+τ from the rising edge of the clock signal Ck sampling some regular flip-flop checked by the double sampling scheme. Considering this margin, relations (C) becomes:

(Dₘᵢₙᵢ+D_{CMPmini})ₘᵢₙ+M_{LATE}=(k−1)T_{CK}+τ+t_{ELh} (C′)

In the similar manner, inequality (D) derived next will also account for a margin M_{LATE}. Furthermore, the various inequalities used hereafter, for specifying relations (A), (B), (C) and (D) in various circuit cases, account for the same margins, and can be transformed similarly into equations by using them.

Avoiding hold time violations will also require that data captured by FF2 20 at the rising edge of clock cycle i+2 do not reach the input of the Error Latch 40 before the end of its hold time related to the latching instant t_{ELk} of the Error Latch 40. Thus, we obtain D_{FFmin}+D_{CMPmin}>t_{ELk}+t_{ELh}−tᵣᵢ₊₂, where tᵣᵢ₊₂ is the instant of the rising edge of cycle i+2 of the clock signal Ck. Using the relation t_{ELk}=tᵣᵢ₊₁+(k−1)T_{CK}+τ, given above for both cases 0<τ<T_{CK} and τ=0, this condition can be written for both these cases as:

D_{FFmin}+D_{CMPmin}>(k−2)T_{CK}+τ+t_{ELh} (D)

### Justification of Non-Conventional Operation

The double-sampling architecture described in this invention are non conventional, as the delay of the path connecting flip-flops FF1 21 to the Error Latch 40 through the Combinational Circuit 10 and the Comparator 30 is larger than the time separating two consecutive latching edges of the clock signals Ck and Ck+τ that rate the flip-flops FF1 21 and the Error Latch 40. Thus, it violates a fundamental rule of synchronous design, and could be thought that they do not operate properly. To illustrate that the conditions (A), (B), (C), (D), ensure the proper operation of this architecture, let us consider as illustration example the implementation of FIG. 4 corresponding to the case k=2, and τ=0. The proper operation of the other cases can be illustrated similarly. To simplify the illustration, we will to reduce the number of the considered parameters. Thus, for constraint (A) we will use the relation Dmax+D_{CMPmax}<2T_{CK}−t_{ELs} instead of (Dₘₐₓᵢ+D_{CMPmaxi})ₘₐₓ<2T_{CK}−t_{ELsu}, and for constraint (C) we will use the relation Dmin+D_{CMPmin}>T_{CK}+t_{EL} instead of (Dₘᵢₙᵢ+D_{CMPmini})ₘᵢₙ>T_{CK}+t_{ELh}. Those skilled in the art will readily understand that the illustration principles used for these simplified constraints, can also be used to illustrate the flawless operation for the constraints (Dₘₐₓᵢ+D_{CMPmaxi})ₘₐₓ<2T_{CK}−t_{ELsu} and (Dₘᵢₙᵢ+D_{CMPmini})ₘᵢₙ>T_{CK}+t_{ELh}.

Then, for the case τ=0 and k=2, shown in the architecture of FIG. 4, we obtain:

Dmax+D_{CMPmax}<2T_{CK}−t_{ELsu} (A.s)

D_{FFmax}+D_{CMPmax}<T_{CK}−t_{ELsu} (B.s)

Dmin+D_{CMPmin}>T_{CK}+t_{ELh} (C.s)

D_{FFmin}+D_{CMPmin}>t_{ELh} (D.s)

In the architecture of FIG. 4, the regular flip-flops FF1 21 and to the Error Latch 40 are both rated by the clock signal Ck. We also consider that the period of the clock signal Ck is set to accommodate the sum Dmax of the maximum delay of a regular flip-flop FF1 21 and the Combinational Circuit 10. Thus, the maximum delay Dmax+D_{CMPmax} of the path connecting the inputs of flip-flops FF1 21 to the Error Latch 40 through the Combinational Circuit 10 and the Comparator 30 is larger than the period of this clock signal. Hence, this architecture violates a fundamental rule of synchronous design, and could be thought that it does not operate properly. However, we will show that constraints (A.s), (B.s), (C.s) and (D.s), guaranty its flawless operation.

Let us consider three clock cycles i, i+1, and i+2. Let us refer as “green” values G1 the data captured in FIG. 4 by flip-flops FF1 21 at the rising edge of clock cycle i (instant tᵣᵢ). The propagation of these values is illustrated in FIG. 7 by green-colored lines. At a time Dmin after tᵣᵢ, the propagation of the “green” values G1 through the Combinational Circuit 10 can reach some inputs of the flip-flops FF2 20 through short-paths, but the input values of these flip-flops are not yet stabilized. Then, at instant tᵣᵢ+Dmax the outputs of the Combinational Circuit 10 are stabilized resulting on the values referred hereafter as “green” values G2. These values will remain stable until the instant at which the new values (illustrated in FIG. 7 by red colored lines) captured by flip-flops FF1 21 at the rising edge of clock cycle i+1 (instant tᵣᵢ₊₁) start to influence the Combinational Circuit 10. This will happen at a time Dmin after tᵣᵢ₊₁. Thus, the propagation of the “green” values G1 creates stable values (“green” values G2) on the inputs of flip-flops FF2 20 in the time interval [tᵣᵢ+Dmax, tᵣᵢ₊₁+Dmin] (shown by a green-colored rectangle (100) in FIG. 7). This stability is due to the fact that, as mentioned earlier, the standard synchronous-design part in FIG. 3 (and in FIG. 4), satisfies the standard setup and hold time constraints of flip-flops FF2 20, as required in standard synchronous designs. Thus, the stable “green” values G2 will be captured by flip-flops FF2 20 at instant tᵣᵢ₊₁ and will reach their outputs no later than the instant tᵣᵢ₊₁+D_{FFmax}. These values will remain stable on the outputs of flip-flops FF2 20 until the instant these flip-flops will capture new values. That is, until the instant tᵣᵢ₊₂+D_{FFmin}, where tᵣᵢ₊₂ is the instant of the rising edge of Ck in the clock cycle i+2. Thus, during the interval [tᵣᵢ₊₁+D_{FFmax}, tᵣᵢ₊₂+D_{FFmin}] (shown by the green-colored rectangle 101 in FIG. 7) the “green” values G2 are also stable on the outputs of FF2 20. Furthermore:
As tᵣᵢ₊₂−tᵣᵢ₊₁−T_{CK}, (B.s) gives

tᵣᵢ₊₁+D_{FFmax}<tᵣᵢ₊₂−D_{CMPmax}−t_{ELsu} (i)
As tᵣᵢ₊₂−tᵣᵢ=2T_{CK}, (A.s) gives

tᵣᵢ+Dₘₐₓ<tᵣᵢ₊₂−D_{CMPmax}−t_{ELsu} (ii)
As tᵣᵢ₊₂−tᵣᵢ₊₁−T_{CK}, (C.s) gives

tᵣᵢ₊₁+Dmin>tᵣᵢ₊₂−D_{CMPmin}+t_{ELh} (iii)
(D.s) trivially implies

tᵣᵢ₊₂+D_{FFmin}>tᵣᵢ₊₂−D_{CMPmin}+t_{ELh} (iv)

The outcome of the above analysis is that: the “green” values G2, coming from the propagation of the “green” values G1 captured by flip-flops FF1 21 at the rising edge of clock cycle i (instant tᵣᵢ), are stable on the inputs of flip-flops FF2 20 during the time interval [tᵣᵢ+Dmax, tᵣᵢ₊₁+Dmin] shown by the green-colored rectangle 100 in FIG. 7; these values G2 are also stable on the outputs of flip-flops FF2 20 during the time interval [tᵣᵢ₊₁+D_{FFmax}, tᵣᵢ₊₂+D_{FFmin}], shown by the green-colored rectangle 101 in FIG. 7. Then, relations (i), (ii), (iii), and (iv) imply that the time interval [tᵣᵢ₊₂−D_{CMPmax}−t_{ELsu}, tᵣᵢ₊₂−D_{CMPmin}+t_{ELh}] is within both these intervals, which further implies that:
During the time interval [tᵣᵢ₊₂−D_{CMPmax}−t_{ELsu}, tᵣᵢ₊₂−D_{CMPmin}+t_{ELh}] the “green” values G2, coming from the propagation of the “green” G1 captured by flip-flops FF1 21 at the rising edge of clock cycle i, are stable on the inputs and the outputs of flip-flops FF2 20 (which by the way are the inputs of the comparator). Thus, the Comparator 30 compares these equal values and provides the result on the input of the Error Latch 40.
As the maximum delay of the Comparator is D_{CMPmax}, relations (i) and (ii) imply that the result of this comparison is ready on the output of the comparator before the instant tᵣᵢ₊₂−t_{ELsu}, which satisfies the setup-time constraint of the Error Latch 40.
As the minimum delay of the comparator is D_{CMPmin}, relations (iii) and (iv) imply that the result of this comparison is guaranteed to be stable on the output of the comparator until some time after tᵣᵢ₊₂+t_{ELh}, which satisfies the hold-time constraint of the Error Latch 40.

The above imply that the Error Latch 40 will capture, at the rising edge of clock cycle i+2, the valid results of the comparison of the inputs and outputs of flip-flops FF2 20, resulting from the propagation of the data captured by FF1 21 at the rising edge of clock cycle i. Consequently the non-conventional architecture of FIG. 4 works properly.

### Duration of Detectable Faults

As specified earlier, in FIG. 3 the data captured by the flip-flops FF2 20 at the rising edge of cycle i+1 (instant tᵣᵢ₊₁) of the clock signal Ck, are checked by the comparator and the result of the comparison is captured by the Error Latch 40 at the instant t_{ELk}. An output signal of the combinational circuit 20, which is ready no later than tᵣᵢ₊₁−t_{FFsu} (where t_{FFsu} is the setup time of the regular flip-flops FF2 20), does not induce errors in these regular flip-flops. We want to determine the maximum duration of delay faults (i.e. the maximum time δ after the instant tᵣᵢ₊₁−t_{FFsu} that an output signal of the combinational circuit 20 should be ready in order for the fault to be detected), that is guaranteed to be detected by the double sampling scheme of FIG. 3. In order for a faulty value latched by a regular flip-flop FF2 20 at the rising edge of Ck to be detected, the propagation through the comparator of the correct value established later in the input of this flip-flop should reach the output of the comparator no later than the instant t_{ELk}−t_{ELsu}. Thus we obtain tᵣᵢ₊₁−t_{FFsu}+δ+D_{CMP(Error!->Error)max}=t_{ELk}−t_{ELsu}. Note that, as this relation concerns the activation of the error detection state on the output of the comparator, we have to use the maximum delay of the propagation through the comparator of the non-error state to the error transition (i.e. Error!->Error). Thus, we use the delay D_{CMP(Error!->Error)max} instead of D_{CMPmax}. From the specifications of t_{ELk} and k given earlier, for both cases τ=0 and 0<τ<T_{CK} we have t_{ELk}−tᵣᵢ₊₁=τ+(k−1)T_{CK}.

Thus, for both these cases we obtain

δ=(k−1)T_{CK}+τ−D_{CMP(Error!->Error)max}+(t_{FFsu}−t_{ELsu}) (E)

Note also that, a transient which is present on the input of the flip-flop at the instant tᵣᵢ₊₁−t_{FFsu} will induce an error at this flip-flop, but it is guaranteed to be detected if it is no still present at the instant t_{ELk}−t_{ELsu}−D_{CMP(Error!->Error)max}. Thus, any SET (single event transient) whose duration does not exceed the value (t_{ELk}−t_{ELsu}−D_{CMP(Error!->Error)max)}−(tᵣᵢ₊₁−t_{FFsu})=(k−1)T_{CK}+τ−D_{CMP(Error!->Error)max}+(t_{FFsu}−t_{ELsu}) is guaranteed to be detected. Therefore, the duration d of SETs that are guaranteed to be detected is also given by (E).

### Instantiation of Constraints (A), (B), (C), (D), and (E)

Conditions (A) and (B) are the long-path constraints and condition (C) and (D) are the short-path constraints, which guaranty the flawless operation of the double-sampling scheme of FIG. 3. In addition, condition (E) gives the duration of detectable faults. These conditions are generic (are given for any integer value k≥1, and any real value τ in the interval 0<τ<T_{CK}), and can be instantiated to few cases of practical interest.

For k=1 we obtain:

(Dₘₐₓᵢ+D_{CMPmaxi})max<T_{CK}+τ−t_{ELsu} (A1)

D_{FFmax}+D_{CMPmax}<τ−t_{ELsu} (B1)

(Dₘᵢₙᵢ+D_{CMPmini})ₘᵢₙ>τ+t_{ELh} (C1)

D_{FFmin}+D_{CMPmin}>−T_{CK}+τ+t_{ELh} (D1)

δ=τ−D_{CMP(Error!->Error)max}+(t_{FFsu}−t_{ELsu}) (E1)

Note that, as specified earlier, k takes values≥1 in the case 0<τ<T_{CK}, and values≥2 in the case τ=0. Thus, the case k=1 and τ=0 cannot exist.

For k=2 and 0<τ<T_{CK}, we obtain:

(Dₘₐₓᵢ+D_{CMPmaxi})ₘₐₓ<2T_{CK}+τ−t_{ELsu} (A2)

D_{FFmax}+D_{CMPmax}<T_{CK}+τ−t_{ELsu} (B2)

(Dₘᵢₙᵢ+D_{CMPmini})ₘᵢₙ>T_{CK}+τ+t_{ELh} (C2)

D_{FFmin}+D_{CMPmin}>τ+t_{ELh} (D2)

δ=T_{CK}+τ−D_{CMP(Error!->Error)max}+(t_{FFsu}−t_{ELsu}) (E2)

For k=2 and τ=0 we obtain:

(Dₘₐₓᵢ+D_{CMPmaxi})ₘₐₓ<2T_{CK}−t_{ELsu} (A3)

D_{FFmax}+D_{CMPmax}<T_{CK}−t_{ELsu} (B3)

(Dₘᵢₙᵢ+D_{CMPmini})ₘᵢₙ>T_{CK}+t_{ELh} (C3)

D_{FFmin}+D_{CMPmin}>t_{ELh} (D3)

δ=T_{CK}−D_{CMP(Error!->Error)max}+(t_{FFsu}−t_{ELsu}) (E3)

In the case k=1 (corresponding to the conditions (A1), (B1), (C1)), the clock signal of the Error Latch 40 will be realized by adding a delay τ on the clock signal Ck. The similar implementation using this realization of the clock signal for the Error Latch was proposed in reference [7] and later in reference [18]. However, reference [7] does not assure flawless operation as it does not provides these conditions. Also, as mentioned earlier, reference [7] adds unnecessary delays on every input of the Comparator 30 coming from the input of a regular flip-flop. On the other hand, reference [18] provides the short-path constraint Dₘᵢₙ=τ instead of the short path constraint (C1) (see paragraph [0083] in [18]: “Also in the embodiment referred to in FIG. 4 (as likewise the subsequent FIG. 5), the time interval t represents the granularity of the error-check function. In the case of the embodiment of FIG. 4 (and of FIG. 5), τ is longer than the sum of the delays of the XOR gates and of the OR gate so as to guarantee the proper latching of the signal Fault_flag.”). Note also that relation Dmin>τ used in [18] is not very exact as it does not account for the hold time of the Error Latch. The correct expression should be Dmin>τ+t_{ELh}. But it is fair noting that the error in Dmin>τ, with respect to the correct expression Dmin>τ+t_{ELh}, is small, as t_{ELh} is a small value. This being said, let us mention that the implementation proposed in reference [18] is subject to some more important issues. First, as in practical designs the comparator 30 will have to check a significant number of regular flip-flops, its delays will be significant. Thus, our proposed condition (C1) requires a quite smaller value for Dmin. This will result in significant lower cost, as the delay that should be added in each short path for enforcing (Dₘᵢₙᵢ+D_{CMPmini})ₘᵢₙ>τ+t_{ELh} (constraint C1), is lower by at least the value D_{CMPmin} with respect to the delay that should be added in these paths for enforcing Dmin>τ+t_{ELh}, reducing significantly the cost of the buffers needed for adding these delays. Second, the value of delay of τ is set in [18] to be equal to the delay of the comparator (see [18] table II: “FIG. 4 Error signal delayed with respect to the master clock by the granularity and recognition delay”, “FIG. 5 Error signal delayed with respect to the master clock by the granularity and recognition delay”). However, as shown in the analysis on which is based this invention, the value of τ should be equal to τ=δ+D_{CMP(Error!->Error)max}+(t_{FFsu}−t_{ELsu}) (relation E1), where δ is the target duration of detectable faults. Using the value τ=D_{CMP(Error!->Error)max}+(t_{FFsu}−t_{ELsu}) will result on nil duration of detectable faults. Thus, the scheme proposed in [18] is both, unnecessary expensive and inefficient. Thus, with respect to the previous state-of-the-art, the present invention provides all the mandatory constraints required for achieving flawless operation, efficient error detection, and also leads to lower area and power cost.

Case k=2 (corresponding to the conditions (A2), (B2), (C2), (D2), (E2)), will be used when D_{FFmax}+D_{CMPmax}>T_{CK}, in order to avoid implementing a very large delay τ to realize the clock signal Ck+τ (and thus to avoid the related cost and also the related increase of the sensitivity of the clock signal Ck+τ to variations). Indeed, when D_{FFmax}+D_{CMPmax}>T_{CK}, if we use the case k=1, (B1) will imply a value τ>T_{CK}+t_{ELsu}, which is quite large, while using the case k=2, (B2) will imply reducing the above value of τ by an amount of time equal to T_{CK}.

The case where D_{FFmax}+D_{CMPmax}>2T_{CK} will be treated similarly by setting k=3, in order to reduce the value of τ by an extra amount of time equal to T_{CK}, and similarly for D_{FFmax}+D_{CMPmax}>3T_{CK} and k=4, and so on. It is worth noting that the implementation and the related conditions, proposed here for the cases k=2, k=3, etc. are not considered in previous works.

In the case k=2 and τ=0, the latching event of the Error Latch 40 will be the rising edge of the clock signal Ck. Thus, this latch will be rated directly by the clock signal Ck as shown in FIG. 4. Note that the similar implementation using this realization of the clock signal for the Error Latch is also presented in reference [7]. However, this proposal does not guarantee flawless operation, as it does not provide the conditions guarantying it. Furthermore, as mentioned earlier, the scheme proposed in reference [7] adds unnecessary delays on every input of the Comparator 30 coming from the input of a regular flip-flop.

Another option is to employ an error latch, which uses the falling event of its clock as latching event. This implementation is shown in FIG. 5, where the clock signal Ck+ω is obtained by delaying Ck by a delay ω, and the circle on the Ck+ω terminal of the Error Latch 40 indicates that the latching event of the Error Latch 40 is the falling edge of the clock signal Ck+ω.

As the falling edge of Ck+ω occurs at a time T_{H} after the rising edge of Ck+ω (where T_{H} is the duration of the high level of the clock signal Ck), in relations (A), (B), and (C) we have

(Dₘₐₓᵢ+D_{CMPmaxi})ₘₐₓ<kT_{CK}+T_{H}+ω−t_{ELsu} (A-H)

D_{FFmax}+D_{CMPmax}<(k−1)T_{CK}+T_{H}+ω−t_{ELsu} (B-H)

(Dₘᵢₙᵢ+D_{CMPmini})ₘᵢₙ>(k−1)T_{CK}+T_{H}+ω+t_{ELh} (C-H)

D_{FFmin}+D_{CMPmin}>(k−2)T_{CK}+T_{H}+ω+t_{ELh} (D-H)

δ=(k−1)T_{CK}+T_{H}+ω−D_{CMP(Error!->Error)max}+(t_{FFsu}−t_{ELsu}) (E-H)

These conditions are generic (are given for any integer value k≥1, and any real value ω in the interval 0<ω<T_{L}, where T_{L}=T_{CK}−T_{H} is the duration of the low level of the clock signal), and can be specified to different cases of practical interest. For k=1 we obtain:

(Dₘₐₓᵢ+D_{CMPmaxi})ₘₐₓ<T_{CK}+T_{H}+ω−t_{ELsu} (A-H1)

D_{FFmax}+D_{CMPmax}<T_{H}+ω−t_{ELsu} (B-H1)

(Dₘᵢₙᵢ+D_{CMPmini})ₘᵢₙ>T_{H}+ω+t_{ELh} (C-H1)

D_{FFmin}+D_{CMPmin}>−T_{CK}+T_{H}+ω+t_{ELh} (D-H1)

δ=T_{H}+ω−D_{CMP(Error!->Error)max}+(t_{FFsu}−t_{ELsu}) (E-H1)

For k=2 we obtain:

(Dₘₐₓᵢ+D_{CMPmaxi})ₘₐₓ<2T_{CK}+T_{H}+ω−t_{ELsu} (A-H2)

D_{FFmax}+D_{CMPmax}<T_{CK}+T_{H}+ω−t_{ELsu} (B-H2)

(Dₘᵢₙᵢ+D_{CMPmini})ₘᵢₙ>T_{CK}+T_{H}+ω+t_{ELh} (C-H2)

D_{FFmin}+D_{CMPmin}>T_{H}+ω+t_{ELh} (D-H2)

δ=T_{CK}+T_{H}+ω−D_{CMP(Error!->Error)max}+(t_{FFsu}−t_{ELsu}) (E-H2)

For k=1 and ω=0 we obtain:

(Dₘₐₓᵢ+D_{CMPmaxi})ₘₐₓ<T_{CK}+T_{H}−t_{ELsu} (A-H3)

D_{FFmax}+D_{CMPmax}<T_{H}−t_{ELsu} (B-H3)

(Dₘᵢₙᵢ+D_{CMPmini})ₘᵢₙ>T_{H}+t_{ELh} (C-H3)

D_{FFmin}+D_{CMPmin}>−T_{CK}+T_{H}+t_{ELh} (D-H3)

δ=T_{H}−D_{CMP(Error!->Error)max}+(t_{FFsu}−t_{ELsu}) (E-H3)

For k=2, and ω=0 we obtain:

(Dₘₐₓᵢ+D_{CMPmaxi})ₘₐₓ<2T_{CK}+T_{H}−t_{ELsu} (A-H4)

D_{FFmax}+D_{CMPmax}<T_{CK}+T_{H}−t_{ELsu} (B-H4)

(Dₘᵢₙᵢ+D_{CMPmini})ₘᵢₙ>T_{CK}+T_{H}+t_{ELh} (C-H4)

D_{FFmin}+D_{CMPmin}>T_{H}+t_{ELh} (D-H4)

δ=T_{CK}+T_{H}−D_{CMP(Error!->Error)max}+(t_{FFsu}−t_{ELsu}) (E-H4)

Cases with values of k larger than 2 can also be considered, but they will be of interest for quite large values of D_{CMPmax}, which are not very likely in practical designs.

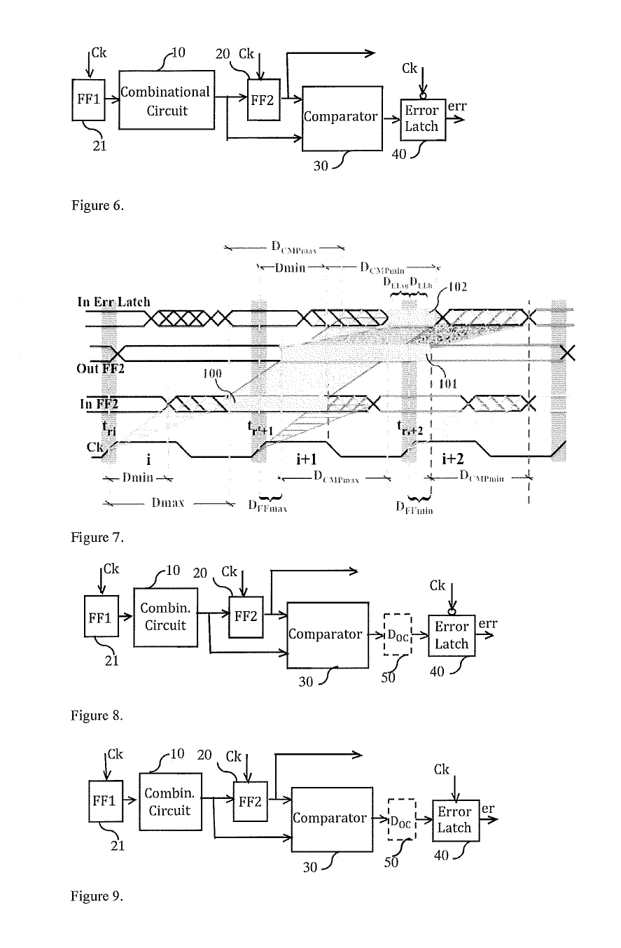

Note that in the cases using ω=0, the double sampling scheme will be implemented as shown in FIG. 6, where the Error Latch is rated directly by the clock signal Ck, and its latching event is the falling edge of the clock signal Ck.

Note also that, the cases derived from conditions (A-H), (B-H), and (C-H) are not proposed in previous works, except the case k=1 and ω=0, which is proposed in reference [7]. However, this proposal does not guarantee flawless operation, as it does not provide the necessary conditions for guarantying it. Furthermore, as mentioned earlier, the scheme proposed in reference [7] adds unnecessary delays on every input of the Comparator 30 coming from the input of a regular flip-flop, resulting in significant cost increase.

### Constraints Enforcement

So far, we have derived the constraints required for the flawless operation of the proposed double-sampling scheme. However, to use this scheme in practical implementations, we need a methodology for: manually selecting the values of the parameters k and τ or ω, together with the related architecture (FIG. 3, 4, 5, or 6), and for enforcing the instantiation of constraints (A), (B), (C), (D), and (E) corresponding to the selected architecture and values of k and τ or ω; or for implementing an automation tool performing these selections and synthesizing designs enforcing these constraints. Preferably, this methodology should also allow minimizing the implementation cost of the double-sampling scheme. The starting point for selecting the values of k and τ (or ω), together with the related architecture (the one of FIG. 3, 4, 5, or 6), are the timing characteristics of the design and its components and the target duration δ of detectable faults.

For the architecture of FIG. 3 we have to enforce the constraints (A), (B), (C), (D) and (E). Since we have Dmax<T_{CK} (as required for avoiding setup violations for the standard synchronous-design part of this architecture), we find trivially that relation (B) implies relation (A). Indeed, as Dmax<T_{CK}, then (B) implies Dmax+D_{CMPmax}<kT_{CK}+τ−t_{ELsu}. We also have (Dₘₐₓᵢ+D_{CMPmaxi})ₘₐₓ<Dmax+D_{CMPmax}. Thus, (Dₘₐₓᵢ+D_{CMPmaxi})ₘₐₓ<kT_{CK}+τ−t_{ELsu}, which is constraint (A). Also, as T_{CK}>D_{mini i} for each flip-fop FF2 20, we find T_{CK}+D_{CMPmin}>(Dₘᵢₙᵢ+D_{CMPmini})ₘᵢₙ. Thus, (C) gives D_{CMPmin}>(k−2)T_{CK}+τ+t_{ELh}, which is constraint (D). Thus, for the case of FIG. 3, we only need to enforce (B), (C), and (E). Similarly, we also find that: as Dmax<T_{CK}, relation (B-H) implies relation (A-H); and as T_{CK}>Dₘᵢₙᵢ for each flip-fop FF2 20, relation (C-H) implies relation (D-H). Thus, for the case of FIG. 5, we only need to enforce (B-H), (C-H), and (E-H). Note that as mentioned earlier, constraint (B) is preferable to be enforced with some margin M_{EARLY}, which is a designer-selected margin accounting for possible clock skews, jitter, and circuit delay variations, resulting in the constraint that was referred as (B′).

Concerning the enforcement of constraints (B) and (E), let □_{trg} be the target duration of detectable faults in a design implementing the architecture of FIG. 3. Then, there are two possible cases:
a) δ_{trg}≥(D_{CMPmax}−D_{CMP(Error!->Error)max}+D_{FFmax}+t_{FFsu})+M_{EARLY}
b) δ_{trg}<(D_{CMPmax}−D_{CMP(Error!->Error)max}+D_{FFmax}+t_{FFsu})+M_{EARLY}

As for any design implemented according to the architecture of FIG. 3, the duration a of detectable faults was found earlier to be δ=(k−1)T_{CK}+τ−D_{CMP(Error!->Error)}max+(t_{FFsu}−t_{ELsu}), enforcing this relation for the target value δ_{trg} of a gives δ_{trg}=(k−1)T_{CK}+τ−D_{CMP(Error!->Error)max}+(t_{FFsu}−t_{ELsu}). Then, combining it with a) gives (k−1)T_{CK}+τD_{CMP(Error!->Error)max}+(t_{FFsu}−t_{ELsu})>(D_{CMPmax}−D_{CMP(Error!->Error)max}+D_{FFmax}+t_{FFsu})+M_{EARLY}, resulting in (k−1)T_{CK}+τ−t_{ELsu}>D_{CMPmax}+D_{FFmax}+M_{EARLY}, which enforces constraint (B) with a designer-selected margin M_{EARLY}. Thus, in case a) enforcing constraint (E) enforces also constraint (B).

On the other hand, if the target duration δ_{trg} of detectable faults verifies case b), combining this case with constraint (B′), which is constraint (B) with a designer-selected margin M_{EARLY}, implies δ_{trg}+D_{FFmax}+D_{CMPmax}+M_{EARLY}<(k−1)T_{CK}+τ−t_{ELsu}+(D_{CMPmax}−D_{CMP(Error!->Error)max}+D_{FFmax}+t_{FFsu})+M_{EARLY}, which gives δ_{trg}<(k−1)T_{CK}+τ−D_{CMP(Error!->Error)max}+(t_{FFsu}−t_{ELsu}). Thus, in case b), enforcing constraint (B′) results in a design that detects faults of duration δ=(k−1)T_{CK}+τ−D_{CMP(Error!->Error)max}+(t_{FFsu}−t_{ELsu}), which is larger than the target value δ_{trg} of detectable faults.

The outcome of this analysis is that, to enforce constraints (B) and (E), we check the value of when the target duration δ_{trg} of detectable faults. Then:
If δ_{trg}≥(D_{CMPmax}−D_{CMP(Error!->Error)max}+D_{FFmax}+t_{FFsu})+M_{EARLY}, we enforce constraint (E) by setting τ=δ_{trg}+D_{CMP(Error!->Error)max}+(t_{ELsu}−t_{FFsu})−(k−1)T_{CK}, and this action enforces also constraint (B′).
If δ_{trg}<(D_{CMPmax}−D_{CMP(Error!->Error)max}+D_{FFmax}+t_{FFsu})+M_{EARLY}, we enforce constraint (B′) by setting τ=D_{FFmax}+D_{CMPmax}+t_{ELsu}−(k−1)T_{CK}+M_{EARLY}, and this action enforces also constraint (E).

Similarly, concerning the enforcement of constraints (B-H) and (E-H) in designs implementing the architecture of FIG. 5, we find that:
If δtrg≥(D_{CMPmax}−D_{CMP(Error!->Error)max}+D_{FFmax}+t_{FFsu})+M_{EARLY}, we enforce constraint (E-H) by setting ω=δ_{trg}+D_{CMP(Error!->Error)max}+(t_{ELsu}−t_{FFsu})−(k−1)T_{CK}−T_{H}, and this action enforces constraint (B-H) with a margin M_{EARLY}, which is a designer-selected margin accounting for possible clock skews, jitter, and circuit delay variations.
If δ_{trg}<(D_{CMPmax}−D_{CMP(Error!->Error)max}+D_{FFmax}+t_{FFsu})+M_{EARLY}, we enforce constraint (B-H) with a designer-selected margin M_{EARLY} (which accounts for possible clock skews, jitter, and circuit delay variations), by setting ω=D_{FFmax}+D_{CMPmax}+t_{ELsu}−(k−1)T_{CK}−T_{H}+M_{EARLY}, and this action enforces also constraint (E-H).

Fig.Form the above analysis, the designer has first to determine the target duration strg of detectable faults required for its target application, and check if for this duration satisfies case a) or case b). Then:
If the design is implemented by means of the architecture of FIG. 3, the designer will enforce constraints (B) and (E), by determining the value of τ enforcing constraint (E) if case a) is satisfied, or by determining the value of τ enforcing constraint (B) if case b) is satisfied, as described above.
If the design is implemented by means of the architecture of FIG. 5, the designer will enforce constraints (B) and (E), by determining the value of ω enforcing constraint (E-H) if case a) is satisfied, or by determining the value of ω enforcing constraint (B-H) if case b) is satisfied, as described above.

However, for determining the value of τ or ω by means of the expressions provided in our analysis above, the designer will also need to determine the value of k. An option is to use k=1 regardless to the design parameters. But in designs checking large number of regular flip-flops FF2 20, the delay of the comparator can be very large and may result in large value for τ or ω. Then, as a large value of c or c requires adding a large delay on the clock input of the Error Latch 40, the designer may prefer to reduce this value, in order to reduce the cost required to add large delays on the clock input of the Error Latch 40 and/or reduce the sensitivity of the values of τ or ω to delay variations. Then, to maximize the reduction of the value of τ or ω, the designed can use the following approach.

P1) Architecture of FIG. 3 in which case a) is satisfied: k=I+1 and τ=F, where I is the integer part of (δ_{trg}+D_{CMP(Error!->Error)max}+(t_{ELsu}−t_{FFsu}))/T_{CK} and F is the fractional part of (δ_{trg}+D_{CMP(Error!->Error)max}+(t_{ELsu}−t_{FFsu}))/T_{CK}

P2) Architecture of FIG. 3 in which case b) is satisfied: k=I+1 and τ=F, where I is the integer part of (D_{FFmax}+D_{CMPmax}+t_{ELsu}+M_{EARLY})/T_{CK} and F is the fractional part of (D_{FFmax}+D_{CMPmax}+t_{ELsu}+M_{EARLY})/T_{CK}

P3) Architecture of FIG. 5 in which case a) is satisfied: k=I+1, where I is the integer part of (δ_{trg}+D_{CMP(Error!->Error)max}+(t_{ELsu}−t_{FFsu}))/T_{CK}. Concerning w its value is determined by means of the value of the fractional part F of (δ_{trg}+D_{CMP(Error!->Error)max}+(t_{ELsu}−t_{FFsu}))/T_{CK}, in the following manner:
i. If F≥T_{H} then ω=F−T_{H}.
ii. If F<T_{H} we can modify the duty cycle of the clock to make the duration T_{H} of the high level of the clock equal to F and we set ω=0; alternatively, we can set ω=0 and add a delay D_{OC}=T_{H}−F on the output of the Comparator 30 as shown in FIG. 8.

P4) Architecture of FIG. 5 in which case b) is satisfied: k=I+1, where I is the integer part of (D_{FFmax}+D_{CMPmax}+t_{ELsu}+M_{EARLY})/T_{CK}. Concerning w its value is determined by means of the value of the fractional part F of (D_{FFmax}+D_{CMPmax}+t_{ELsu}+M_{EARLY})/T_{CK}, in the following manner:
i. If F≥T_{H} then ω=F−T_{H}.
ii. If F<T_{H} we can modify the duty cycle of the clock to make the duration T_{H} of the high level of the clock equal to F and we set ω=0; alternatively, we can set ω=0 and add a delay D_{OC}=T_{H}−F on the output of the Comparator 30 as shown in FIG. 8.
   Selecting the Architecture that Minimizes the Added Delay on the Clock Input of the Error-Latch

A last question is which of the architectures of FIG. 3 or of FIG. 5 minimizes the delay that we have to add on the clock signal of the Error Latch 40. To answer this question, from points P1, P2, P3, and P4 we remark that, the values of F and I differ in cases a) and b), but are identical for both architectures. Thus, we can determine the value of F, before making the selection of the architecture of FIG. 3 or 5, and use this value to select the preferable architecture, as described bellow:
i. If 0<F<T_{H}, we select the architecture of FIG. 3 with k=I+1 and τ=F≠0. Alternatively, we can modify the duty cycle of the clock signal Ck, to have T_{H}=F, resulting in case iii. (treated bellow) which provides for this case the preferable architecture. A second alternative is to add a delay D_{OC}=T_{H}−F on the output of the comparator, leading to a fractional part F′=T_{H}, resulting in case iii. and the architecture shown in FIG. 6.
ii. If F=0, we select the architecture of FIG. 4 (i.e. the architecture of FIG. 3 with τ=0) with k=I+1 and I≥1.
iii. If F=T_{H}, we select the architecture of FIG. 6 (i.e. the architecture of FIG. 5 with ω=0) with k=I+1.
iv. If F>T_{H}, we select the architecture of FIG. 5 with k=I+1 and ω=F−T_{H}. Alternatively, we can modify the duty cycle of the clock signal Ck, to have T_{H}=F, resulting in case iii. and the related architecture. A second alternative is to add a delay D_{OC}=T_{CK}−F on the output of the comparator, leading a fractional part F′=0 for (□+D′_{CMP})/T_{CK}, resulting in case ii. and the architecture shown in FIG. 9.

In addition to the double-sampling scheme, in certain designs we may also have to implement an error recovery scheme, which restores the correct state of the circuit after each error detection. In this case, the output of the Error Latch 40 will be used to interrupt the circuit operation (e.g. by blocking the clock signal Ck by means of clock gating), in order to interrupt the propagation of the error through the pipeline stages. Then, to simplify the implementation of the error recovery process, we may have interest to activate this interruption at the earliest possible cycle of the cock signal Ck, in order to minimize the number of pipe-line stages at which the error is propagate. In this context, minimizing the value of k, and in certain cases the value of z, will be very useful. Then, it is worth noting that: the implementations described above, which add a delay D_{OC} on the output of the comparator as illustrated in FIGS. 8 and 9; will postpone the rising edge of the Error Latch 40 by a delay equal to D_{OC}, and could postpone the cycle of the clock signal Ck at which the interruption is activated. In this case, it would be preferable not to use these alternatives.

It is also worth noting that, if we employ some of the implementations described above where we add a delay D_{OC} on the output of the comparator, then, in the enforcement of relations (C) and (C-H) discussed below, we will implicitly consider the value D′_{CMP}=D_{CMP}+D_{OC} instead of D_{CMP}. Similarly, if we employ some of the implementations described above where we modify the duration T_{H} of the high level of the clock signal Ck, then, in the enforcement of relations (C) and (C-H) discussed bellow, we will implicitly consider the modified value of T_{H}.

### Enforcement of Constraint (C)

From (C) we have (Dₘᵢₙᵢ+D_{CMPmini})ₘᵢₙ>(k−1)T_{CK}+τ+t_{ELh}. Knowing the design parameters T_{CK}, and t_{ELh}, and the values of (k−1) and τ determined by the above procedure, we can check if this relation is satisfied for the actual value of (Dₘᵢₙᵢ+D_{CMPmini})ₘᵢₙ of the design, with the target margin M_{LATE}. Then, for each path starting from the input of a regular flip-flops FF1 21 and ending on the input of the Error Latch 40, and having delay lesser than (k−1)T_{CK}+τ+t_{ELh}+M_{LATE}, we add buffers to ensure that their delay exceeds this value. These buffers can be added in the Combinational Circuit part and/or in the Comparator part of the path, by taking care when adding these buffers not to increase the maximum delay Dmax of the circuit, nor to increase the maximum delays D_{CMPmax} and D_{CMP(Error!->Error)max} of the Comparator 30. This will enforce constraint (C) for the architecture of FIG. 3.

Similarly, from (C-H) we have (Dₘᵢₙᵢ+D_{CMPmini})ₘᵢₙ>(k−1)T_{CK}+T_{H}+ω+t_{ELh}. As now we know the values (k−1), T_{CK}, ω, and t_{ELh}, we can check if this relation is satisfied for the actual value of (Dₘᵢₙᵢ+D_{CMPmini})ₘᵢₙ, with the target margin M_{LATE}. Then, for each path starting from the input of a regular flip-flop FF1 21 and ending on the input of the Error Latch 40, and having delay lesser than (k−1)T_{CK}+ω+t_{ELh}+M_{LATE}, we add buffers in the Combinational Circuit and/or in the Comparator part of Pi, as described above for constraint (C), to ensure that their delay exceeds this value. This will enforce constraint (C-H) for the architecture of FIG. 5.

### Accelerating the Speed of the Comparator

In most designs, each time the output signal of the Error Latch 40 is activated, this signal will be used to stop the circuit operation as early as possible (usually be blocking the clock signal), in order to limit the propagation of the errors within the subsequent pipeline stages, and to initiate an error recovery process to correct the error. Generally the higher is the number of pipeline stages at which the errors are propagated, the higher will be the complexity of the error recovery process. Thus, we have interest to latch the error detection signal as early as possible. We observe that, if an error is latched by some of the regular flip-flips FF2 20 at the latching edge of a clock cycle i+1, then, from relation (E) we find that the error detection signal detecting this error will be latched by the Error Latch 40 at a time δ+D_{CMPmax} after the latching edge of a clock cycle i+1. In complex designs, where large numbers of flip-flops are checked by comparing duplicated signals, D_{CMPmax} will be high and will delay significantly the activation of the error detection signal. Thus, we have interest to reduce this delay as much as possible. To achieve this reduction this invention combines: properties derived by the structure of the comparator; its interaction with the rest of the error detection architecture; and the way the error detection signal is employed.

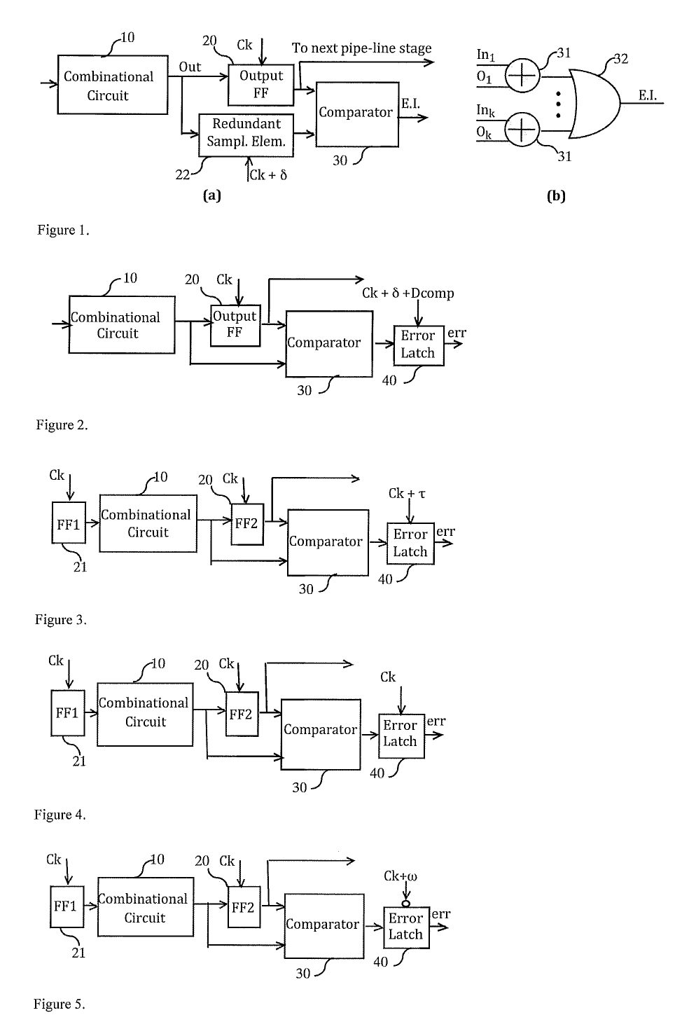

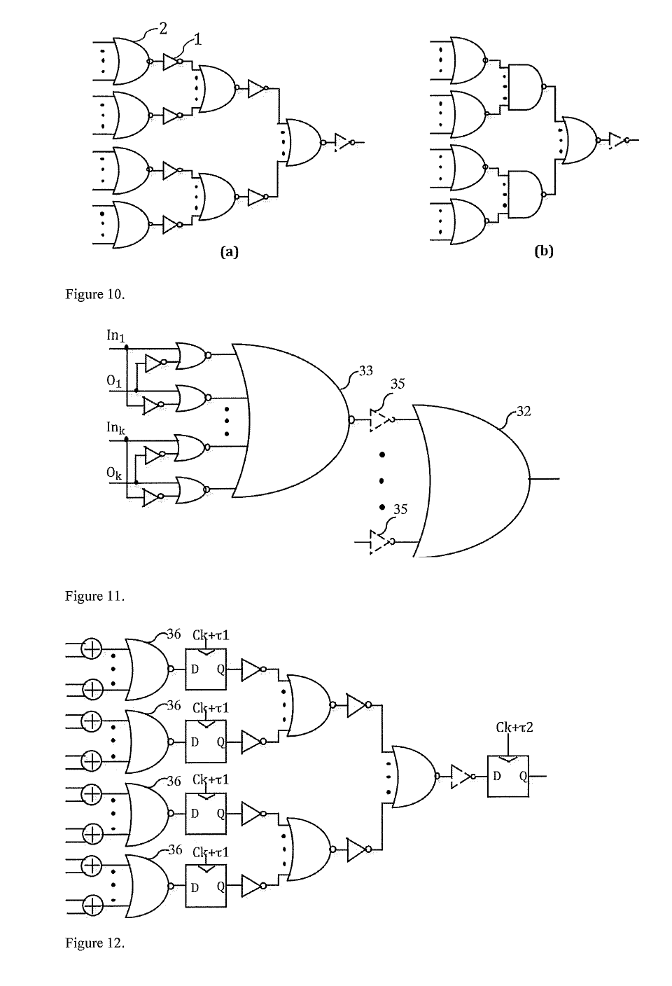

A comparator can be implemented in various ways. For instance, as illustrated in FIG. 1b, it can be implemented by using a stage of XOR gates 31, each comparing a pair of signals (Inᵢ, Oᵢ), plus an OR tree 32 compacting the outputs of the XOR gates into a single error detection signal. The OR tree, can be implemented in various ways using inverting gates, as non inverting gates do not exist in CMOS technologies. For instance, the OR tree can be implemented, by using several levels of OR gates, each implemented by means of a NOR gate and an inverter, as illustrated in FIG. 10.a. This comparator signals error detections by supplying the value 1 on his output and no detections by supplying the value 0. In FIG. 10.a, the inverter shown on the output of the comparator in dashed lines, can be omitted. In this case, the comparator will signal error detections by supplying the value 0 on its output and no detection by supplying the value 1. Another implementation of the OR tree, illustrated on FIG. 10.b, alternates stages of NOR gates and NAND gates, starting by a stage of NOR gates on the outputs of the XOR gates. Similarly to FIG. 10.a, the inverter on the output of the comparator, shown in dashed lines, can be omitted. Another possibility is to use an XNOR gate to compare each pair of signals (Inᵢ, Oᵢ), and then employ an AND tree to compact compacting the outputs of the XNOR gates into a single error detection signal. The AND tree can be implemented by in various ways. For instance, the AND tree can be implemented, by using several levels of AND gates, each implemented by means of a NAND gate and an inverter. Another implementation of the AND tree, alternates stages of NAND gates and NOR gates, starting by a stage of NAND gates on the outputs of the XNOR gates. Those skilled in the art will readily understand that the comparator can also be implemented in various other ways, even without using a stage of XOR or XNOR gates. Such an implementation is illustrated in FIG. 11, where the comparison of a group of k pairs of signals (In₁, O₁), . . . (Inₖ, Oₖ) is realized by implementing the logic function In₁!O₁+In₁O₁! In₂!O₂+In₂ O₂! . . . +Inₖ!Oₖ+InₖOₖ! (where the symbol ! represents the logic negation—not), by means of 2 k inverters, 2 k NOR gates of two inputs each, a NOR gate 33 of k inputs and an inverter. Several such circuits can be used for several groups of such signal pairs. The outputs of all these circuits will be compacted by an OR tree 32. Also, the inverters 35 on the output of the NOR gates 33, shown in dashed lines, can be omitted. in this case, an AND tree will be used instead of the OR tree 32. The OR tree and the AND tree, can be realized in various manners as described earlier.

The output of a NOR gate of q inputs is connected to the Gnd by means of q NMOS parallel transistors, and is also connected to the Vdd by means of q PMOS transistors disposed in series. Then, the 1 to 0 transitions of the NOR gate output are very fast, as the current discharging its output has to traverses only one NMOS transistor. To realize an OR tree of Q inputs, we can use log₂Q levels of two-input NOR gates each followed by an inverter. If we have to check a very large number of flip-flops (e.g. 5000), we have to realize an OR tree of a large number of levels (e.g. 12 levels of NOR gates and 12 levels of inverters), which will result in a large delay D_{CMPmax}. To reduce, this delay, we can try to use NOR gates with more inputs (e.g. using 4-input NOR gates will result in (6 levels of NOR gates and 6 levels of inverters), however, as the PMOS network of a 4-input NOR gate uses 4 MOS transistors in series, the maximum delay of the gate (i.e. the delay of the 0 to 1 transition), will be much larger than the maximum delay of the 2-input NOR gate. We have the similar problem with a q-input NAND gates, in which, the delay of the 0 to 1 transitions are fast, as the charging current traverses only one PMOS transistor, while the 1 to 0 transitions are too slow as the discharging current traverses q NMOS transistors connected in series.

The goal of the present analysis is to increase the speed and reduce the power of the comparators. The first step on this direction is to eliminate hazards in the OR or the AND tree used to implement the comparator. Hazards in these blocks may occur due to two causes. The first cause is that XOR and XNOR gates are hazard prone (i.e. they may produce hazards even if their inputs change at the same time). The second and more serious cause is that, in the double sampling architectures, the inputs of the comparator do not change values at the same time. For instance, in the architecture of FIG. 1.a, at the rising edge of each clock cycle the regular flip-flops FF2 20 apply on the inputs of the Comparator 30 the new values produced by the Combinational Circuit 10, while the redundant sampling elements 22 apply these new values on the inputs of the Comparator 30 at the a time □ after this edge. Thus, even if no errors occur in the regular flip-flops FF2 20, the inputs of the comparator may receive non-equal values during the time period □. Similarly, in the architecture of FIG. 3, the comparator may receive different values on its inputs for a certain time during each clock period, as the half of its inputs come from the regular flip-flops 20, and the other half come directly from the outputs of the Combinational Circuit 10.

To isolate from these hazards the whole OR tree (or AND tree) of the comparator or a part of it, we can pipeline this tree. The first stage of flip-flops of this pipeline can be placed:
either on the inputs of the OR tree (or AND tree) of the comparator: that is on the outputs of the XOR gates or XNOR gates used to implement the comparator, or on the outputs of the NOR gates 33 or the inverters 35 preceding the OR tree in the Comparator implemented without XOR gates illustrated in FIG. 11;
or on the outputs of any subsequent stage of gates. For instance, in FIG. 12, the first stage of flip-flops of the pipelined OR tree, are placed on the outputs of the NOR gates 36 subsequent to the stage of XOR gates.

With this implementation, the part of the OR tree or AND tree, which are between this first stage of the flip-flops and the output of the OR tree or AND tree (to be referred hereafter as hazards-free OR or AND tree), is not subject to hazards.

In all possible realizations of a comparator, we find that:
1. When during a clock cycle no errors occur, the output of each NOR gate is at 1, and the output of each NAND gate is at 0.
2. When some errors in a clock cycle occur, then, the outputs of some XOR gates are at 1 (and if XNOR gates are used their outputs are at 0). Each path connecting the output of one of these XOR (XNOR) gates to the output the OR tree or AND tree will be referred hereafter as sensitized error-path. Then, the output of each NOR gate belonging to a sensitized error-path will take the value 0, and the output of each NAND gate belonging to sensitized error-path will take the value 1. Furthermore the outputs of all other NOR gates will take the value 1, and the outputs of all other NAND will take the value 0. The signals of the OR-tree or the AND-tree of the comparator, which take the value 0 when a sensitized error-path traverses them, will be referred hereafter as 0-error signals, and those that take the value 1 when a sensitized error-path traverses them, will be referred hereafter as 1-error signals. Thus, the inputs of the NOR gates, the outputs of the NAND gates of the OR-tree or the AND-tree are 1-error signals, while the inputs of the NAND gates and the outputs of the NOR gates of the OR-tree or the AND-tree are 0-error signals. Also, the input of inverters driven by the outputs of NAND gates and the outputs of inverters driving the inputs of NOR gates are 1-error signals, while the input of inverters driven by the outputs of NOR gates and the outputs of inverters driving the inputs of NAND gates are 0-error signals.

Then, in all possible realizations of a comparator, which is pipelined as described above, we find that for the NOR gates and/or NAND gates belonging to the hazards-free OR tree or AND tree, the hazards-free property of these paths, and the points 1 and 2 given above, imply the following properties:
a. When in a clock cycle i there are no errors and at the following clock cycle i+1 there are no errors, then no transitions occur on the outputs of any NOR and/or NAND gate.
b. When in a clock cycle i there are no errors and at the following clock cycle i+1 there are some errors, then: in each sensitized error-path all NOR gate outputs undergo a 1-to-0 transition and all NAND gate outputs undergo a 0-to-1 transition (which are the fast transitions for the NOR and the NAND gates); the outputs of all other NOR and NAND gates do not change value. Thus, in this case, transitions occur only in the gates belonging to the sensitized error-paths, and all these transitions are fast.
c. When no errors occur in the clock cycle i+2, subsequent to the error cycle i+1 in which some errors have occurred as described in the previous point, then, transitions occur in all the gates belonging to the sensitized error-paths and only to these gates, and all these transitions are slow.

Based to the above analysis we use the following approach to accelerate the computation of the error detection signal:
The first stage of flip-flops of the pipelined OR tree or AND tree will be clocked by considering the slow transitions of the gates composing the first pipeline stage of the comparator.
Until error detection, all other flip-flops of the pipelined OR tree or AND will be clocked by considering the fast transition delays of the gates composing the hazards-free OR tree or AND tree. As before the cycle of error detection no transitions occur (see point a. above), and at the cycle of error detection only fast transitions occur in the hazards-free OR tree or AND tree (see point b. above), then, the comparator will be clocked correctly. It is worth noting that the delay of fast transitions (i.e. the 1 to 0 transition of the NOR gate output) depends on the number of the gate inputs that undergo the 0 to 1 transition. Then, in determining the clock period, we will consider the slowest of these fast transitions (i.e. when just one input of the NOR gate undergoes the 0 to 1 transitions). Similarly, for the NAND gates we will consider the delay of the slowest fast transition (i.e. when just one input of the NAND gate undergoes the 1 to 0 transitions). Similarly, the term fast transition will be used hereafter in the sense of the slowest fast transition. —When error detection occurs, for the error detection signal to go back to the error-free indication, slow transitions should occur in the NOR and/or NAND gates (see point c. above). Thus, for this change to occur, we have to give to the flip-flop stages of the hazards-free part of the OR tree or AND tree, more time than that given in the situations considered above. This can be done in various manners. The more practical manner is to exploit the period during which the system stops its normal operation in order to mitigate the impact of the detected errors. For, instance, one strategy consists in:
Stopping the circuit operation when the error detection signal goes active, in order to stop as early as possible the propagation of the error in the pipeline stages.
Activating an error recovery process, during which the clock period is increased. This is necessary for timing faults, in order to avoid that the detected fault is activated again. Usually, the clock period is doubled to provide confortable margins, so that the error does not occur again.
After error recovery, returning to the normal operation, during which the normal value of the clock period is employed.

We remark that, as the clock period is increased during the error recovery process, we dispose more time to allocate to the hazards-free part of the OR tree or AND tree. Thus, we can adapt the clock signals of the flip-flop stages of this part, to provide the extra time required when considering the delay of slow transitions. Alternatively, we can design the circuit in a manner that the Error Latch does not returns to the error-free indication immediately at the first cycle at which the states of the regular flip-flops become error free, but after few clock cycles.

Note that the basic advantage of this implementation is that it allows detecting the errors faster and thus enables blocking the error propagation earlier, making this way simpler the error recovery process. Another advantage is that, during most of the time, there are no transitions in the hazards-free part of the comparator (see above point a.), which reduces its power dissipation. Those skilled in the art will readily understand that, the fast OR or AND tree design described above, can be used in any circuit in which errors are detected by using a comparator to compare pairs of signals that are equal during fault-free operation, as well as in any circuit in which errors are detected by using a plurality of error detection circuits, such that, each error detection circuit provides an error detection signal, and an OR tree or an AND tree is used to compact in a single error detection signal the plurality of the error detection signal provided by the plurality of the error detection circuits.

Another question concerns the selection of the positions of the first stage of flip-flop in the pipelined OR tree or AND tree. We remark that, the closer to the inputs of the OR tree or AND tree are placed these flip-flops, the larger the hazards-free part of the OR tree or AND tree, and thus, the higher the acceleration of the comparator speed during normal operation. But on the other hand, placing the first stage of flip-flops close to the inputs of the OR tree or AND tree, increases the number of the flip-flops of this stage. Thus, the designer will have to decide about this position based on the complexity reduction of the error recovery process and the related implementation cost, and the increase of the number of flip-flops to be used in the pipelined OR tree or AND tree. We note that, as we move away from the inputs of the OR tree or AND tree, the number of flip-flops decreases exponentially. Thus, we can reduce drastically their cost by moving the first stage of flip-flops a few gate levels away the inputs of the comparator.

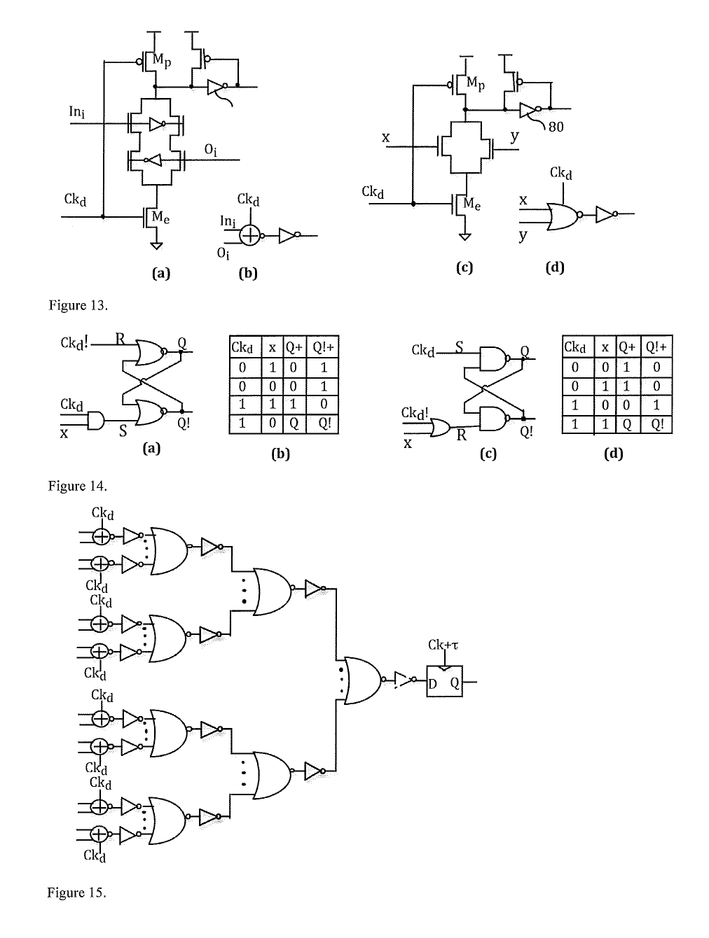

Another option is to eliminate the first stage of flip-flops, and replace a stage of static gates of the comparator by their equivalent dynamic gates. In this case, a first option consists in using dynamic logic to implement the XOR gates of the comparator. An implementation of the dynamic XOR gate (dynamic XNOR gate plus output inverter 80 is shown in FIG. 13.a and the symbol representing it is shown in FIG. 13.b. Then, the implementation of the comparator is shown in FIG. 15, where the dynamic XOR gates are represented by using their symbol shown in FIG. 13.b.

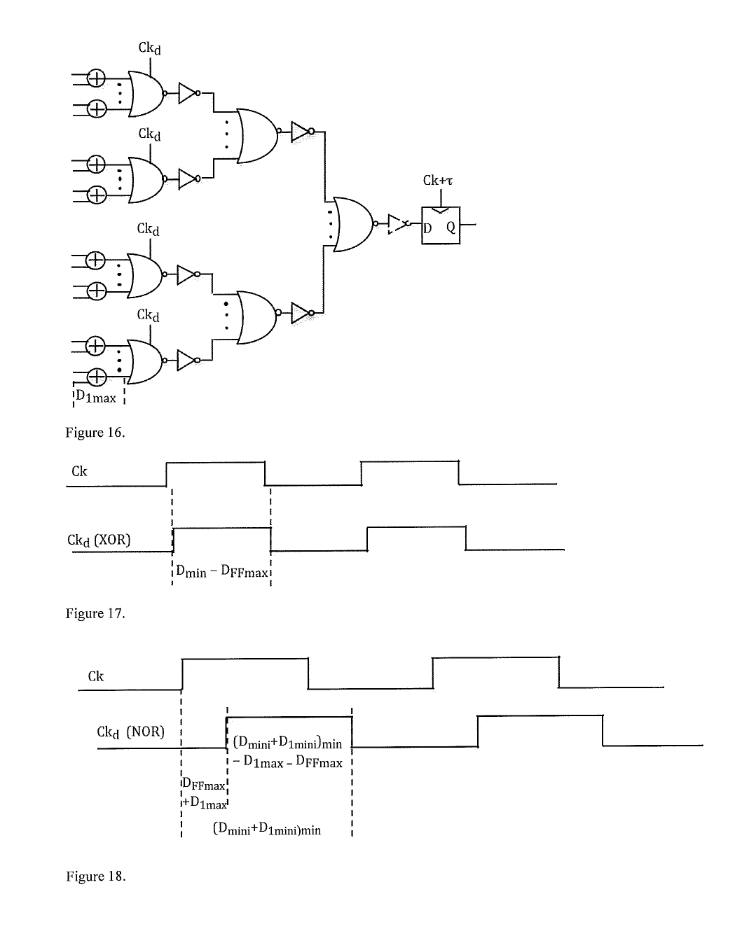

Another option consists in using dynamic logic to implement one of the stages of OR gates of the comparator, as illustrated in FIG. 16. In this Fig., the first stage of OR gates of the comparator is implemented by means of dynamic OR gates (NOR gate plus inverter) as those shown in FIG. 13.c together with their symbol shown in FIG. 13.d. The other possibility is to use dynamic logic to implement one of the stages of AND gates (NAND gate plus inverter) of the comparator. However, as the n-transistors in NAND gates are connected in series, dynamic AND gates using a network of n-transistors and a PMOS precharge transistor will be slow. Thus, for speed reasons it will be preferable to implement fast dynamic AND gates by using a network of p-transistors, and a NMOS discharge transistor. Nevertheless, the preferable implementation will use OR dynamic gates, which are generally faster, even from the fast version of AND dynamic gates, as n-transistors are faster than p-transistors. Thus, hereafter we discuss implementations using dynamic OR gates. However, those skilled in the art will readily understand that the proposed implementation for increasing the comparator speed is also valid if we use dynamic logic to implement a stage of inverters of the comparator; and that it is also valid if we use dynamic logic to implement a stage of AND gates of the comparator. But in the case of dynamic AND gates, we should employ the following modifications: the clock signal used to control the dynamic AND gates will be the inverse Ck_{d}! of the clock signal Ck_{d} used to control the dynamic OR gates, and in the relations derived hereafter, the duration T_{H} of the high level of the clock signal Ck_{d} used to control the dynamic OR gates, should be replaced by the duration T_{L} of the low level of the clock signal Ck_{d}! used to control the dynamic AND gates.

Finally, instead of using dynamic gates, we can insert a stage of set-reset latches like the ones shown in FIG. 14. These latches can be used to replace a stage of inverters of the OR-tree or the AND-tree of the comparator, like for instance one of the two stages of inverters shown in FIG. 10. In this case, the inputs x of the stage of set-reset latches will be driven by the signals that drive the inputs of the inverters before this replacement, and the outputs Q! of the stage of latches will drive the signals driven by the outputs of the inverters before this replacement. Another option is to insert a stage of these latches between the outputs of a stage of gates of the OR-tree or the AND-tree of the comparator and the inputs of the subsequent stage of gates of this tree. In this case, the outputs of the first stage of gates will drive the inputs x of the stage of latches, while the outputs Q of the stage of latches will drive the inputs of said subsequent stage of gates.

As it can be seen in the truth table of FIG. 14.b, when Ck_{d}=0, the outputs Q and Q! of the latch of FIG. 14.a are reset to Q=0 and Q!=1 regardless to the value of the input signal x. On the other hand, when Ck_{d}=1, the value x=1 sets the outputs Q and Q! to Q=1 and Q!=0, while the value x=0 preserves the previous values of Q and Q!. Thus, latches having the truth table of FIG. 14.b will be used when the signals of the OR-tree or the AND-tree driving their inputs x are 1-error signals. On the other hand, when the signals of the OR-tree or the AND-tree driving the inputs x of the latches are 0-error signals, latches having the truth table of FIG. 14.d will be used.

Those skilled in the art will also readily understand that, the use of dynamic logic for eliminating the first stage of flip-flops in the above described fast implementation of the OR or AND tree, can be employed for any kind of error detection circuits providing a plurality of error detection signals that is compacted by this OR or AND tree.

In the following, we discus in details the timing constraints that should be satisfied, when such as stage of dynamic gates is used in the Comparator 30 of the architecture of FIG. 3. Let D₁ₘᵢₙᵢ and D₁ₘₐₓᵢ be the minimum and the maximum delay of the path of the Comparator 30 connecting the input of the ith flip-flop FF2 20 to an input of the stage of dynamic gates used in the Comparator, as illustrated in FIGS. 15 and 16. Also, let D_{CCmini} be the minimum delay and D_{CCmaxi} the maximum delay of the paths connecting the outputs of the regular flip flops FF1 21 to the input of the ith regular flip flop FF2 20. We set Dmini=D_{FFmin}+D_{CCmini}, and Dmaxi−D_{FFmax}+D_{CCmaxi}. Then, (Dₘᵢₙᵢ+D₁ₘᵢₙᵢ)ₘᵢₙ will designate the minimum value of the sum Dₘᵢₙᵢ+D₁ₘᵢₙᵢ, and (Dₘₐₓᵢ+D₁ₘₐₓᵢ)ₘₐₓ will designate the maximum value of the sum Dₘₐₓᵢ+D₁ₘₐₓᵢ, for the set of regular flip-flops FF2 20 checked by the Comparator 30. Also, D₁ₘₐₓ and D₁ₘᵢₙ designate the maximum and minimum delays of the part of the comparator that is comprised between the inputs of the XOR gates and the inputs of the dynamic gates (say part 1 of the comparator).

As shown in FIGS. 13, 15, and 16, in the dynamic OR gates, the n-transistor driven by the clock Ck_{d} is ON during the high level of signal Ck_{d}. Thus, during this time, if the n-network driven by the inputs of the dynamic gate connects the output node of the NOR-gate part of the dynamic OR gate to the drain of the n-transistor driven by Ck_{d}, the NOR-gate output will discharge to low level, other-wise it will remain high. To simplify the discussion, we will consider that D₁ₘₐₓ+D_{FFmax} is less than Tck, which will be the case for most practical applications. Then, to avoid that hazards induced by propagation through long paths starting at regular flip-flops FF2 20, erroneously discharge this output, the relation tᵣᵢ₊₁+D_{FFmax}+D₁ₘₐₓ<t_{rdi+1} must be satisfied, where tᵣᵢ₊₁ is the instant of the rising edge of the clock signal Ck controlling the regular flip-flops FF2 20, and t_{rdi+1} is the instant of rising edge of the clock signal Ck_{d} subsequent to tᵣᵢ₊₁. By setting τ_{rd}=t_{rdi+1}−tᵣᵢ₊₁ we obtain

D_{FFmax}+D₁ₘₐₓ<τ_{rd} (B_{d1})

From the definition of D₁ₘᵢₙ and D₁ₘₐₓ, in implementations using dynamic XOR gates it will be D₁ₘᵢₙ=D₁ₘₐₓ=0. Thus, in the illustration of FIG. 17 using dynamic XOR gates, we employ a clock signal Ck_{d}, whose rising edge roughly coincides with the rising edge of clock signal Ck of the regular flip-flops 20 (i.e. it is delayed with respect to signal Ck by a very small delay equal to D_{FFmax}). As another illustration shown in FIG. 16, in the implementation using dynamic logic in the first stage of OR gates of the comparator, D₁ₘₐₓ is the maximum delay of the XOR gate.

To avoid that hazards induced by propagation through long paths starting at regular flip-flops FF1 21, erroneously discharge the output of the dynamic gates, the following constraint should be verified

(Dₘₐₓᵢ+D₁ₘₐₓᵢ)ₘₐₓ≤T_{CK}+τ_{rd} (A_{d1})

We observe that, as Dmax<T_{CK}, constraint (B_{d1}) implies Dmax+D₁ₘₐₓ<T_{CK}+τ_{rd}. We also have (Dₘₐₓᵢ+D₁ₘₐₓᵢ)ₘₐₓ≤Dmax+D₁ₘₐₓ. Thus, (Dₘₐₓᵢ+D₁ₘₐₓᵢ)ₘₐₓ<T_{CK}+τ_{rd}, which satisfies (A_{d1}). Hence, no particular care is required for enforcing constraint (A_{d1}).

On the other hand, to avoid that hazards induced by propagation through short paths starting at regular flip-flops FF1 21, erroneously discharge the outputs of the dynamic gates, the relation tᵣᵢ₊₁+(Dₘᵢₙᵢ+D₁ₘᵢₙᵢ)ₘᵢₙ≥t_{fdi+1} should be satisfied, where t_{fdi+1} is the instant of the falling edge of Ck_{d} subsequent to tᵣᵢ₊₁. By setting τ_{fd}=t_{fdi+1}−tᵣᵢ₊₁ we obtain

(Dₘᵢₙᵢ+D₁ₘᵢₙᵢ)ₘᵢₙ>τ_{fd} (C_{d1})

Then, as the period of the clock signal Ck_{d}, is equal to the period of the clock signal Ck of the Regular Flip-Flops FF1 21 and FF2 20, the definition of its rising and falling edge completely determines it.

Constraints (B_{d1}) and (C_{d1}) also imply

T_{Hd}<(Dₘᵢₙᵢ+D₁ₘᵢₙᵢ)ₘᵢₙ−D₁ₘₐₓ−D_{FFmax} (H_{d})

where T_{Hd} is the duration of the high level of Ck_{d}.

Then, the clock signal Ck_{d} can be generated in various ways. The simpler way is to use a clock signal Ck such that T_{H}=T_{Hd}. In this case the clock signal Ck_{d} can be simply generated by delaying the clock signal Ck by a delay equal to D_{FFmax}+D₁ₘₐₓ (the minimum value of τ_{rd} allowed by constraint (B_{d1})), as illustrated in FIG. 18, where we have used the value T_{H}=T_{Hd}=(Dₘᵢₙᵢ+D₁ₘᵢₙᵢ)ₘᵢₙ−D₁ₘₐₓ−D_{FFmax}, which verifies constraint (H_{d}). In this case, for the implementation using dynamic XOR gates Ck_{d} roughly coincides with Ck, as shown in FIG. 17.

For the comparator part comprised between the outputs of the dynamic gates and the input of the Error Latch 40, we have to consider the delay of the fast transitions for the static gates. Also, as the evaluation delay of dynamic OR gates is the delay of the 1-to-0 transition of the NOR gate plus the 0 to 1 transitions of the inverter composing the dynamic OR gate, it corresponds to the fast transitions of the static OR gates. Then, for the comparator part comprised between the inputs of the dynamic gates and the input of the Error Latch (to be referred hereafter as part 2 of the comparator), we have to consider only the delays of fast transitions. Thus, the maximum and minimum delays of this part will be represented hereafter as D_{2maxFast} and D_{2minFast}. Note also that, as we consider only the fast transitions, then, in balanced OR trees and AND trees, where all paths of the tree contain the same number and the same kinds of gates (like for instance in the OR trees of FIGS. 3.a and 3.a), we will have D_{2maxFast}=D_{2minFast}=D₂. To maximize the duration of detectable faults allowed by the proposed design, the Error Latch 40 should capture the result of the comparison corresponding to the data provided at the output of the dynamic gates at the instant τ_{fd}. Thus, considering the cycle i+k at which the Error Latch 40 captures the result of the comparison corresponding to the data provided at the output of the dynamic gates at the instant τ_{fd} of clock cycle i+1, then, to avoid long path issues the following constraint should be satisfied.

τ_{fd}+D_{2maxFast}<(k−1)T_{CK}+τ−t_{ELsu} (B_{d2})

Then, if we use the minimum value of τ_{rd} allowed by constraint (B_{d1}) (i.e. τ_{rd}=D_{FFmax}+D₁ₘₐₓ, constraint (B_{d2}) becomes D_{FFmax}+D₁ₘₐₓ+D_{2maxFast}<(k−1)T_{CK}+τ−t_{ELsu}

Concerning short path issues, we should ensure that data starting from regular flip-flops FF2 20 at cycle i+2, and data starting from regular flip-flops FF1 21 at clock cycle i+1, do not affect the value captured by the Error Latch 40 at the cycle i+k. For the propagations of these data, we remark that: from constraint (B_{d1}) the first of these data are ready on the inputs of the dynamic gates before the instant t_{rdi+2}, and will start at instant t_{rdi+2} to propagate through the dynamic gate towards the Error Latch 40; and from constraint (A_{d1}) the second of these data will arrive on the inputs of the dynamic gates before the instant t_{rdi+2}, and will start at instant t_{rdi+2} to propagate through the dynamic gates towards the Error Latch 40. Then, to avoid short path issues, we should ensure that t_{rdi+2}+D_{2minFast}>tᵣᵢ₊ₖ+τ+t_{ELh}. Thus we obtain:

D_{2minFast}>(k−2)T_{CK}−τ_{rd}+τ+t_{ELh} (C_{d2})/(D_{d2})

Note that the value of k is determined by constraint (B_{d2}). As the delay D_{2maxFast} used in this constraint considers the fast transitions, there is a hope that in most cases k will be equal to 1. Then, in this case, constraint (C_{d2})/(D_{d2}) will become D_{2minFast}>−T_{CK}−t_{rd}+τ+t_{ELh}. From the definitions of k and r, given earlier in this text, we have τ<T_{CK}. Thus, in this case, no particular care will be needed for satisfying constraint (C_{d2})/(D_{d2}).

To determine the worst-case duration of detectable faults, we will use the delay D_{DG}(Error!→Error)ₘₐₓ, which is the maximum delay of the (non-error) to (error) transition of the output of the dynamic gate. For instance, if the dynamic gate is an OR gate (i.e. like the gate of FIG. 13.c), the delay D_{DG}(Error!→Error)ₘₐₓ is the discharging delay (1→0) of the output node of the dynamic NOR gate plus the delay of the 0→1 transition of the output node of the output inverter 80. We will also use the delay D₁(Error!→Error)ₘₐₓ, which is the maximum delay of the propagation of the (non-error) to (error) transition through the comparator part connecting the inputs of the comparator to the inputs of the dynamic gates (to be referred hereafter as part 1 of the comparator). If the dynamic gate is an XOR gate (i.e. like the gate of FIG. 13.a), the delay D_{DG}(Error!→Error)ₘₐₓ is the delay of the 0→1 transition of the output node of the inverter driven by one of the gate inputs (input Inᵢ or input Oᵢ) plus the discharging delay of the output node of the dynamic XNOR gate plus the delay of the 0→1 transition of the output node of the output inverter 80. Also if the dynamic gates are the XOR gates of the comparator the delay D₁(Error!→Error)ₘₐₓ will be equal to 0. Then, as our goal is to determine the worst-case duration of detectable faults, we have to consider the worst-case delay of error detection. Thanks to the constraint (B_{d2}) and (C_{d2})/(D_{d2}), the Error Latch 40 captures at the cycle i+k the result of the comparison corresponding to the values provided at the output of the dynamic gates at the instant τ_{fd} of cycle i+1. If there is a discrepancy between the inputs and the outputs of the regular flip-flops FF2 20, an error indication will reach the outputs of the dynamic gates after a time that will not exceed D₁(Error!→Error)ₘₐₓ+D_{DG}(Error!→Error)ₘₐₓ. Thus, this error indication is the result of the comparison of the values present on the inputs and outputs of the regular flip-flops FF2 20 at an instant tc>τ_{fd}−D₁(Error!→Error)ₘₐₓ−D_{DG}(Error!→Error)ₘₐₓ of cycle i+1 (the case where instant tc is larger than the second part of this relation, is when the delay of error detection is less than the worst case delay considered in this part). As in fault-free operation, the values present on the inputs of the regular flip-flops FF2 20 are ready at a time D_{FFsu} before the rising edge of Ck, then, the values present on these inputs at the instant τ_{fd}−D₁(Error!→Error)ₘₐₓ−D_{DG}(Error!→Error)ₘₐₓ are guaranteed to be correct for any delay fault of duration not exceeding the value τ_{fd}−D₁(Error!→Error)ₘₐₓ−D_{DG}(Error!→Error)ₘₐₓ+D_{FFsu}. Thus, any delay fault affecting the values captured by the regular flip-flops FF2 20 is guaranteed to be detected if its duration does not exceed this value. Thus, the duration □ of detectable faults, guaranteed to be detected by the proposed design, is given by the following relation

δ=τ_{fd}+D_{FFsu}−D₁(Error!→Error)ₘₐₓ−D_{DG}(Error!→Error)ₘₐₓ (E_{d})

Then, if we use the maximum value of τ_{fd} (i.e. τ_{fd}=(Dₘᵢₙᵢ+D₁ₘᵢₙᵢ)ₘᵢₙ allowed by constraint (C_{d1}), relation (Ed) gives δ=(Dₘᵢₙᵢ+D₁ₘᵢₙᵢ)ₘᵢₙ+D_{FFsu}−D₁(Error!→Error)ₘₐₓ−D_{DG}(Error!→Error)ₘₐₓ.

The enforcement of the constraints derived above, can be done in the following manner. First, the designer determines the target duration of detectable faults; then uses relation (E_{d}) to determine the value of τ_{fd}; then selects a value for τ_{rd} satisfying (B_{d1}) (preferably the minimum value τ_{rd}=D_{FFmax}+D₁ₘₐₓ allowed by this constraint); then based on constraint (B_{d2}) it computes the integer part I and the fractional part F of (D_{2maxFast}+τ_{fd}+t_{ELsu})/T_{CK}, and use them in the process P1, presented earlier in this text, to determine the values of k and τ; then, if there are paths in the part of the comparator comprised between the inputs of the dynamic gates and the inputs of the Error Latch 40 (i.e. the part 2 of the comparator), which do not obey (C_{d2})/(D_{d2}), she/he enforces this constraint by adding buffers in these paths; then, if there are paths connecting the outputs of the regular flip-flops FF1 21 to the inputs of the dynamic gates of the comparator, which do not obey (C_{d1}), she/he enforces this constraint by adding buffers in the part of these paths belonging to the Combinational Circuit 10 and/or in the comparator part comprised between the inputs of the XOR gates and the inputs of the dynamic gates (i.e. the part 1 of the comparator).

Note that, if set-reset latches are used instead of dynamic gates, then, constraint (B_{d1}) is replaced by D_{FFmax}+D₁ₘₐₓ≤τ_{rd}−t_{SRsu}, constraint (A_{d1}) is replaced by (Dₘₐₓᵢ+D₁ₘₐₓᵢ)ₘₐₓ<T_{CK}+τ_{rd}−t_{SRsu}, constraint (C_{d1}) is replaced by (Dₘᵢₙᵢ+D₁ₘᵢₙᵢ)ₘᵢₙ≥τ_{fd}+t_{SRh}, and relation (H_{d}) is replaced by T_{Hd}≤(Dₘᵢₙᵢ+D₁ₘᵢₙᵢ)ₘᵢₙ−D₁ₘₐₓ−D_{FFmax}−t_{SRsu}−t_{SRh} (where t_{SRsu} is the setup time and t_{SRh} is the hold time of the set-reset latch).

Furthermore, in this case constraint (B_{d2}) becomes τ_{fd}+D_{2maxFast}+D_{SRmax}<(k−1)T_{CK}+τ−t_{ELsu} and constraint (C_{d2})/(D_{d2}) becomes D_{2minFast}+D_{SRmin}>(k−2)T_{CK}−τ_{rd}+τ+t_{ELh} (where D_{SRmax} and +D_{SRmin} are the maximum and minimum delays of the set-reset latch, and in this case, D_{2maxFast} and D_{2minFast} are the maximum and minimum delays of the fast transitions of the comparator part comprised between the outputs of the set-reset latches and the input of the Error Latch. Finally relation (E_{d}) providing the duration δ of detectable faults is replaced by δ=τ_{fd}+D_{FFsu}−t_{SRsu}−D₁(Error!→Error)ₘₐₓ−D_{DG}(Error!→Error)ₘₐₓ.

Note also that using a stage of dynamic gates or set-reset latches creates a barrier that blocks hazards, so that the part 2 of the Comparator is hazards-free and we can consider for this part the delays of fast transitions for determining the instant the Error-Latch 40 latches the error indication signal. Then, another way to create this kind of barrier is to insert in the Comparator a stage of latches which are transparent during the high level of clock signal Ck_{d}, and opaque during its low level.

It is also worth noting that, as dynamic gates, set-reset latches, and transparent latches are clocked, inserting in the comparator a stage of any of these circuits will consume more power than an implementation of the comparator using only static gates. Nevertheless, in the case of dynamic gates some reduction of this power is possible by using different signals to clock the precharge transistor (Mp) and the evaluation transistor (Me) of the dynamic gates. Indeed, as observed in [10] the signal clocking the precharge transistor needs to undergo a transition to turn on the precharge transistor only after error detection. Then, it will undergo the opposite transition to turn off the precharge transition and will stay at this state until the next error detection. Note also that, a similar power reduction can be achieved if a stage of set reset latches is employed instead of the stage of dynamic gates. In this case, in the set-reset latch of FIG. 14.a, instead of using signal Ck_{d}! to drive the reset signal R of the set-reset latch, we can use a signal that stays low as long as no error occurs, and goes high after error detection, during the low level of Ck_{d} of a clock cycle, in order to reset Q and Q! to the values Q=0 and Q!=1, and then goes low and stays at this level as far as no error detection occurs. Similarly, in FIG. 14.c, instead of using signal Ck_{d} to drive the set signal S, we can use a signal that stays high as long as no error occurs, and goes low after error detection, during the low level of Ck_{d} of a clock cycle, in order to set Q and Q! to the values Q=1 and Q!=0. The extra power of the stage of dynamic gates, of set-reset latches, or transparent latches, can also be reduced significantly by implementing this stage several gate levels after the inputs of the comparator, so that the number of clocked elements is reduced significantly. Yet another way to reduce the number of clocked dynamic gates, consists in using dynamic gates with larger number of inputs than the dynamic gates shown in FIG. 13. For instance, FIG. 13.c shows a 2-input dynamic OR gate. This gate uses a network of two parallel n-transistors fed by the two inputs x and y of the gate and one n-transistor, plus one p-transistor fed by the clock signal Ckd. We can similarly implement a k-inputs dynamic OR gate, by using a network of k parallel n-transistors fed by the k inputs of this gate, plus one p-transistor fed by the clock signal Ckd. Then, if we replace q 2-input dynamic OR gates by one 2q-inputs dynamic gate, in the first case the clock signal Ckd will feed one n-transistor and one p-transistor in each 2-input OR gate (i.e. a total of q n-transistors and q p-transistors), while in the second case, the clock signal Ckd will feed a total of only one n-transistor and one p-transistor. Similarly, if instead of using q dynamic XOR gates comparing one pair of signals Ini and Oi, we use dynamic XOR gates comparing q pairs of signals Ini and Oi, we will divide by q the number of transistors fed by the clock signal Ckd.

Note finally that, adding a stage of dynamic gates in the comparator-tree increases the sensitivity of the comparator to ionizing particles, which will increase the occurrence rate of false alarms. In addition, many cell libraries do not provide dynamic gates. In this case, it will not be possible for the designer to insert dynamic gates in the comparator-tree. On the other hand, using a pipelined comparator or a stage of Set-Reset latches in the comparator-tree, may not be desirable, as it will induce significant area and power cost and also due to the sensitivity of latches and flip-flops to soft-errors, which will increase the rate of false alarms. An alternative solution, which resolves these issues, consists in replacing in the comparator tree a stage of gates (e.g. a stage of inverters, a stage of NOR gates, a stage of NAND gates, a stage of XNOR gates), by a stage of static gates able to block the propagations of hazards (to be referred hereafter hazards-blocking static gates). These gates will have the following properties: one input of each of each of these gates is fed by the clock signal Ckd; when Ckd=1 the hazards-blocking static gates realizes the same function as the gate it replaces; and when Ckd=0, the output of the static gate is forced in the non-error state. As an example, in the comparator of FIG. 10.a, the outputs of each stage of NOR gates feed a stage of inverters. When all inputs of the comparator are equal, the outputs of all XOR gates of the comparator are 0; the outputs of all NOR gates in the comparator-tree are 1; and the outputs of all inverters are 0. Thus, the non-error state of the inverters' outputs is 0. Then, we can replace each inverter 1 in one of the inverter stages of the comparator-tree by a hazards-blocking static two-input NOR gate. The one input of each of these hazards-blocking static NOR gates is the same as the input of the inverter 1 it replaces (i.e. it comes from the output of the NOR-gate 2 that was feeding the input of this inverter in FIG. 10.a), and the second input of each of the hazards-blocking NOR gates is the signal Ckd!, which is the inverse of clock signal Ckd. Thus, when Ckd=1 each of these hazards-blocking NOR gates realizes the same function as the inverter it replaces, and also, similarly to the dynamic gates of FIG. 13, when Ckd=0 the output of each hazards-blocking NOR gate is 0. Hence, by replacing one stage of inverters by one stage of such NOR gates, on the one hand the function of the comparator remains unchanged when Ckd=1, and on the other hand when Ckd=0 the outputs of the NOR gates are forced to the non-error state (i.e. to 0), and prevent hazards from affecting the outputs of the hazards-blocking NOR gates and the subsequent part of the comparator. Those skilled in the art will readily see that the proposed solution, which accelerates the comparator by introducing in the comparator-tree a stage of static gates that block the propagation of hazards at the second part of the comparator, can be implemented in various other ways. As an example, instead of replacing in the comparator a stage of inverters by a stage of hazards-blocking two-input static NOR gates, as described above, we can replace a stage of NOR gates by a stage of OR-AND-INVERT gates. For instance, a 2-inputs NOR gate realizing the function NOT(X1 OR X2) can be replaced by a 2-1 OR-AND-INVERT gate realizing the function NOT[(X1 OR X2)Ckd]. More generally, a k-inputs NOR gate realizing the function NOT(X1 OR X2 OR . . . Xk) can be replaced by a k−1 OR-AND-INVERT gate realizing the function NOT[(X1 OR X2 OR . . . Xk)Ckd]. An illustration of a 4-1 OR-AND-INVERT gate realizing the function NOT[(X1 OR X2 OR X3 OR X4)Ckd] replacing a four-inputs NOR gate realizing the function NOT(X1 OR X2 OR X3 OR X4) is given in FIG. 26. These gates have the properties of the hazards-blocking gates described earlier. Indeed, when Ckd=0, the output of the gate is forced to the 1 value, which is the non-error sate for the NOR gates of the comparator, and when Ckd=1 the function of the k−1 OR-AND-INVERT is identical to function of the k-inputs NOR gate. Similarly, we can replace k-inputs NAND gates by k−1 AND-OR-INVERT gates, but the k−1 OR-AND-INVERT gates are preferable, as they are much faster for the non-error to the error transitions. An important interest for these gates concerns the power dissipation of the comparator. Similarly to the dynamic gates, as the clock signal feeds each k−1 OR-AND-INVERT gate, there is a significant power cost if we use a large number of such gates. Similarly to the implementation using a stage of dynamic gates, a way to reduce the number of OR-AND-INVERT gates and the related power cost, consists in introducing the stage of these gates several gate levels after the inputs of the comparator. However, the further we introduce this stage from the comparator inputs, the lower is the improvement of the comparator speed. As shown in the implementation using a stage of dynamic gates, a way to reduce the number of dynamic gates without moving them apart from the comparator inputs, consists in using k-inputs dynamic gates with a large value k. The similar improvement is achieved by using k−1 OR-AND-INVERT gates with large number k. Note finally that, similarly to the approach inserting in the comparator a stage of dynamic gates, the approach inserting a stage of OR-AND-INVERT gates divides the comparator in two parts: the part 1 consisting in the comparator part comprised between the inputs of the comparator and the inputs of the OR-AND-INVERT gates; and the part 2 comprised between the inputs of the OR-AND-INVERT gates and the input of the Error Latch. These parts have similar properties as in the approach using dynamic gates, and all the implementation constraints and improvements presented earlier for the approach using dynamic gates, are also valid for the approach using OR-AND-INVERT gates.

Another important issue is that the above implementations enable allocating in the hazards-free part of the comparator shorter time than its worst case delays (i.e. the time corresponding to the propagation of Error!→Error transitions which is must faster than the Error→Error! transitions), but this works properly as long as no-errors occur, in the hazards-free part of the comparator the slow Error→Error! transitions do not occur in this part of the comparator. Nevertheless, after the detection of an error, the slow Error→Error! transition will occur, which requires allocating more time for its propagation. However, the above described comparator implementations using a stage of set-rest latches or of dynamic gates or of hazards-blocking static gates, intrinsically allocate longer time to these transitions. Indeed, the propagation of fast Error!->Error transitions can start in these implementations only after the rising edge of the clock signal Ckd, but the propagation of the slow Error→Error! transitions start at the falling edge of the signal Ckd, because when Ckd=0, the outputs of the dynamic gates, as well as of the hazards-blocking static gates, and of the set-reset latches are set to the non-error (Error!) state. Thus, the an extra time equal to the low level of the Ckd signal is allocated to the slow Error→Error! transitions. In most cases, this significant extra time should be sufficient for compensating the increased delays of the comparator for the slow Error→Error! transitions. Furthermore, in designs where this is not the case, after an error detection we can allocate longer time in the comparator, as proposed in the approach using pipelined comparator. The latest solution can be used to allocate to the hazards-free part of the comparator as much time as desired for the propagation of the slow Error-Error!transitions, that is:
After error detection, we can adapt the clock signals to provide the extra time required for the propagation of the slow transitions.
Alternatively, we can design the system in a manner that, after error detection, it is acceptable for the Error Latch not to return to the error-free indication at the first cycle at which the circuit returns to the error free state, but return to this indication after few clock cycles.

The possibility after each error detection to allocate to the hazards-free part of the comparator as much time as desired for the propagation of the slow Error→Error!transitions, allows to further increase the speed of the hazards-free part of the comparator. In fact, as the k-input static NOR gate employs a network of k serial p-transistors, the delay for the 0→1 transistor increases significantly with the increase of k, while the delay of the 1→0 transition on the gate output increases sub-linearly to the increase of k, as the k-input static NOR gate employs a network of k parallel n-transistors. Furthermore, increasing the number of the NOR-gates inputs will decrease linearly the number of NOR-gates and inverters stages of the OR tree. Thus, increasing the number of inputs of the static NOR gates, will increase drastically the delay of the OR tree for the 0→1 transition and will decrease significantly the delay for the 1→0 transition. Thus, the maximum delay of the OR-tree increases drastically by increasing the number of inputs of the NOR-gates, which is inefficient in comparator implementation preexisting to the present invention. However, for the comparators using a hazards-free part as proposed in this invention, we observe that: the 1→0 transition on the NOR-gate output of an OR-tree, is the fast Error!→Error transition, and the 0→1 transition is the slow Error→Error! transition. Thus, increasing the number of inputs of the static NOR gates in the hazards-free part of the comparator allows to reduce significantly the time allocated to the comparator during the normal operation and until an error detection (i.e. the time τ_{rd} separating the rising instant of clock signal Ckd from the rising instant of clock signal Ck), accelerating significantly the activation of the error detection signal. On the other hand, the inconvenient of this choice is that it increases drastically the time required for the Error→Error! transitions, but as it was seen in the previous paragraph, the use of a stage of dynamic gates or of set-reset latches allocates to these transitions an extra time equal to the low level of the clock signal Ckd, and more importantly, the Error→Error! transitions occur after the occurrence of error detection and after this occurrence we can increase at will the time allocated to the comparator for propagating the slow transition Error→Error!.

Note finally that when we derived the constraints (A), (B), (C), (D) and (E), as well as their instantiations (i.e. constraints (A1), (B1), (C1), (D1) and (E1); (A2), (B2), (C2), (D2) and (E2); (B3), (C3), (D3) and (E3); (A-H), (B-H), (C-H), (D-H) and (E-H); etc), we considered that the Comparator 30 was not pipelined. Those skilled in the art will readily understand that: if the comparator is pipelined, then, we can consider that each flip-flop FF_{fpj} of the first pipe-line stage of the comparator is the Error Latch 40 for the subset RFj of the regular flip-flops FF2 20 that are checked by the part of the comparator feeding flip-flop FF_{fpj}. Then, let us consider a circuit part CPj composed of: such a subset of regular flip-flops RFj; the combinational circuit CCj feeding this subset of regular flip-flops; the part of the comparator CMPj, which checks this subset of regular flip-flops and feeds the input of FF_{fpj}; and the flip-flop FF_{fpj} (which is considered, as mentioned above, as the Error Latch for the circuit part CPj). Then, those skilled in the art will readily understand that each circuit part CPj, determined as above, obeys the structure of the double-sampling architecture of FIG. 3. Thus, to implement each circuit part CPj, we can use the constraints (A), (B), (C), (D), and (E) and more precisely their instantiation corresponding to this circuit part. In the similar manner, if, in the comparator implementation using a stage of dynamic gates, the part of the OR tree or AND tree, which is between this stage of dynamic gates and the Error Latch 40, is pipelined, then, we can consider each flip-flop FF_{fpj} of the first stage of this pipe-line as an Error Latch, and associate to it a circuit part CPj similarly to the above, and then use the constraints (A_{d1}), (B_{d1}), (C_{d1}), (H_{d}), (B_{d2}), (C_{d2})/(D_{d2}), and (E_{d}) to implement it.

### Reducing Buffers' Cost and Comparator's Delay for Architectures not Using Redundant Sampling Elements

Existing double-sampling architectures are based on circuit constraints concerning the global maximum and/or minimum delays of certain blocs ending to or starting from the flip-flops checked by the double-sampling scheme. An improvement of the architectures proposed in this patent consists in considering the individualized sums or differences of maximum and/or minimum delays of the combinational logic and the comparator, which enable significant optimizations of these double-sampling architectures. For instance this is possible for the architecture illustrated in FIGS. 2, 3, . . . 9, because we have removed the redundant latches and there are paths of the combinational logic connected directly to the comparator, resulting in constraints using the sum of the delays of paths traversing the combinational logic and of paths traversing the comparator.

In constraints (A) and (C), instead of the terms (Dₘₐₓᵢ+D_{CMPmaxi})ₘₐₓ and (Dₘᵢₙᵢ+D_{CMPmini})ₘᵢₙ we can also use the terms Dmax+D_{CMPmax} and Dmin+D_{CMPmin}, resulting in the constraints

Dmax+D_{CMPmax}<kT_{CK}+τ−t_{ELsu} (A-gm)

Dmin+D_{CMPmin}>(k−1)T_{CK}+τ+t_{ELh} (C-gm)

Constraints (A-gm) and (C-gm) also guaranty flawless operation for long-paths and short paths, and are simpler to handle than constraints (A) and (B), as they employ the sum of the global minimum (respectively global maximum) delays of the Comparator 30 and the global minimum (respectively global maximum) delay of the paths connecting the inputs of regular flip-flops FF1 21 to the inputs of the regular flip-flops FF2 20 checked by the Comparator 30, instead of the terms (Dₘₐₓᵢ+D_{CMPmaxi})ₘₐₓ and (Dₘᵢₙᵢ+D_{CMPmini})ₘᵢₙ. However, as we have Dmax+D_{CMPmax}>(Dₘₐₓᵢ+D_{CMPmaxi})ₘₐₓ, and Dmin+D_{CMPmin}<(Dₘᵢₙᵢ+D_{CMPmini})ₘᵢₙ, (A-gm) and (C-gm) are more constrained than (A) and (C). Thus, enforcing (C-gm) will require higher cost for buffer insertion in short paths than enforcing (C), and enforcing (A-gm) will require higher delay for the error detection signal than enforcing (A). This advantage of the double-sampling architecture of FIG. 3 is due to the fact that it does not uses redundant sampling elements, as do the architecture of FIG. 1. This advantage is further exploited hereafter for further reducing buffer cost required to enforce the short paths constraint, and for also reducing the delay of the comparator.

Another way to ensure flawless operation for the architecture of FIG. 3, consists in expressing and enforcing relations (A), (D), and (E) for each individual regular flip-flop FF2 20, resulting in the constraints:

Dₘₐₓᵢ+D_{CMPmaxi}<kT_{CK}+τ−t_{ELsu} (A-in)

D_{FFmax}+D_{CMPmax}<(k−1)T_{CK}+τ−t_{ELsu} (B)

Dₘᵢₙᵢ+D_{CMPmini}>(k−1)T_{CK}+τ+t_{ELh} (C-in)

D_{CMPmin}>(k−2)T_{CK}+τ+t_{ELh} (D)

δᵢ=(k−1)T_{CK}+τ−D_{CMPmaxi} (E-in)

Similarly, for the architecture of FIG. 5, constraints (A-H), (C-H), and (E-H), can be individualized as

Dₘₐₓᵢ+D_{CMPmaxi}<kT_{CK}+T_{H}+ω−t_{ELsu} (A-Hin)

Dₘᵢₙᵢ+D_{CMPmini}>(k−1)T_{CK}+T_{H}+ω+t_{ELh} (C-Hin)

δᵢ=(k−1)T_{CK}+T_{H}+ω−D_{CMPmaxi} (E-Hin)

From (E-in) we find δᵢ+D_{CMPmaxi}−(k−1)T_{CK}+τ. Thus, the sum δᵢ+D_{CMPmaxi} takes the same value for any individual flip-flop i. In the similar manner, (E-Hin) implies that the sum δᵢ+D_{CMPmaxi} takes the value (k−1)T_{CK}+T_{H}+ω for any individual flip-flop i.

Thanks to this observation, we can use for different flip-flops FF2 20 different values of δᵢ and of D_{CMPmaxi}, as far as their sum is equal to (k−1)T_{CK}+τ for the architecture of FIG. 3, or equal to (k−1)T_{CK}+T_{H}+ω for the architecture of FIG. 5. This flexibility provides a wide space for optimizing the design in order to reduce the area and power cost consumed by the buffers required to enforce the short path constraint (C-in) for FIG. 3 or (C-Hin) for FIG. 5, and also to reduce the delay of the error detection signal produced by the comparator.

To illustrate these additional advantages that can be achieved by the proposed double-sampling architecture of FIG. 3, let us consider the circuit example presented in table 1.

TABLE 1
Circuit example

| | O₁ | O₂ | O₃ | O₄ | O₅ | O₆ | O₇ | O₈ | O₉ | O₁₀ | O₁₁ | O₁₂ | O₁₃ | O₁₄ | O₁₅ | O₁₆ | O₁₇ | O₁₈ |
|---|---|---|---|---|---|---|---|---|---|---|---|---|---|---|---|---|---|---|
| Dₘₐₓᵢ | 100 | 100 | 95 | 95 | 92 | 88 | 84 | 84 | 78 | 75 | 75 | 66 | 64 | 62 | 62 | 58 | 58 | 54 |
| Dₘᵢₙᵢ′ | 26 | 31 | 55 | 21 | 35 | 43 | 31 | 35 | 28 | 30 | 25 | 29 | 32 | 21 | 44 | 20 | 17 | 25 |
| Dfᵢ | 50 | 50 | 47.5 | 47.5 | 46 | 44 | 42 | 42 | 39 | 37.5 | 37.5 | 33 | 32 | 31 | 31 | 29 | 29 | 27 |
| δᵢ | 50 | 50 | 42.5 | 42.5 | 38 | 32 | 26 | 26 | 17 | 12.5 | 12.5 | −1 | −4 | −7 | −7 | −13 | −13 | −19 |
| Dᵢ′ < 52 | 26 | 31 | — | 21 | 35 | 43 | 31 | 35 | 28 | 25 | 19 | — | — | — | — | — | — | — |
| | 38 | 44 | | 39 | 41 | | 37 | 41 | 34 | 29 | 23 | | | | | | | |
| | | 49 | | | | | 40 | | 42 | | 30 | | | | | | | |

TABLE 2
Implementation of the Standard Double-Sampling Architecture (FIG. 1)

| | O1 | O2 | O3 | O4 | O5 | O6 | O7 | O8 | O9 | O10 | O11 | O12 | O13 | O14 | O15 | O16 | O17 | O18 |
|---|---|---|---|---|---|---|---|---|---|---|---|---|---|---|---|---|---|---|
| δ + t_{ELh} | 52 | 52 | 52 | 52 | 52 | 52 | 52 | 52 | 52 | 52 | 52 | 52 | 52 | 52 | 52 | 52 | 52 | 52 |
| Buffers_Dₘᵢₙᵢ | 26 | 21 | — | 31 | 17 | 9 | 21 | 17 | 24 | 27 | 33 | — | — | — | — | — | — | — |
| | 14 | 83 | | 13 | 11 | | 15 | 11 | 18 | 23 | 29 | | | | | | | |
| | | | | | | | 12 | | 10 | | 22 | | | | | | | |

TABLE 3
Implementation of the New Double-Sampling Architecture (FIG. 2)

| | O1 | O2 | O3 | O4 | O5 | O6 | O7 | O8 | O9 | O10 | O11 | O12 | O13 | O14 | O15 | O16 | O17 | O18 |
|---|---|---|---|---|---|---|---|---|---|---|---|---|---|---|---|---|---|---|
| δᵢ | 50 | 50 | 42.5 | 42.5 | 38 | 32 | 26 | 26 | 17 | 12.5 | 12.5 | | | | | | | |
| D_{CMPmaxi} | 15 | 15 | 22.5 | 22.5 | 27 | 33 | 39 | 39 | 48 | 52.5 | 52.5 | | | | | | | |
| δᵢ + D_{CMPmaxi} | 65 | 65 | 65 | 65 | 65 | 65 | 65 | 65 | 65 | 65 | 65 | | | | | | | |
| D_{CMPmini} | 12 | 12 | 17.4 | 17.4 | 20.5 | 24.8 | 29 | 29 | 35.9 | 39 | 39 | | | | | | | |
| Dₘᵢₙᵢ + D_{CMPmini} | 67 | 67 | 67 | 67 | 67 | 67 | 67 | 67 | 67 | 67 | 67 | | | | | | | |
| Buffers_Dₘᵢₙᵢ | 29 | 24 | — | 28.6 | 11.5 | 0 | 7 | 3 | 3.1 | 3 | 9 | — | — | — | — | — | — | — |
| | 17 | 11 | | | | | 1 | 0 | 0 | 0 | 5 | | | | | | | |
| | | 6 | | 10.6 | 5.5 | | 0 | | 0 | | 0 | | | | | | | |
| δeffi = τ − D_{cmpi} | 50 | 50 | 42.5 | 42.5 | 38 | 32 | 26 | 26 | 17 | 12.5 | 12.5 | — | — | — | — | — | — | — |

For each regular flip-flop i protected by the double sampling scheme of FIG. 3, the duration □ᵢ of detectable faults is the amount of delay of the circuit paths feeding flip-flop i, that exceeds the value Tck−t_{FFsu}. The most prominent failure modes affecting advanced nanometric fabrication processes, such as process, voltage and temperature variations, circuit aging related faults such as BTI and HCl, etc, produce delay faults. Such faults may increase the delay of the affected circuit path beyond the value Tck−t_{FFsu} and induce errors. The duration of faults affecting different paths would be generally different. Furthermore, a delay fault affecting a path with low delay may not increase its delay beyond the clock period, and in any case, it will increase it less than a fault of same duration affecting a path with longer delay. Thus, the fault duration □ᵢ that should be detected in paths with short delays is usually shorter than the fault duration □ⱼ that should be detected in paths with short delays. This is exploited in practical implementations of the double sampling architectures, in order to reduce its cost by protecting only paths whose delay exceeds a certain value.

As for most failure modes different flip-flops must be protected for faults of different durations δᵢ, we can exploit the flexibility concerning the values of □ᵢ and D_{CMPmaxi}, identified above for the proposed double sampling architecture of FIGS. 3 and 5, in order to optimize the design.

The illustration example of table 1 considers a circuit with 18 flip-flops, whose outputs are designated as O1, O2, . . . O18 (and inputs as I1, I2, . . . I18). In this table, row Dmaxi gives the maximum delay for each signal Oi; row Dmini′ gives the minimum delay for each signal Oi before it is modified by adding buffers in order to enforce the short-path constraint (C-in). The delay values used in this illustration are normalized by using the value Dmax=100 for the delays of the critical paths of the circuit (i.e. the maximum delays of signals O1, and O2), which we consider to be equal to the maximum delay value Tck−t_{FFsu} for which the circuit operates correctly. We also consider the normalized values Tck=102 and t_{FFsu}=2.

In this illustration, we consider that, for the target failure modes, the delay of a path can be increased in the worst case by a delay equal to 50% of its fault-free delay. Thus, the values in row Dfᵢ (which gives the worst duration of the delay faults affecting each signal Oi), are computed as Dfi=0.5×Dmaxi. Then, in row δᵢ, the duration δᵢ of the fault that we should be able to detect in a signal Oi (i.e. how much the delay of this signal affected by a fault may exceed the value Tck−t_{FFsu}) is computed as δᵢ=Dmaxi+Dfi−100=1.5×Dmaxi−100.

We observe that under the above assumption (i.e. Dfi is proportional to Dmaxi), the values of δᵢ differ from one signal Oi to another, and this makes possible to optimize the implementation of the double-sampling architecture of FIG. 3, by exploiting the relation δᵢ+D_{CMPmaxi}=(k−1)T_{CK}+τ implied by constraint (E-in). Note however, that the similar optimization is possible in other scenarios. For instance, if the value of Dfi is the same for all signals Oi (i.e. Dfi=Df∀i), δᵢ is given by δᵢ=Dmaxi+Df−100. Thus, the values of δᵢ will also differ from one signal Oi to another.

In table 1, the values of δᵢ are negative for the signals O12 to O18, which means Dmaxi+Dfi<100. Thus, even in the presence of faults, the delay of any path in these signals will not exceed the value Tck−t_{FFsu}. Thus, we can leave unprotected these signals to reduce cost. Hence, in the following we consider only the protection of signals O1 to O11.

In the architecture of FIG. 1, to avoid clock signal proliferation, we should use the same clock signal Ck+δ for all redundant sampling elements 22. Furthermore, to detect all faults, including the fault of maximum duration δᵢmax, the delay added to the clock signal Ck in order to generate the clock signal Ck+δ, should be given by δ=δᵢmax=50. Then, the short path constraint implies Dmin>δ+t_{ELh}=δᵢmax+t_{ELh}, where t_{ELh} is the hold time of the redundant sampling elements 22. This constraint becomes Dmin≥δ+t_{ELh}, if δ is augmented to include some margin M_{LATE} that can be set by the designer to account for clock skews and jitter, and possibly some margin to take into account process variations that could decrease the value of Dmin. For simplicity, in this illustration we will ignore these margins, as the principles of the approach illustrated here do not depend on the exact value of δ. For normalized value t_{ELh}=2, we obtain Dmini≥52. To enforce this constraint we should add buffers to all paths having delays lesser than 52. The delays Dᵢ′ of these paths for each signal Oi are given in the row of table 1 labeled as Dᵢ′<52, and the delays of the buffers that should be added to these paths in order to enforce the short-paths constraints for the standard double-sampling architecture of FIG. 1 are given in the row of table 2 labeled as Buffers_Dmin₁. We observe that we have to add a significant amount of delays, which increase area and power cost. Thus, it is suitable to reduce this cost.

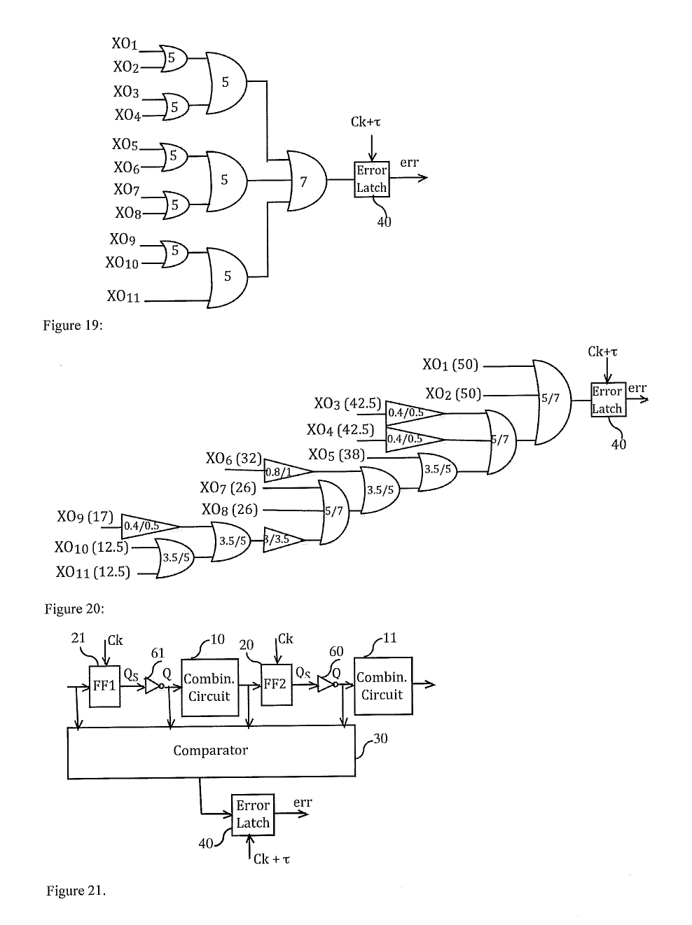

In the double sampling architecture of FIG. 1, the outputs of each pair of regular flip flop 20 and redundant sampling element 22 are compared by an XOR gate, let XO1, XO2, XO11 be the outputs of these XOR gates corresponding to the signals O1, O2, . . . O11. Then, the signals XO1, XO2, XO11, are compacted by an OR-tree into a single error detection signal, which is captured by a sampling element (Error Latch 40) rated by a clock signal Ck+τ. An implementation of this OR-tree is shown in FIG. 19. Let the minimum and maximum normalized delays of the 2-inputs and the 3-inputs OR gate, and the 2-inputs XOR gate be respectively equal to: 3.5 and 5 for the 2-input OR gate, 5 and 7 for the 3-input OR gate, and 7 and 8 for the 2-input XOR gate. Then, for these normalized maximum delays, shown inside the OR gates in FIG. 19, the normalized maximum delay of the OR tree is equal to 17, which gives D_{CMPmax}=25 for the normalized maximum delay of the comparator (XOR gates and OR tree). The value of τ is given by τ=δ+D_{CMPmax}+Dᵣₛ+t_{ELsu}, where Dᵣₛ is the Clk-Q delay of the redundant sampling element 22 and t_{ELsu} is the setup time of the Error Latch 40. Thus, considering Dᵣₛ=2 and t_{ELsu}=2, we obtain τ=79.

The OR tree shown in FIG. 19, can also be used for the case of the architecture of FIG. 3. However, the value of r determines the instant at which the error detection signal is activated. Many applications require performing error correction each time an error is detected. The implementation of the error correction scheme is often simpler if the errors are detected early enough, so that the circuit is halted before the errors are propagated to subsequent pipeline stages. Thus, it is suitable to reduce the value of τ. Hereafter, we illustrate how we can exploit the double sampling implementation of FIG. 3, in order to reduce this value as well as the cost of the buffer required to enforce the short-paths constraint.

For the double-sampling architecture of FIG. 3, relation (E-in) gives δᵢ+D_{CMPmaxi}=(k−1)T_{CK}+τ. Then, as the target duration of detectable faults differs from one regular flip-flop FF2 20 to another, we can implement an unbalanced comparator having shorter delays D_{CMPmaxi} for regular flip-flops FF2 20 requiring large durations of detectable faults, and larger delays D_{CMPmaxi} for regular flip-flops FF2 20 requiring short durations of detectable faults. Then, as we reduce the delay D_{CMPmaxi} for regular flip-flops FF2 20 requiring large values for δᵢ, this implementation will reduce the maximum value of δᵢ+D_{CMPmaxi}, which is equal to the delay of the error detection signal. Furthermore, from relation (E-in), for regular flip-flops FF2 20 requiring small values □ᵢ the maximum delay D_{CMPmaxi} of the corresponding path of the comparator increases. In addition, the maximum and minimum delays of OR-gates and thus of each path of the OR-tree are correlated, implying that D_{CMPmini} increases when D_{CMPmaxi} is increased. Thus, for regular flip-flops requiring small δᵢ, D_{CMPmini} increases. It results in the decrease of Dₘᵢₙᵢ, since from constraint (C-in) the value of Dₘᵢₙᵢ+D_{CMPmini} is constant. Thus, using unbalanced comparator implementation in the architecture of FIG. 3, allows also reducing the cost of the buffers required for enforcing the short paths constraint.

For the circuit example of table 1, the unbalanced implementation of the OR-tree is shown in FIG. 20. To improve readability, FIG. 20 shows within each OR gate its minimum and maximum delays, and also shows on each input of the OR-tree, the corresponding value δᵢ. In this unbalanced implementation we minimize the number of logic levels of the OR tree for the signals Oi that have the largest values δᵢ and increase the number of these levels for signals with decreased values δᵢ. This way, at a first step we reduce the differences between the sums δᵢ+D_{CMPmaxi} corresponding to different signals Oi by implemented an unbalanced OR tree, and at a second step we completely balance these sums by adding small delays in selected nodes of the OR tree. Thus, to make all these sums completely identical to each other, we also add buffers to increase the delays of some input signals Oi, and/or of some branches of the OR-tree, by preferably adding delays inside the OR, as in this way one delay may increase the delays of several comparator paths. This can be seen in FIG. 20, where, one delay of normalized value 3.5, added on the output of a two-inputs OR gate, increases by 3.5 the delay of three signals (O9, O10, and O11). Thus, using an unbalanced OR-tree, and, when additional delays are required, adding them preferably in the OR-tree branches, allows significant reduction of the cost required to balance the values of the sums δᵢ+D_{CMPmaxi}. Note also that balancing completely the values of the sums δᵢ+D_{CMPmaxi} is not mandatory. But as in this case the sums δᵢ+D_{CMPmaxi} take various values, we should pay attention which of these values we should use for computing the values of k and τ. Then, in order to ensure that we detect all faults not exceeding the target duration δᵢ associated to the affected signal Oi, we should determine the values of k and τ by employing the relation (δᵢ+D_{CMPmaxi})max=(k−1)T_{CK}+τ, which is the relations (E-in) corresponding to the maximum value of the sums δᵢ+D_{CMPmaxi}. Note also that, if the values of the sums δᵢ+D_{CMPmaxi} are not completely balanced, then, if a sum δᵢ+D_{CMPmaxi} corresponding to a signal Oi is smaller than the sums corresponding to other signals Oj, we will need to add more buffers in the short paths related to signal Oi. The advantage is an increase of the duration of detectable faults affecting Oi, but this increase will be beyond the target duration of detectable faults set by the designer for the signal Oi. So, this increase may not be very valuable. The drawback is a higher cost for compensating the unbalanced sums δᵢ+D_{CMPmaxi}, due to two reasons. First adding delays in the OR-tree for balancing the sums (δᵢ+D_{CMPmaxi}, will often allow using a single delay for balancing the sums δᵢ+D_{CMPmaxi} for several signals Oi. Thus, the cost will be higher if we have to compensate the missing delays of several unbalanced sums δᵢ+D_{CMPmaxi}, by adding buffers in the short paths of several signals Oi. Furthermore, for a signal Oi for which the value of the sum δᵢ+D_{CMPmaxi} is smaller than the value obtained from relation (E-in), we may need to add delays in several short paths of Oi for compensating it. This will result in higher cost than the one required for balancing the sums δᵢ+D_{CMPmaxi} by adding delays in the OR-tree.

The numerical results corresponding to the implementation of FIG. 20 are shown in table 3. In this table, the row labeled as Si gives the values of δᵢ for the signals O1 to O12, obtained in table 1. For O13 to O18, as for these signals the values of δᵢ in table 1 are negative, and these signals do not need to be checked. The row labeled D_{CMPmaxi} gives the values of D_{CMPmaxi}, obtained from the maximum delays of the OR-tree in FIG. 20, plus the maximum delay 8 of the XOR gate. The row labeled D_{CMPmin} gives the values of D_{CMPmin}, obtained from the minimum delays of the OR-tree in FIG. 20, plus the minimum delay 7 of the XOR gate. The row labeled δᵢ+D_{CMPmaxi} gives the values of the sum τ+D_{CMPmaxi}, obtained by summing the values of the rows δᵢ and D_{CMPmaxi}. Then, replacing in constraint (E-in) the values δᵢ+D_{CMPmaxi}=65 and Tck=102, gives k=1 and τ=65. Setting k=1, τ=65, and t_{ELh}=2 in constraint (C-in) gives Dₘᵢₙᵢ+D_{CMPmini}>67. This constraint can be written as Dₘᵢₙᵢ+D_{CMPmini}>67, if the values of δ_{I} used in (E-in) for computing z are augmented to include some margins M_{LATEi} that can be set by the designer to account for clock skews and jitter, and possibly some margins to take into account process variations that could decrease the value of Dmin. Then, similarly to the illustration given in table 2 for the architecture of FIG. 1, for simplifying the discussion, the illustration of the architecture of FIG. 3 given in table 3 will also ignore these margins, as the principles of the approach illustrated here do not depend on the precise values of δᵢ. The row labeled Buffers_Dₘᵢₙᵢ gives the values of the delays that have to be added in the short paths of the circuit for enforcing constraint (C-in). To compute these delays, we subtract from the value Dₘᵢₙᵢ+D_{CMPmini}=67, the values of the row labeled as Dₘᵢₙᵢ′ in table 1 and the values of the row labeled D_{CMPmini} in table 3.

As a last verification, note that row δ_{effi}=τ−D_{cmpi} in table 3 gives for each signal Oi the effective duration of detectable faults, resulting from this implementation. From the results shown in this row, we find that the effective durations of detectable faults are equal to those required by the target fault model, shown in row δᵢ of table 1.

From the results given in tables 2 and 3 we find that, the implementation of the architecture of FIG. 1 requires inserting in the short paths circuit buffers of a total delay equal to 415, while, the implementation of the architecture of FIG. 3, using the unbalanced XOR-tree of FIG. 20, requires inserting in the short paths of the circuit buffers of a total delay equal to 174.3, resulting in drastic reduction of buffers' cost. Furthermore, normalized delay of the error detection signal is equal to τ=79 for the architecture of FIG. 1. This delay is reduced to τ=65, for the architecture of FIG. 3 using the unbalanced OR-tree of FIG. 20. Thus, we obtained a reduction of the delay of the error detection signal equal to 14 normalized points. This is significant, as 10 of these 14 normalized points are obtained by reducing the delay of the OR-tree, whose normalized delay is equal to only 17 normalized points for the implementation of the architecture of FIG. 1. Thus, we obtained a 58.8% reduction of the delay of the OR-tree. This highlights that, in the illustration example used here, the amount of the total delay reduction for the error detection signal is not significant (i.e. 65/79=8.23%). However, the reduction of the delay of the OR-tree is drastic, which implies a significant reduction of the total delay, for implementations checking large numbers of regular flip-flops FF2 20.

The efficient implementation of the OR-tree for the architecture of FIG. 3, described above, is based on the constraints (E-in) and (C-in):
First, the constraint (E-in), implies that the delay of the error detection signal is determined by the sum δᵢ+D_{CMPmaxi}, and allows reducing this delay by reducing the delay D_{CMPmaxi} for signals Oi requiring large values for δᵢ.
Second, from relation (E-in), for signals Oi requiring small values δᵢ, the delay D_{CMPmaxi} of the corresponding path of the comparator increases. In addition, the maximum and minimum delays of OR-gates, and thus of each path of the OR-tree, are correlated, implying that D_{CMPmini} increases when D_{CMPmaxi} is increased. Thus, for regular flip-flops requiring small δᵢ, D_{CMPmini} increases. It results in the decrease of Dₘᵢₙᵢ, since from constraint (C-in) the value of Dₘᵢₙᵢ+D_{CMPmini} is constant, reducing the cost of the buffers required for enforcing the short paths constraint.

As the sums δᵢ+D_{CMPmaxi}, and Dₘᵢₙᵢ+D_{CMPmini}, are also used in relations (E-Hin) and (C-Hin), the proposed optimization using unbalanced OR trees, can be used in the similar way to optimize the implementation of the architecture of FIG. 5.

Concerning the implementation where the comparator uses a stage of dynamic gates proposed in the previous section, the constraints (C_{d1}) and (E_{d}) can be expressed for each individual signal Oi, giving:

Dₘᵢₙᵢ+D₁ₘᵢₙᵢ≥τ_{fd} (C_{d1}-in)

δᵢ=τ_{fd}+D_{FFsu}−D₁ₘₐₓᵢ−D_{DG}(Error→Error!)ₘₐₓ (E_{d}-in)

Constraint (E_{d}-in) gives δᵢ+D₁ₘₐₓᵢ=τ_{fd}+D_{FFsu}−D_{DG}(Error→Error!)ₘₐₓ. Thus, for the comparators using a stage of dynamic gates, we have two relations in which the second parts are constant for all signals Oi, and the first parts are the sums Dₘᵢₙᵢ+D₁ₘᵢₙᵢ and δᵢ+D₁ₘₐₓᵢ. These sums are similar to the sums Dₘᵢₙᵢ+D_{CMPmini} and δᵢ+D_{CMPmaxi}, used in constraints (C-in) and (E-in), except the fact that in (C_{d}-in) and (E_{d}-in) the terms D₁ₘᵢₙᵢ and D₁ₘₐₓᵢ concern the part of the comparator comprised between the inputs of the XOR gates and the inputs of the stage of dynamic gates of the comparator, while the terms D_{CMPmini} and D_{CMPmaxi} in constraints (C-in) and (E-in) concern the whole comparator. Consequently, the unbalanced implementation of the comparator presented in this section, can also be used in the case of comparators using a stage of dynamic gates, in order to reduce the impact on the delay of the error detection signal, of the comparator part comprised between the inputs of the XOR gates and the inputs of the stage of dynamic gates of the comparator, and also reduce the cost of the buffers that should be inserted in the short paths for enforcing the short paths constraint C-in).

It is worth noting that, in the comparators using a stage of dynamic gates, proposed in the previous section, the part of the comparator that is comprised between the inputs of the dynamic gates and the input of the Error Latch 40 is fast (i.e. its delay is determined by fast transitions only), while the part comprised between the inputs of the XOR gates and the inputs of the dynamic gates is slow. Thus, using the approach presented in this section, to reduce the impact of the delay of this part on the delay of the error detection signal can be valuable. The same observation holds in the case of pipelined comparators proposed in the previous section, where the part of the comparator comprised between the inputs of the XOR gates and the inputs of the first stage of flip-flops of the pipelined comparator, is also slow. Then, we can use for this part too, the implementation proposed in this section to reduce its impact on the delay of the error detection signal. Note also that, when we use a pipelined comparator, the number of flip-flops of the pipeline is reduced exponentially as we move away from the inputs of the comparator. Thus, when we implement this approach, we have interest to move the first pipeline stage away the inputs of the comparator to reduce cost. But moving away from the inputs of the comparator, will impact its delay, as the part of the comparator ahead the first pipeline stage is slow. Thus, using the approach proposed in this section to mitigate this delay is valuable for improving cost versus delay tradeoffs. The similar is valid for the implementations proposed in the previous section using dynamic gates, as the number of these gates is reduced exponentially as we move away from the inputs of the comparator. Then, as each dynamic gate is rated by the clock, reducing their number is valuable for reducing power dissipation. Thus, in this case too, using the approach proposed in this section to mitigate the delay of the part of the comparator that is ahead the dynamic gates is valuable for improving power versus delay tradeoffs.

Note finally that, in the example of FIG. 20, which illustrates the use of an unbalanced comparator for reducing the area and power cost consumed by the buffers required to enforce the short-paths constraint (C-in) for FIG. 3 or (C-Hin) for FIG. 5, and also to reduce the delay of the error detection signal generated by the comparator, we considered only the delays of the gates composing the comparator. However, the delays of the comparator paths may also depend on the delays of the interconnections. Thus, we can also consider the interconnect delays when implementing a comparator having paths with unbalanced delays, for reducing the cost required to enforce constraints employing the sum or the difference of the delays of paths of the combinational logic and of the comparator.

### Mitigating Metastability

If under a timing fault a transition occur in the input of a regular flip-flop FF1 21 FF2 20, during the setup or time, the master latch of a flip-flop may become metastable at the rising edge of the clock signal Ck, which may affect the error detection capabilities of the double-sampling architecture [8-10]. Thus, to cope with this issue, references [8][9] add a metastability detector on the output of each flip-flop checked by the comparator.

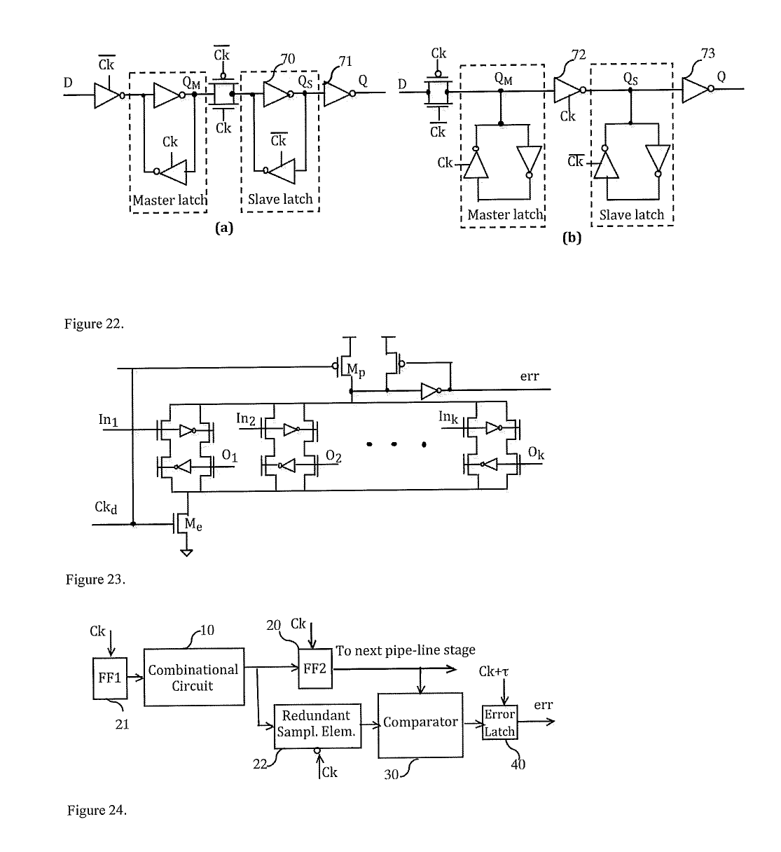

To illustrate the effects of metastability, let us consider the double-sampling implementation of FIG. 21 and the D flip-flop designs of FIGS. 22.a and 22.b.

As the master latch of a regular flip-flop FF1 21 FF2 20 becomes metastable at the rising edge of the clock signal Ck, then, starting from this instant, its node Q_{M} will supply an intermediate voltage V_{Min} on the slave latch until the falling edge of the clock, or until earlier if the metastability in the master latch resolves before this edge. Until the falling edge of the clock, the slave latch is transparent and propagates the intermediate level V_{Min} to its output node Q_{S}, which can result on an intermediate level V_{Min}′ on Q_{S}. Then, as at the falling edge of the clock the slave latch is disconnected from the output of the master latch, its node Q_{S} will generally go to a logic level. However, there is also a non-zero probability for the slave latch to enter metastability. This may happen if the metastability of the master latch resolves around the falling edge of the clock signal Ck. Nevertheless, depending on its design characteristics, the slave latch could also enter metastability due to the intermediate voltage supplied on its input by the master latch, even if the metastability of the master latch does not resolve around the falling edge of the clock signal Ck. Then, if the slave latch enters metastability, it will supply an intermediate voltage level V_{Sin} on its node Q_{S}.

When, under metastability, the intermediate voltage level V_{Min}′ or V_{Sin} is supplied on the node Q_{S} of the flip-flop, we may have the following issues:
Due to noise, the voltage level of Q_{S} may slightly vary, crossing in different directions the threshold voltage Vth of the inverter 71 73 60 61, which drives the signal Q that feeds the subsequent combinational logic, and producing oscillations on Q. The similar is possible with noise on signal Q_{M}, when it is in the intermediate voltage V_{Min}.
The propagation to the output Q of the intermediate voltage V_{Min}′ or V_{Sin} present on node Q_{S} of the inverter 71 73 60 61, may produce a still intermediate voltage on Q, which can be interpreted as different logic levels by different parts of the combinational logic fed by this signal.

Concerning the impact of metastability on the reliability of a design, we remark that the probability of timing faults is low, and then when such a fault occurs, the probability of metastability occurrence is also low, Thus, the product of these two low probabilities will result in very low probability for metastability occurrence, which will be acceptable in many applications. On the other hand, in applications where the resulting probability for metastability occurrence is not acceptable, it is suitable to improve it without paying the high cost of metastability detectors. We remark that metastability detectors detect the occurrence of a metastable state regardless to its impact on the state of the circuit. However, such a strong requirement is not necessary: if the metastability does not induce errors in the circuit it is not necessary to detect it. This observation relaxes our requirements to detect the occurrence of metastability only when it induces errors in the circuit state. Then, as the mission of the Comparator 30 in the double-sampling architecture is to detect errors, we can introduce some modifications in this architecture to enable detecting errors induced by metastability. In achieving this goal, the first step is to avoid the case where:

i) An intermediate voltage is produced on the output of the flip-flop and is interpreted by the Comparator 30 as the correct logic level, which then will not detect it; and this intermediate voltage is interpreted by some parts of the Combinational Circuit 10 as the incorrect logic level; resulting in errors that are not detected.

In addition to this issue related to inconsistent interpretation of intermediate voltages, we should also cope with the following issues, which could induce errors in the circuit that are not guaranteed to be detected by the comparator if no particular care is taken:

ii) The metastability resolves within the clock cycle and causes the change of the output voltage of the flip-flop;
iii) Noise induces oscillations on the output of the flip-flop;
iv) The circuit delays increase due to the intermediate voltage produced on the internal flip-flop nodes and on its output.

To cope with these issues, this invention proposes the implementation described bellow in points a., b., and c.:
a. Implement the circuit in a manner that, for each regular flip flop FF1 21 FF2 20 checked by the double-sampling scheme the same node Q_{S} of the slave latch of this flip-flop feeds both the Combinational Circuit 10 and the Comparator 30 by means of an inverter 60 61, which receives as input the node Q_{S} and whose output Q is the node feeding the Combinational Circuit 10 and the Comparator 30. Furthermore, each flip-flop FF1 21 FF2 20 checked by the double-sampling scheme and the inverter through which it feeds the Combinational Circuit 10 and the Comparator 30, are implemented in a manner that, when this flip-flop is in metastability, and some of its internal nodes are in an intermediate voltage, the output (Q) of the inverter 60 61 is driven to a given logic level. A first of the possible approaches to achieve this goal is to implement this inverter 60 61 (also shown in the master-slave flip-flops of FIG. 22 as the inverter 71 73 placed between the signals Qs and Q), in a manner that its threshold voltage Vth is substantially smaller or substantially larger than both the intermediate voltages V_{Min}′, and V_{Sin}, which are produced on the output of each regular flip-flop FF1 21 FF2 20 checked by the double-sampling scheme, when respectively its master or its slave latch is in the metastability state. A second of the possible approaches for achieving this goal consists in designing some internal inverters/buffers of the flip-flop, in the way proposed in [19]. For instance, in the D flip-flop of FIG. 22.a (respectively 22.b), the inverter 70 (respectively buffer 72) producing the signal Qs, can be designed to have a threshold voltage substantially smaller or larger than the intermediate voltage level produced on signal Q_{M} when the master latch is in metastability, and the inverter 71 (respectively 73) placed on the output of the flip-flop can be designed to have a threshold voltage substantially smaller or larger than the intermediate voltage level produced on signal Q_{S} when the slave latch is in metastability. Note that, when we enforce logic levels on signal Q by using just one inverter 60 61 71 73, which has a logic threshold voltage Vth substantially smaller larger than both or substantially larger than both the intermediate voltages V_{Min}′, V_{Sin} produced respectively on the output Q_{S} of the flip-flop when the master latch or the slave latch is in metastability, this logic level will be the same in both metastability cases. On the other hand, if we enforce logic levels by using: an inverter/buffer 70 72, which has a logic threshold voltage V_{Mth} substantially smaller or substantially larger than the intermediate voltages V_{Min} produced on the output Q_{M} of the master latch when this latch is in metastability, and an inverter 71 73, which has a logic threshold voltage V_{Sth} substantially smaller or substantially larger than the intermediate voltages V_{Sin} produced on the output Q_{S} of the slave latch, then: if V_{Mth}>V_{Min} (respectively V_{Mth}<V_{Min}), and V_{Sth}>V_{Sin} (respectively V_{Sth}<V_{Sin}), the logic level produced on signal Q will be the same in both metastability cases; if V_{Mth}>V_{Min} (respectively V_{Mth}<V_{Min}), and V_{Sth}<V_{Sin} (respectively V_{Sth}>V_{Sin}), the logic level produced on signal Q will be different in the two metastability cases. Thus, in a preferable embodiment of this invention the regular flip-flops checked by the double-sampling architecture will be implemented to produce the same logic level in both metastability cases. Note also that, the second approach described above for producing logic levels on signal Q is also more robust with respect to oscillations induced by noise. Indeed, as both the inverter/buffer 70 72 and the inverter 71 73 have threshold voltage substantially higher or lower than the intermediate voltages produced respectively on nodes Q_{M} and Q_{S}, then, when the master latch or the slave latch is in metastability, noise will not cause the voltage on their input to cross their logic threshold voltage. On the other hand, as in the first approach the inverter/buffer 70 72 is not designed to have threshold voltage substantially higher or lower than the intermediate voltage produced on signal Q_{M}, oscillation between the logic level 1 and 0 is possible on the output Q_{S} of this inerter/buffer, and if it occurs it will be propagated to the output of the flip-flop during the high level of the clock. However, the first approach can also be used as this kind of oscillation is subject to detection by the implementation of the Comparator 30 and Error Latch 40 described in the next point
b. The output Q of a regular flip-flop may change values due to oscillation or due to the resolution of metastability. Thus, the comparator may produce on its output an error indication at some instants and no-error indication at some other instants. Then, if at the instant of the rising edge of Ck+τ it produces no-error indication, the Error Latch 40 will latch this level, and no error will be detected. To cope with this issue, in a preferable embodiment of this invention a stage of the Comparator will be implemented by means of dynamic logic, or by means of set-reset latches. For the architectures of FIGS. 3 and 5, these implementations of the Comparator are described in section «Accelerating the Speed of the Comparator». This section also provides the timing constraints (A_{d1}), (B_{d1}), (C_{d1}), and (E_{d}) that should govern this implementation to ensure flawless operation. Furthermore, constraints (B_{d1}) and (Ed) allow determining the raising and falling edge of the clock signal Ck_{d} rating the dynamic gates or the set-reset latches. As described in section «Accelerating the Speed of the Comparator» we can place the dynamic logic at any stage of the comparator. However, placing the dynamic gates far from the inputs of the comparator may reduce its resolution face to situations where the values of a pair of inputs of the comparator differ to each other for a short time duration, due to the effects of points i- and ii- presented below:
   i. A gate will strongly attenuate and often completely filter a short pulse a→a!→a occurring on its input if the duration of this pulse is shorter that the delay of the propagation of the transition a→a! from the input of the gate to its output.
   ii. When a pulse a→a!→a is not filtered due to the effect described in point i- above, then, its duration is reduced when it traverses a gate for which the delay of the propagation of the transition a→a! from its input to its output is larger than the delay of the propagation of the transition a!→a from its input to its output;
   iii. When a pulse a→a!→a is not filtered due to the effect described in point i- above, then, its duration is increased when it traverses a gate for which the delay of the propagation of the transition a→a! from its input to its output is shorter than the delay of the propagation of the transition a!→a from its input to its output;
   Fortunately, when the values of a pair of inputs of the comparator differ to each other, a pulse of the type 0→1→0 will occur on each NOR gate input belonging to the propagation path of this pulse and will induce a pulse of the type 1→0→1 on the output of this NOR gate, and a pulse of the type 1→0→1 will occur on each NAND gate input belonging to the propagation path of this pulse and will induce a pulse of the type 0→1→0 on the output of this NAND gate. Furthermore, the output transitions 1→0 of NOR gates are the fast transitions of these gates, as opposed to the output transitions 0→1 of NOR gates which are their slow transitions; and the output transitions 0→1 of NAND gates are the fast transitions of these gates, as opposed to the output transitions 1→0 of NAND gates which are their slow transitions. Thus, on the one hand, the probability that these pulses will be filtered due to the effect described in the above point i- is reduced; and on the other hand, thanks to the effect of point iii- described above, the propagation of these pulses through the NOR and NAND h-gates of the comparator will increase their duration. Thus, there is a reduced risk for the pulse, produced when the values of a pair of inputs of the comparator differ to each other for a short duration of time, to be filtered during its propagation through several gate levels of the comparator. Thus, this risk can be acceptable in many cases and we could place the dynamic gates several gate levels after the inputs of the comparator. However, as the comparator may compare signals coming from flip flops distributed all over a design, it will be possible to use each gate belonging to the first gate levels of the comparator to compare groups of signals coming from flip-flops that are in proximity to each other. Thus, for these gates it will be possible to avoid long interconnections for the signals driving their inputs. However, after some gate levels, it will be necessary to use long interconnections for connecting the outputs of some gates to the inputs of their subsequent gates. Then, the large output load of the first gates may increase their delay even for fast transitions at a value that may result in the pulse filtering described above in point i−. Thus, we will need to place the stage of dynamic gates, before these gates. Furthermore, in cases where very high reliability is required, it can be mandatory to increase as much as possible the detection capabilities of the comparator with respect to the pulses produced when the values of a pair of inputs of the comparator differ to each other for a short duration of time. Thus, in these cases we will need to place the stage of dynamic gates as close as possible to the inputs of the comparator. The best option with respect to the error detection efficiency is to use dynamic logic for implementing the stage of XOR gates of the comparator, as shown in FIGS. 13.a, 13.b and 15. However, in this case the clock signal Ck_{d} will have to clock as many dynamic gates as the number of regular flip-flops FF1 21 FF2 20 checked by the double-sampling architecture. But this is not desirable, as it will increase the power dissipated by the clock signal Ck_{d}. Then, to achieve high error detection efficiency and at the same time reduce power, we can use dynamic gates to implement the first level of OR (or AND gates) of the OR-tree of the Comparator 30. By using dynamic gates with k inputs to implement this level, we divide by k the number of dynamic gates clocked by the signal Ck_{d}. This solution improves significantly the sensitivity of the Comparator 30, but it is still less sensitive than the implementation using dynamic XOR gates. Then, to further improve its sensitivity, we can use dynamic logic, which merges in a single gate the function of k XOR gates and of a k-inputs OR-tree compacting the outputs of the k XOR gates into a single error detection signal. Such a gate is shown in FIG. 23. Thus, we maximize the error detection capability of the comparator, face to discrepancies of short duration on its inputs, while moderating the power cost by dividing by k the number of clocked gates. However, it is worth noting that, increasing the number k of the inputs of this gate increases its output capacitance, which may have an impact on its sensitivity, moderating the practical values of k. This sensitivity will also be impacted by the length of interconnections, connecting the inputs and outputs of the regular flip-flops FF1 21 FF2 20 to the inputs of the gate. Thus, this issue also imposes limiting the value of k, in order to moderate the length of interconnects by using the gate to check flip-flops that are close to each other. For the implementation using the dynamic gate of FIG. 16, the value of D₁ₘₐₓ, D₁ₘₐₓᵢ and D₁ₘᵢₙᵢ used in constraints (A_{d1}), (B_{d1}), (C_{d1}), (H_{d}), and (E_{d}) will be D₁ₘₐₓ=D₁ₘₐₓᵢ=D₁ₘᵢₙᵢ=0. Then, constraint (B_{d1}) becomes D_{FFmax}≤τ_{rd}. Hence, the designer can select the value τ_{rd}=D_{FFmax} or a larger value τ_{rd}=D_{FFmax}+D_{mrg} if she/he wants to account for possible clock skews or jitter. Furthermore, from relation (Ed) the value of τ_{fd} is given by τ_{fd}=δ−D_{FFsu}+D_{DG}(Error!→Error)ₘₐₓ, where D_{DG}(Error!→Error)ₘₐₓ is the maximum delay of the (non-error indication) to (error indication) transition of the output of the dynamic gate, which for the dynamic comparator gate of FIG. 23, comprises the same terms as for the dynamic XOR gate of Fig. X6.a, given in section «Accelerating the Speed of the Comparator». Then, the duration of the high level of clock signal Ck_{d} will be given by T_{Hd}=τ_{fd}−τ_{rd} and its rising edge will occur at a time τ_{rd} after the rising edge of Ck. To ease the generation of Ck_{d}, we can implement a clock generator to generate a clock signal Ck whose high level duration is equal T_{H}=T_{Hd}, and then, generate the clock signal Ck_{d} by delaying the clock signal Ck by a delay equal to τ_{rd}=D_{FFmax}, or τ_{rd}=D_{FFmax}+D_{mrg} if we opt to use a security margin D_{mrg} for accounting clock skews and jitter.
c. Design the double-sampling scheme for a duration δ of detectable timing faults larger than Dm+D_{FF}+tₛᵤ, where Dm is the delay increase induced on the design when a flip-flop FF1 21 enters the metastability state and produces an intermediate voltage Vᵢₙ on some of its internal nodes. Note that, as the threshold voltage Vth of the inverters/buffer enforcing the above point a. is substantially larger or smaller than the intermediate voltage of the node feeding its input, the delay increase Dm will be moderate. Thus, the duration δ of detectable faults, selected by a designer for covering the other types of timing faults affecting the design, would be generally larger than Dm+D_{FF}+tₛᵤ. In the improbable case where Dm+D_{FF}+tₛᵤ would be larger than the value of δ used for the other faults, a small increase of the value of δ will be required to ensure that it will become larger than Dm+D_{FF}+tₛᵤ.

Probabilistic analysis shows that the probability that the metastability induces logic errors and at the same time it is not detected by the implementation described above in points a., b. and c. is extremely low and would be acceptable for any application.

Another issue that can affect reliability, is that in rare cases, the metastability does not induce logic errors, but due to extra delays induced in the circuit by the propagation of the metastability state, transitions may occur on some flip-flop inputs of this subsequent stage during their setup time, inducing new metastability sate(s). If this new metastability state induces some errors, their non-detection probability is, as above, extremely low. However, it is again possible that no logic errors are induced, but for the same reason as above, the next stage of flip-flops may enter metastabiliy, and so on. This recurring metastability may induce problems if it reaches other blocks, which do not have the ability for error and metastability detection as the double-sampling architecture proposed here. Nevertheless, the probability for this situation to happen is very low. Furthermore it is possible to bloc this kind of recurring metastability propagation, by using, on the boundary with such blocks, a pipeline stage with low delays, so that, extra delays induced by the metastability do not violate the setup time. The other solution is to use metastability detectors in the flip-flop stages that provide data to some subsequent block that do not have the abilities for error and metastability detection like those that has the double-sampling architecture proposed here. However, if for this subsequent block for simple error recovery is not feasible, using metastability detectors in such flip-flops may not be sufficient to completely resolve the problem, if the detection signal is activated too late for blocking the propagation of the metastability effects to this subsequent block. These flip-flops will be referred hereafter as late-detection-critical boundary flip-flops. For instance, an error producing a wrong address, which is used during a write operation on a memory or a register file, will destroy the data stored in this address. Then, as the destroyed data could be written in the memory or the resister file by a write operation performed many cycles earlier, then, simple error recovery, which reexecutes the latest operations performed during a small number of cycles, could not reexecute this write and the destroyed data will not be restored. The similar problem occurs for a wrongly activated write enable. On the other hand, writing, during a correctly enabled write operation, wrong data in the correct address, will not prevent using simple error recovery. Indeed, an error recovery which reexecutes a small number of cycles determined in a manner that guaranties to include the cycle of the error occurrence, will repeat this write and will store the correct data in this correct address. Thus, boundary flip-flops containing data to be written in a memory or register file, are not prone to the above described late-detection issue, and this is of course the case for flip-flops containing read data. Hence, in the boundaries with a memory block or a register file, the late-detection-critical boundary flip-flops are the flip-flops containing the memory or register file addresses, as well as those used for generating the write enable signal. Critical flip-flops with respect to late error detection may also exist in the boundaries with other kind of blocks for which propagated errors are not recovered by means of simple error recovery is implemented. The similar problem occurs even if late-detection-critical boundary flip-flops are not affected by metastability, but are affected by logic errors, which are detected but the detection signal is activated too late for blocking the propagation of these errors to the subsequent block for which simple error recovery is not feasible. In all these situations, the delay of the Comparator 30 is a critical issue, especially, in designs where a large number of flip-flops is checked by means of the double-sampling scheme. Then, instead of using the global error detection signal produced by this comparator to block the error propagation from late-detection-critical boundary flip-flops to the subsequent block for which no simple error recovery is possible, a partial error detection signal will be generated as the result of the comparison of the inputs and outputs of the late-detection-critical boundary flip-flops, and this partial error detection signal, which will be ready much earlier than the said global error detection signal, will be used to block the propagation of errors to this subsequent block. Note also that, this solution can be used in designs protected by any error detection scheme, like for instance designs using: any double-sampling scheme; hardware duplication; any error detecting codes; transition detectors; etc. In all these cases, instead of using the global error detection signal for blocking error propagation from late-detection-critical boundary flip-flops to a subsequent block, we can use for each of these blocks a partial error detection signal, which will be produced by checking subsets of the flip-flops checked by the global error detection signal that include the late-detection-critical boundary flip-flops providing inputs to this subsequent block.

### Double-Sampling Architecture Enhancement for SEUs

In the double sampling architecture of FIG. 1 the short-paths constraint imposes that the minimum delay of any pipeline stage must be larger than δ+t_{RSh} (where t_{RSh} is the hold time of the redundant sampling element). Thus, a source of cost for implementing this architecture consists in buffers that we should insert in short paths to enforce this constraint. Fortunately, in applications requiring detecting timing faults, most the flip-flops fed by paths with small delays do not need protection. Thus, a small amount of flip-flops need protection, reducing the cost for implementing the double sampling architecture of FIG. 1. This architecture can also be used to detect single-event transients (SETs) induced by cosmic radiations. However, radiation induced failures can affect any circuit path. Thus, the cost for enforcing the short paths constraint will be high, due to 3 reasons: the short-paths constraint should be enforced in a much larger number of paths than in the case of timing faults, because in the present all flip-flops should be protected; in space environment, high energy particles induce SETs of very large duration, increasing the value of δ, and by consequence the minimum acceptable delay imposed by the short paths constraint becomes very large; as the short paths constraint should be enforced also for flip-flops fed by short paths, longer delays should be added to such paths to enforce the short paths constraint. Thus, for designs dedicated to space applications, the short paths constraint will induce quite high cost. Note also that, the short paths constraint should also be enforced in the double-sampling architecture of FIG. 3, as well as in other error detection architectures including RAZORII [20]; and the Time-Borrowing Double Sampling and the Time-Borrowing Transition Detection architectures [13], which will all require large cost for enforcing the short-paths constraint in designs dedicated to space applications. Therefore, it is valuable to dispose a double-sampling scheme not requiring enforcing this constraint.

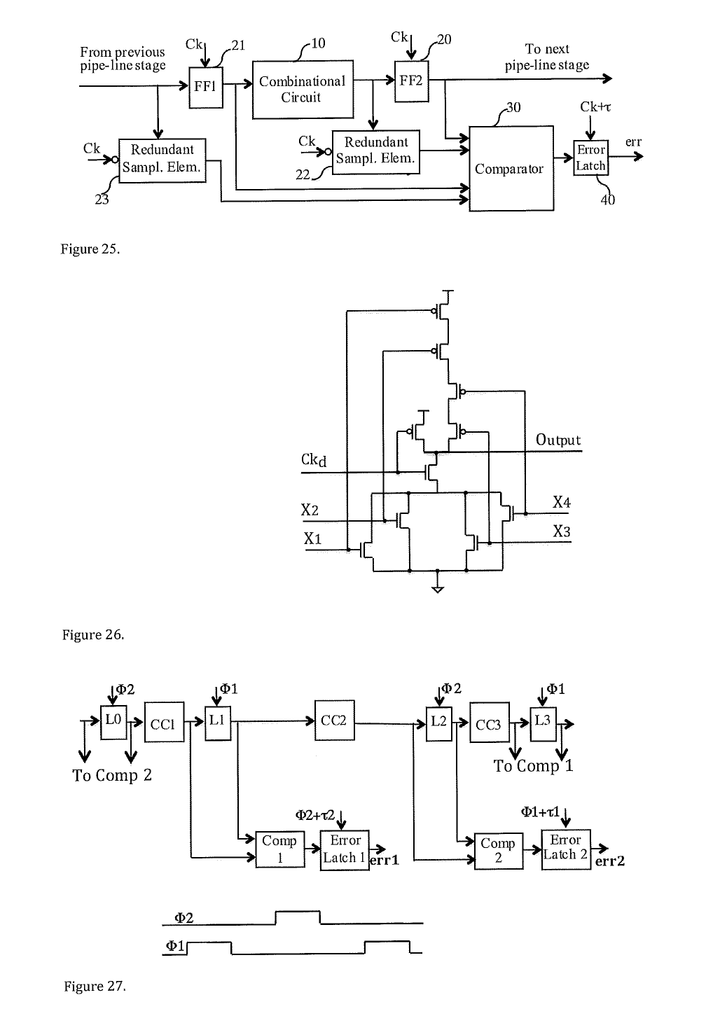

This goal is reached by a modification of the operation of the double-sampling scheme of FIG. 1 [17], consisting in using a clock signal Ck, such that the duration T_{H} of its high level is larger than the largest circuit delay. In this case, the circuit enters a new operating mode not considered in the previous double-sampling implementations. To describe this mode, as presented in reference [17], let us consider the double sampling architecture of FIG. 24 (as well as of FIG. 25 which shows also the protection of flip-flops FF1 21 which was omitted in FIG. 24). The architecture of FIGS. 24 and 25 is structurally identical to that of FIG. 1, but differs in the fact that it uses a clock signal Ck, whose high level has a duration T_{H} larger than the largest circuit delay. Also, in FIGS. 24 and 25, the Redundant Sampling Elements 23 22 instead of latching the value present on their inputs at the raising edge of a clock signal Ck+δ, obtained by adding a delay δ on the clock signal Ck they latch this value at the falling edge of Ck (which will be equivalent with the clocking of the Redundant Sampling Element 22 in FIG. 1 if we use δ=T_{H}). In FIGS. 24 and 25, new values are captured by the regular flip-flops FF1 21 FF2 20, at the rising edge of each clock cycle i, and become the new inputs of the Combinational Circuit fed by these flip-flops (e.g. Combinational Circuit 10 for flip-flops FF1 21). As T_{H} is larger than the largest circuit delay, the combinational logic 10 of each pipeline stage will produce before the falling edge of clock cycle i its output values corresponding to these inputs. Thus, at the falling edge of clock cycle i, the redundant sampling elements will capture these output values. These output values are also captured by the regular flip-flops at the rising edge of clock signal Ck in clock cycle i+1. Then, SETs of duration not exceeding T_{L}−t_{RSh}−t_{FFsu} could not affect both a regular flip-flops FF1 21 FF2 20 and their associated Redundant Sampling Element 23 22 (where T_{L} is the duration of the low level of clock signal Ck, t_{FFsu} is the setup time of the regular flip-flops FF1 21 FF2 20, and t_{RSh} is the hold time of Redundant Sampling Elements 23 22). Therefore, comparing the values captured by the redundant sampling elements at the falling edge of clock cycle i against the values captured by the regular flip-flop at the rising edge of clock cycle i+1, will enable detecting SETs of a duration as large as T_{L}−t_{RSh}−t_{FFsu}. Furthermore, as the Redundant Sampling Elements 23 22 capture their inputs at the falling edge of clock signal Ck in clock cycle i, they cannot be affected by the new values captured by the regular flip-flops FF1 21 FF2 20 at the raising edge of cycle i+1. Thus, in this operating mode, the double-sampling architecture is not affected by short-path constraints, and we can use a clock Ck having a low level duration T_{L} as large as required to detect any target duration of SETs, without paying any cost for enforcing short path constraints. Thus, this operating mode is very suitable for covering large SETs in space applications. However, in space applications circuits are very sensitive to single-event upsets (SEUs), and we also need to ensure high coverage for these faults.

An SEU affecting a regular flip-flop FF1 21 during a clock cycle i, may not be detected by the Comparator 30 and Error Latch 40 if it occurs after the instant tᵣᵢ+τ−t_{ELsu}−D_{CMP}(Error!→Error)ₘₐₓ, where tᵣᵢ is the instant of the raising edge of clock signal Ck in the clock cycle i and thus tᵣᵢ+τ is the instant of the raising edge of clock signal Ck+τ subsequent to the instant tᵣᵢ (at this edge the Error Latch 40 latches the value present on its input); t_{ELsu} is the setup time of this latch; and D_{CMP}(Error!→Error)ₘₐₓ is the maximum delay for the propagation through the comparator of the transition from the non-error state to the error state. Then, the propagation of this undetectable SEU through the Combinational Logic 10, may affect the values latched by the subsequent stage of regular flip-flops FF2 20 at the raising edge of cycle i+1 (instant tᵣᵢ₊₁). Thus, an SEU affecting a stage of regular flip-flops may not be detected but induce errors in the subsequent flip-flops. A first goal of the invention is to avoid this situation. This situation can be avoided if an SEU affecting a regular flip-flop FF1 21 at the instant tᵣᵢ+τ−t_{ELsu}−D_{CMP}(Error!→Error)ₘₐₓ or later, cannot reach the inputs of the subsequent stage of regular flip flops FF2 20 before the instant tᵣᵢ₊₁+t_{FFh}. This is 100% guaranteed if Dmin≥(tᵣᵢ₊₁+t_{FFh})−(tᵣᵢ+τ−t_{ELsu}−D_{CMP}(Error!→Error)ₘₐₓ), which gives

Dmin≥Tck+t_{FFh}+t_{ELsu}+D_{CMP}(Error!→Error)ₘₐₓ−τ (1)

where Dmin is the minimum delay of combinational circuit starting from any regular flip-flop checked by the scheme of FIGS. 24 and 25 (e.g. FF1 21) and ending to the flip-flops of the subsequent circuit stage (e.g. FF2 20); Tck is the clock period; and t_{FFh} the hold time of the regular flip-flops FF2 20. Thus, imposing the avoidance of this situation implies enforcing a new short-path constraint (i.e. constraint (1)). To moderate this constraint we have to use a value for τ as large as possible. τ can take without constraints any value such that τ+t_{ELh}≤T_{H}+D_{RSmin} (where D_{RSmin} is the minimum Clk-to-Q delay of the Redundant Sampling Elements 23 22). Higher values of T are possible by taking into account the delays of the comparator, in order to ensure that the new values captured by the redundant flip-lops will not induce false error detections. To avoid such detection we should ensure that these new values will not reach the input of the Error Latch before the end of its hold time. Thus, the following constraint should be enforced:

τ+t_{ELh}≤T_{H}+D_{RSmin}+D_{CMp}(Error!→Error)ₘᵢₙ (2).

Combining constraint (1) and (2) (i.e. setting in (1) the maximum value of τ from (2)) we find:

Dmin≥Tck+t_{FFh}+t_{ELsu}+D_{CMP}(Error!→Error)ₘₐₓ−(T_{H}+D_{RSmin}−t_{ELh}+D_{CMP}(Error!→Error)ₘᵢₙ),

resulting in:

Dmin≥T_{L}+t_{FFh}+t_{ELh}+t_{ELsu}−D_{RSmin}+D_{CMP}(Error!→Error)ₘₐₓ−D_{CMP}(Error!→Error)ₘᵢₙ (C_{SEU})

Thus, Dmin should be larger than T_{L}, and thus even larger than the duration of faults guaranteed to be detected, which, as we have seen earlier are equal to T_{L}−t_{RSh}−t_{FFsu}. Thus, we need to enforce a strong short-path constraint, which, as explained earlier, in the context of SETs and SEUs protection will induce very high cost. This high cost is probably the reason for which no SEU detection was proposed so far for this double sampling architecture, which is important for space applications as it achieves protection of large SETs at low cost. Even in a recent work [17] discussing this architecture, the falling edge of the clock signal Ck is used as the latching edge of the Error Latch 40, which, from the analysis above, will result in low coverage of SEUs.

To improve this architecture, in this invention we also show that we can relax the short-paths constraint by arranging the operation of the circuit in a way that: SEUs affecting Regular Flip-flops FF1 21 at a clock cycle i, are authorized not to be detected and their propagation through the Combinational Circuit 10 to induce at the next clock cycle i+1 erroneous values in the subsequent stage of Regular flip-flops FF2 20, but these news erroneous values should be detected at clock cycle i+1. Then, to detect the new erroneous values affecting FF2 20 at clock cycle i+1, we will arrange the operation of the circuit in a manner that, the propagation through the Combinational Circuit 10 of undetectable SEUs affecting the Regular Flip-flops FF1 21 at a clock cycle i, will not induces at clock cycle i+1 erroneous values in the subsequent stage of Redundant Sampling elements 22. This way, if the SEUs are not detected at cycle i, they will not affect the subsequent stage of Redundant Sampling Elements 22, and then, if they affect the subsequent stage of Regular Flip-flops FF2 20, the difference between the values of the Redundant Sampling Elements 22 and the Regular Flip-flops FF2 20 at the clock cycle i+1, will be detected by the Comparator 30.

As shown earlier, an SEU affecting a regular flip-flop FF1 21 during a clock cycle i, is guaranteed to be detected by the Comparator 30 and the Error Latch 40 if it occurs before the instant tᵣᵢ+τ−t_{ELsu}−D_{CMP}(Error!→Error)ₘₐₓ, and is not guaranteed to be detected if it occurs after this instant. Thus, we should ensure that, an SEU occurring on a regular flip-flop FF1 21 at this instant or later will not affect the value latched by the subsequent stage of Sampling Elements 22 at the falling edge of Ck in clock cycle i. This will happen if the propagation through the Combinational Logic 10 of the erroneous value induced by this SEU on a flip-flop FF1 21 will reach the input of the subsequent stage of Redundant Sampling Elements 22 at the instant t_{fi}+t_{RSh}=tᵣᵢ+T_{H}+t_{RSh} or later (where t_{fi} is the falling edge of CK in clock cycle i). This is guaranteed if Dmin≥(tᵣᵢ+T_{H}+t_{RSh})−(tᵣᵢ+τ−t_{ELsu}−D_{CMP}(Error!→Error)ₘₐₓ), resulting in:

Dmin≥T_{H}−τ+t_{RSh}+t_{ELsu}+D_{CMP}(Error!→Error)ₘₐₓ (3).

Setting in (3) τ=T_{H}+D_{RSmin}+D_{CMP}(Error!→Error)ₘᵢₙ−t_{ELh} (i.e. the maximum value of τ from (2) gives:

Dmin≥t_{RSh}+t_{ELsu}+t_{ELh}−D_{RSmin}+D_{CMP}(Error!→Error)ₘₐₓ−D_{CMP}(Error!→Error)ₘᵢₙ) (C_{SEUrelaxed})

Constraint (C_{SEUrelaxed}) is drastically relaxed with respect to the constraint (C_{SEU}) (i.e. Dmin is reduced here by the value T_{L}), and will require much lower cost for enforcing it. Moreover, enforcing this constraint will require very low cost. Indeed, the setup time, hold time and propagation delay of sampling elements are small, resulting in small value for t_{RSh}+t_{ELsu}+t_{ELh}−D_{RSmin}. Furthermore, the non-error to error transitions, are the fast transitions of the comparators. Thus the difference D_{CMP}(Error!→Error)ₘₐₓ−D_{CMP}(Error!→Error)ₘᵢₙ between the maximum and the minimum delays of these transitions will be small. Thus, the relaxed constraint (C_{SEUrelaxed}) will require small values for Dmin. Thus, it should be satisfied by the intrinsic minimum delay of most paths, which will then not require adding buffers. Also as this value is small, enforcing the constraint in paths not satisfying it by their intrinsic delay, will require low cost.

In addition to the above constraints, we should also guaranty that the values captured by the regular flip-flops at the instant tᵣᵢ of the rising edge of a clock cycle i, reach the input of the error latch at a time t_{ELsu} before the instant tᵣᵢ+τ of the rising clock edge of the error flip-flop, resulting in the constraint:

τ≥D_{FFmax}+D_{CMPmax}+t_{ELsu} (4)

where D_{FFmax} is the maximum Ck-to-Q propagation delay of the regular flip-flops FF1 21 FF2 20, and D_{CMPmax} is the maximum delay of the comparator. This constraint gives the lower limit of τ.

Note that, to guaranty the detection of errors the following constraint, which is more relaxed than constraint (4), should be satisfied:

τ>D_{FFmax}+D_{CMP}(Error!→Error)ₘₐₓ+t_{ELsu} (4′).

But constraint (4′) will result in false detections, when hazards induced by the fact that the values of the regular flip-flops can be different to those of the redundant flip-flops during the time interval (t_{fi}, tᵣᵢ)) can bring to the error detection state the outputs of the gates in some paths of the Comparator (i.e. bring to 1 the outputs of some NOR gates, or to 0 the outputs of some NAND gates), because the delay D_{CMP}(Error→Error!)max of the comparator is larger than D_{CMP}(Error!→Error)ₘₐₓ, and thus constraint (4′) does not provide enough time for values captured by the regular flip-flops at the rising edge of the clock to restore the correct value (i.e. the non-error detection state) at the output of the comparator.

Constraints Enforcement:

We can enforce the different constraints by considering the typical values of the different parameters involved in these constraints is possible, but the constraints can be violated in the case where the values of the parameters are different from their typical values. Thus, if the goal is to enforce the constraint for all possible parameter values, we should select for some parameters their minimum value and for some other their maximum value. Also, as in advanced nanometric technologies the circuit parameters are increasingly affected by process, voltage and temperature variations, as well as by interferences, circuit aging, jitter, and clock skews (to be referred hereafter as VIAJS effects), we can use some margins when enforcing the constraints, to guaranty their validity even under these effects.

We can enforce constraint (2), by setting:

τ=T_{H}+D_{RSmin}−t_{ELh}+D_{CMP}(Error!→Error)ₘᵢₙ,

where we will not consider the typical value of D_{RSmin}−t_{ELh}+D_{CMP}(Error!→Error)ₘᵢₙ, but its minimum one. We can further increase the margins for enforcing constraint (2) by setting

τ=T_{H}+D_{RSmin}−t_{ELh}+D_{CMP}(Error!→Error)ₘᵢₙ−Dmarg₂ (5)

where the value of Dmarg₂ is selected to enforce (2) against VIAJS or other issues with the desirable margins.
where the value of Dmarg₂ is selected to enforce (2) against VIAJS or other issues with the desirable margins. Concerning constraint (4), we remark that, when we enforce constraint (2) by setting τ=T_{H}+D_{RSmin}−t_{ELh}+D_{CMP}(Error!→Error)ₘᵢₙ, enforcing constraint (4) will require T_{H}≥+D_{CMPmax}−D_{CMP}(Error!→Error)ₘᵢₙ+t_{ELsu}+t_{ELh}+D_{FFmax}−D_{RSmin}. The difference D_{CMPmax}−D_{CMP}(Error!→Error)ₘᵢₙ depends on the implementation of the comparator and will be quite small if the comparator is balanced and larger otherwise, furthermore t_{ELsu}, t_{ELh}, D_{FFmax}, D_{RSmin} are small values. Then, as T_{H} was set to be larger than the maximum delay of the pipeline stages of the circuit, in most cases, enforcing (2) will also enforce (4).

If in some design this is not the case, some modifications are needed for enforcing both constraints. These modifications consist in designing the comparator in a manner that, the difference D_{CMPmax}−D_{CMP}(Error!→Error)ₘᵢₙ is reduced. The delay D_{CMPmax} will be larger than D_{CMP}(Error!→Error)ₘᵢₙ, as it corresponds to the charging of the outputs of the NOR gates (resp. the discharging of the outputs of the NAND gates) used in the OR tree of the comparator, and the larger is the comparator the larger will be the difference D_{CMPmax}−D_{CMP}(Error!→Error)ₘᵢₙ. Furthermore D_{CMPmax} corresponds to the slowest paths of the comparator while D_{CMP}(Error!→Error)ₘᵢₙ to its shortest path. Then, in some cases, large circuits using large comparators and quite imbalanced comparators, enforcing constraint (2) may violate constraint (4).

A first approach for reducing the value of the delay D_{CMPmax} used in constraint (4), consists in pipelining the comparator. In this case, constraints (2) and (4) (as well as (1), and (3)), will involve the delays of the first stage of the pipelined comparator and the value τ corresponding to the clock Ck+τ of the flip-flops of this stage. Then, as the size of the OR trees ending to these flip-flops is much smaller than the OR tree of the full comparator, the value of the difference D_{CMPmax}−D_{CMP}(Error!→Error)ₘᵢₙ involved in constraints (2) and (4) is reduced significantly, and the first stage of the pipelined comparator can be selected to be as small as required for reducing D_{CMPmax}−D_{CMP}(Error!→Error)ₘᵢₙ at a level, which guarantees that enforcing constraint (2) enforces also constraint (4). Further reduction of the value of the delay D_{CMPmax} can be achieved by using NOR gates with large number of inputs in the implementation of the hazards-free part of the comparator, as presented earlier in this invention, and this approach can also be used in the enforcement of constraints (2) and (4), discussed below for approaches introducing in the comparator a stage of dynamic gates, or a stage of hazards-blocking static gates, or a stage of set-reset flip-flops considered bellow.

A second approach for reducing the difference D_{CMPmax}−D_{CMP}(Error!→Error)ₘᵢₙ, consists in implementing a stage of gates of the comparator by means of dynamic gates, as illustrated in FIG. 16; or by implementing a stage of the comparator by means of hazards-blocking static gates, like the k−1 OR-AND-Invert gates driven by Ckd as illustrated in FIG. 26, or the two-input static NOR gates driven by Ckd and used to replace a stage of inverters in the comparator as described earlier, etc. Let Ckd be the clock signal driving the dynamic gates, or the hazards-blocking static gates. In the discussion bellow we consider the approach using dynamic gates, but the derived constraints are also valid for the approach using hazards-blocking static gates, by considering the corresponding delays for each approach. For instance, in the approach using dynamic gates D_{CMP1max} is the maximum delay of the paths connecting the inputs of the comparator to the inputs of the stage of dynamic (part 1 of the comparator), while in the approach using hazards-blocking static gates D_{CMP1max} is the maximum delay of the paths connecting the inputs of the of the comparator to the inputs of the stage of hazards-blocking static gates (part 1 of the comparator); and in the approach using dynamic gates D_{CMP2}(Error!→Error)ₘₐₓ is the delay for the fast transitions Error!→Error of the slowest path of the part 2 of the comparator (i.e. the part comprised between the inputs of the stage of dynamic gates and the input of the Error Latch), while in the approach using hazards-blocking static gates D_{CMP2}(Error!→Error)ₘₐₓ is the delay for the fast transitions Error!→Error of the slowest path of the part 2 of the comparator (i.e. the part comprised between the inputs of the stage of hazards-blocking static gates and the input of the Error Latch).

In the approaches using dynamic gates (as well that using hazards-blocking static gates), the constraint (4.d) presented bellow, should be enforced to ensure that hazards induced by differences on the values of redundant regular flip-flops that may occur during the time interval (t_{fi}, tᵣᵢ) will not discharge the dynamic gates, and also that differences between the values captured by the redundant flip-flops at the instant t_{fi-1} of the rising edge of a cycle i−1 of clock signal Ck and the values captured by the regular flip-flops at the instant tᵣᵢ of the rising edge of cycle 1 of Ck, reach the input of the dynamic gates at a time t_{mrg} before the rising edge of clock signal Ckd (i.e. before the instant tᵣᵢ+τd). In this constraint, id is the time separating the rising edge of clock signal Ckd from the rising edge of clock signal Ck; D_{CMP1max} is the maximum delay of the paths connecting the inputs of the of the comparator to the inputs of the stage of dynamic gates (first part of the comparator); and t_{mrg}≥0 is a timing margin for securing to ensure that values captured by the regular latches will reach the input of the dynamic gates at a time before the rising edge of clock signal Ckd.

τd≥D_{FFmax}+D_{CMP1max}+t_{mrg} (4.d)

Furthermore, the constraint (4.2) presented bellow, should be enforced to ensure that differences between the values captured by the redundant flip-flops at instant t_{fi-1} of the rising edge of a cycle i−1 and the values captured by the regular flip-flops at the instant tᵣᵢ of the rising edge of clock cycle i (which start propagating through the dynamic gates at the instant tᵣᵢ+τd), will reach the input of the error latch at a time t_{ELsu} before the instant tᵣᵢ+τ of the rising clock edge of the error flip-flop. In this constraint, D_{CMP2}(Error!→Error)ₘₐₓ is the delay for the fast transitions Error!→Error of the slowest path of the second part of the comparator (i.e. the part comprised between the inputs of the stage of dynamic gates and the input of the error latch).

τ−τd≥D_{CMP2}(Error!→Error)ₘₐₓ (4.2)

Enforcing constraint (4.d) by setting τd=D_{FFmax}+D_{CMP1max}+t_{mrg} and replacing this value in (4.2) gives τ≥D_{FFmax}+t_{mrg}+D_{CMP1max}+D_{CMP2}(Error!→Error)ₘₐₓ. Then, as D_{CMPmax} corresponds to the delay of the slow transitions (Error→Error!) in the slowest path of the whole comparator, and the sum D_{CMP1max}+D_{CMP2}(Error!→Error)ₘₐₓ involves the fast transitions (Error!→Error) in the second part of the comparator, this sum is much smaller than the delay D_{CMPmax} of the whole comparator involved in constraint (4). Thus, using dynamic gates in a stage of the comparator replaces constraint (4) by constraints (4.d) and (4.2), which are relaxed with respect to constraint (4) and are easier to enforce without violating constraint (2). Similar gains can be achieved by replacing in the comparator-tree a stage of inverters by a stage of set-reset latches, as those shown in FIG. 14.

To enforce constraint (1) we can set Dmin=Tck+t_{FFh}+t_{ELsu}+D_{CMP}(Error!→Error)ₘₐₓ−τ, where we will not consider the typical value of t_{FFh}+t_{ELsu}+D_{CMP}(Error!→Error)ₘₐₓ, but its maximum one. We can further increase the margins for enforcing constraint (1) by setting

Dmin=Tck+t_{FFh}+t_{ELsu}+D_{CMP}(Error!→Error)ₘₐₓ−τ+Dmarg₁ (1′)

where the value of Dmarg₁ is selected to enforce (1) with the desirable margins against VIAJS or other issues.

Then, by replacing in (1′) the value of τ from (5) we find that by enforcing constraints (2) and (5) as above, the value of Dmin is given by:

Dmin=T_{L}+t_{FFh}+t_{ELh}+t_{ELsu}−D_{RSmin}+D_{CMP}(Error!→Error)ₘₐₓ−D_{CMP}(Error!→Error)ₘᵢₙ+Dmarg₂+Dmarg₁ (C′_{SEU})

where we do not consider the typical value of t_{FFh}+t_{ELh}+t_{ELsu}−D_{RSmin}+D_{CMP}(Error!→Error)ₘₐₓ D_{CMP}(Error!→Error)ₘᵢₙ but its maximum one.

To enforce constraint (3) we can set Dmin=T_{H}−τ+t_{RSh}+t_{ELsu}+D_{CMP}(Error!→Error)ₘₐₓ, where we will not consider the typical value of t_{RSh}+t_{ELsu}+D_{CMP}(Error!→Error)ₘₐₓ, but its maximum one. We can further increase the margins for enforcing constraint (3) by setting

Dmin=T_{H}−τ+t_{RSh}+t_{ELsu}+D_{CMP}(Error!→Error)ₘₐₓ+Dmarg₃ (3′)

where the value of Dmarg₃ is selected to enforce (3) with the desirable margins against VIAJS or other issues.

Then, by replacing in (3′) the value of τ from (5) we find that by enforcing constraints (2) and (5) as above, the value of Dmin is given by:

Dmin□□t_{RSh}+t_{ELh}+t_{ELsu}−D_{RSmin}+D_{CMP}(Error!→Error)ₘₐₓ−D_{CMP}(Error!→Error)min+Dmarg₂+Dmarg₃ (C′SEUrelaxed)

where we do not consider the typical value of t_{RSh}+t_{ELh}+t_{ELsu}−D_{RSmin}+D_{CMP}(Error!→Error)ₘₐₓ−D_{CMP}(Error!→Error)ₘᵢₙ but its maximum one.

Constraint (1) as well as constraint (3) are expressed by using: the global minimum delay Dmin for all paths started from the flip-flops checked by the double-sampling scheme of FIG. 24 and finishing to the flip-flops of the subsequent circuit stage; and the global maximum delay D_{CMP}(Error!→Error)ₘₐₓ of the non-error to error transition for all the comparator paths staring to each of these flip-flops and ending to the input of the Error Latch clocked by clock signal Ck+x. Using the global minimum delay Dmin and the global maximum delay D_{CMP}(Error!→Error)ₘₐₓ in constraint (1) guarantees the detection of all SEUs affecting the flip-flops protected by the scheme of FIG. 24, and this is also true for constraint (3). Expressing constraint (1) individually for each flip-flop checked by the scheme of FIG. 24, allows detecting the SEUs affecting each flip-flop. Thus, the individual expression of constraint (1) does not reduce the protection against SEUs with respect to the protection provided by constraint (1), and this is also true for the individual expression of constraint (3). Expressing individually the constraints (1) and (3) for each flip-flop FFi checked by the scheme of FIG. 24 gives:

Dₘᵢₙᵢ−D_{CMP}(Error!→Error)ₘₐₓᵢ≥Tck+t_{FFh}+t_{ELsu}−τ (1i)

Dmini−D_{CMP}(Error!→Error)maxi≥T_{H}−τ+t_{RSh}+t_{ELsu} (3i)

Where D_{CMP}(Error!→Error)maxi—is the maximum delay of the compparator path starting from the output of flip-flop FF i and ending to input of the Error Latch capturing the output of the comparator checking this flip-flop. The interest of constraints (1i) and (3i) is that, though they provide the same protection against SEUs as constraints (1) and (3), they can be enforced by means of lower cost. This is because when using expression (1) the minimum delay of each path connecting any flip-flop FFi to the subsequent flip-flops should be larger than Tck+t_{FFh}+t_{ELsu}+D_{CMP}(Error!→Error)max−τ, while with expression (1i) the minimum delay of each of these paths should be larger than Tck+t_{FFh}+t_{ELsu}+D_{CMP}(Error!→Error)maxi−τ, which for many flip-flops will be shorter, as D_{CMP}(Error!→Error)max is the maximum value of D_{CMP}(Error!→Error)maxi for all flip-flops FFi. This cost reduction is also valid for constraint (3i) in comparison with constraint (3).

In addition, the cost reduction, achieved by enforcing the individualized constraint (1i) or (3i) for each flip-flop FFi, can be further improved by appropriate implementation of the comparator. The delays of the paths connecting different inputs of a comparator to its output are generally unbalanced due to two reasons: the gate-level implementation of the OR tree of the comparator may not be symmetric, as in the case of FIG. 19, where the number of inputs of the comparator is not a power of 2 and thus the gate-level implementation of the OR tree is necessarily asymmetric (i.e. the path connecting XO₁₁ to the output of the OR tree has less gates that the paths connecting the other inputs of the OR tree to its output); the lengths of the interconnections in these paths can also be different resulting in unbalanced delays. Then, to reduce the cost for enforcing the target constraint (i.e. constraint (1i) or constraint (3i)), we can rearrange the gate level implementation of the comparator and its place and route, in order to reduce the values of D_{CMP}(Error!→Error)maxi for the flip-flops FFi for which enforcing constraint (1i) or constraint (3i) induces high cost. This approach is similar to the approach described earlier for constraint (G1).

Concerning constraint (1i), the smaller than Tck+t_{FFh}+t_{ELsu}+D_{CMP}(Error!→Error)ₘₐₓᵢ−τ is the delay of a path connecting the output of a flip-flip FFi to the flip-flop inputs of the subsequent circuit stage, the larger is the cost for enforcing constraint (1i) for this path. Furthermore, the larger is the number of such paths the larger is the cost for enforcing constraint (1i). Thus, to optimize the cost reduction, we will select with priority such flip-flops FFi for connecting them to the comparator inputs that have lower delays D_{CMP}(Error!→Error)maxi. The similar approach is also valid for constraint (3i).

To further reduce the delays of the comparator paths connecting to flip-flops FFi requiring high cost for enforcing constraint (1i) or (3i) we can further imbalance the gate-level implementation of the OR tree, as in the example of FIG. 20.

Note however, that implementing the comparator in imbalanced manner for reducing the delay D_{CMP}(Error!→Error)maxi for certain of its branches, may increase the delay D_{CMP}(Error!→Error)ₘₐₓⱼ of certain other branches, as is the case of the example of FIG. 20. This may have as impact the increase of the cost for enforcing constraint (1i) or (3i) for the paths connecting flip-flop FFj to the flip-flops of the subsequent circuit stage. To avoid this drawback, we should implement the imbalanced comparator in a manner that, the delay D_{CMP}(Error!→Error)ₘₐₓⱼ is increased for flip-flops FFj for which the paths connecting a flip-flop FFj to the flip-flops of the subsequent pipe-line stage have large enough delays, so that the increase of delay D_{CMP}(Error!→Error)ₘₐₓⱼ will not induce extra cost for enforcing the target constraint ((1i) or (3i) or will induce very small extra cost.

Another issue that has also to be considered carefully is that reducing the delay D_{CMP}(Error!→Error)ₘₐₓⱼ for some branches of the comparator, may reduce the global minimum delay D_{CMP}(Error!→Error)ₘᵢₙ of the comparator, which, due to constraint (2) will reduce the value of τ, and by the way may violate constraint (4). Then, if constraint (4) is violated, we have to use some of the approaches presented earlier for relaxing (4) and/or reduce moderate the reduction of τ at a level that does not induce the violation of constraint (4).

Further reduction of the cost for enforcing the constraint selected for guarantying the detection of SEUs (i.e. constraint (1) or (3), or their individualized versions (1i) or (3i)) can be achieved by relaxing constraint (2) to increase the value of τ, or by relaxing the constraint (1)/(1i) or (3)/(3i) itself.

False-Alarms-Constraint Relaxing:

As shown earlier, if we use a value τ higher than that required for enforcing constraint (2), the circuit will produce false error detections (a false error detection is a detection activated when no error has occurred). A false error detection does not affect reliability, but it will interrupt the execution of the application to activate the error recovery process, and will increase the time required to execute a task. Infrequent false error detections will slightly affect the time required to execute a task and can be acceptable, but frequent ones may affect it significantly and have to be avoided. Thus, we should either enforce constraint (2) in all situations, by using the value of given by equation (5), or increase it at a value for which false error detections will not exceed a target occurrence rate.

Reliability-Constraint Relaxing:

Concerning reliability, zero failure rate is never achieved. Thus, for each component destined to an application, a maximum acceptable failure rate is fixed and then the component is designed to reach it. Consequently, the maximum acceptable SEU rate of a component will not be nil. Thus, a designer will never need to strictly enforce constraint (1) or constraint (3) if she/he opts for this constraint). Instead, it may accept to enforce it loosely, by setting a value of Dmin lower than the one imposed by the constraint (1) or (3), as far as it will satisfy its target maximum acceptable failure rate. Another way for which the constraint (1) or (3), could be loosely satisfied in a design, is due to the uncertainties of the circuit delays, like for instance the uncertainties of the interconnect delays; process, voltage and temperature variations, circuit aging, jitter, and clock skews. Thus, given these uncertainties, the designer may accept loose enforcement, but take the necessary actions to ensure that the percentage of SEUs that are related to circuit paths, which do not satisfy them, and are not detected, will not result in exceeding her/his maximum acceptable failure rate.

If constraint (C_{SEUrelaxed}) is not enforced, it is not guaranteed that all SEUs will be detected. Let us set D_{SEUrelaxed}=t_{RSh}+t_{ELh}+t_{ELsu}−D_{RSmin}+D_{CMP}(Error!→Error)ₘₐₓ−D_{CMP}(Error!→Error)ₘᵢ. Then, if Dmin′ is smaller than D_{SEUrelaxed}, SEUs occurring during an opportunity window of duration D_{SEUrelaxed} Dmin′ will not be detected. Thus, if Dmin′ is slightly smaller than the second part of constraint (C_{SEUrelaxed}), this opportunity window will be short and the occurrence probability of undetectable SEUS will be small (this probability is equal to (D_{SEUrelaxed}−Dmin′)/Tck, where Tck is the clock period). On the other hand, if Dmin′ is significantly smaller than the second part of constraint (C_{SEUrelaxed}), this opportunity window will be significant and the occurrence probability of undetectable SEUS will be significant. Hence, it is mandatory to enforce constraint (C_{SEUrelaxed}) with good margins, in order to be sure that in all situations this constraint will be satisfied (i.e. Dmin′ will be larger than or equal to the second part of this constraint). On the other hand, if a small nonzero probability P_{SEUund} of undetectable SEUs is acceptable in some application, then, if in some situations Dmin′ becomes smaller than the second part of constraint (C_{SEUrelaxed}), this will be acceptable if the difference D_{SEUrelaxed}−Dmin′ remains small, so that the occurrence probability of undetectable SEUs does not exceed P_{SEUund}.

Note furthermore that, if in some pipeline stage we enforce constraint (C_{SEU}), this enforcement can be achieved in the similar manner as the enforcement of constraint (C_{SEUrelaxed}) described above.

BOUNDARY FLIP-FLOPS: Note also that, an important difference between the constraint (1) (or its related constraint (C_{SEU})) and constraint (3) (or its related constraint (C_{SEUrelaxed})), is that, the former detects within the clock cycle they occur the SEUs whose propagation through the circuit can induce errors in a subsequent pipeline stage, while the later detects some of them in the subsequent clock cycle and in the subsequent pipeline stage. Thus, the second constraint will require error recovery approaches that work properly even when an error is detected one clock cycle after its occurrence. Another solution will consist in enforcing constraint (3) or its related constraint (C_{SEUrelaxed}) (or a loose version of it), for all regular flip-flops FF1 21 FF2 20, except for those who may complicate error recovery if their SEUs are detected one cycle later, or those for which detection is not possible to the subsequent pipe-line stage. This could be for instance the case of flip-flops, which are on the boundaries of the circuit part protected by the double-sampling scheme proposed here and thus, enforcing constraint (3)(C_{SEUrelaxed}) does not guaranty the SEU detection in the subsequent pipeline stage. Then, for these flip-flops, the designer can use different options:

A first option for these flip-flops consists in enforcing constraint (1) or its related constraint (C_{SEU}), or a loose version of it. Furthermore, if these flip-flops are late-detection-critical boundary flip-flops as defined in the section “METESTABILITY MITIGATION”, and the global error detection signal is not ready early enough to block the propagation to the subsequent block of the errors affecting these flip-flops, then, instead of using the global error detection signal for blocking this propagation, we can use a partial error detection signal, which will be produced by checking a subset of the flip-flops checked by the global error detection signal, which subset includes these late-detection-critical boundary flip-flops.

Another option consists in implementing these flip-flops by using SEU hardened flip-flops.

### Improving Double-Sampling for Latch-Based Designs

The important advantages of the architecture of FIGS. 2, and 3 is the elimination of the redundant sampling elements, which reduces significantly the area and power cost, as well as the cost reduction of constraints enforcement, achieved as this this elimination enables considering jointly the maximum and/or minimum delays of the combinational logic and of the comparator. As these improvements are based on the elimination of redundant sampling elements, they can also be exploited in other double-sampling architectures, which eliminate the sampling elements, like the architecture shown in FIG. 27, which combines latch-based design using non-overlapping clocks (Φ1, Φ2) with double-sampling [21]. In this Fig. odd latch-stages (L1, L3, . . . ) capture the outputs of odd combinational-circuit stages (CC1, CC3, . . . ) and are rated by clock Φ1; even latch-stages (L0, L2, . . . ) capture the outputs of even combinational circuit stages (CC2, . . . ) and are rated by clock Φ2. Furthermore, each latch-stage is blocked during the low level of its clock and is transparent during the high level of its clock. This implies that the inputs of even latch-stages are guaranteed to be stable until the end of the low level of Φ1, and the inputs of odd latch-stages are guaranteed to be stable until the end of the low level of Φ2. Thus, we dispose plenty of time for comparing the inputs of the latches against their outputs, to detect faults of large duration without adding redundant sampling elements. Hence, the only cost for implementing the double-sampling scheme is the cost of two comparators, Comparator 1 comparing the inputs against the outputs of odd latch stages, and Comparator 2 comparing the inputs against the outputs of even latch stages. Two Error Latches (Error Latch 1 and Error Latch 2) are also used for capturing the error signal generated by the two OR trees. The latching event of Error Latch 1 (i.e. the instant at which Error Latch 1 captures the value present on its input) occurs at a time τ2 after the rising edge of clock signal Φ2, and the latching event of Error Latch 2 occurs at a time τ1 after the rising edge of clock signal Φ1. Note also that the elements referred in FIG. 27 as Error Latch 1 and Error Latch 2 can be implemented by using latch cells or by using flip-flop cells.

A first important advantage of this architecture is that it does not use redundant sampling elements, reducing area and more drastically power cost. A second important advantage is that, the above-mentioned stability of the latch inputs does not depend on short path delays. Thus, we do not need to insert buffers in the combinational logic for enforcing the short-path constraint, which also reduces significantly area and power penalties.

This architecture allows detecting timing faults of large duration, which is important for advanced nanometric technologies, which are increasingly affected by timing faults, as well as for applications requiring using very low supply voltage for reducing power dissipation, as voltage supply reduction may induce timing faults. Furthermore, this architecture also detects Single-Event Transients (SETs) of large duration. More precisely, in FIG. 27, an SET affecting during a clock cycle i the value captured by a latch L1j belonging to the stage of latches L1, is guaranteed to be detected if its duration does not exceed the value:

D_{SETdet}=tᵣ₂ᵢ+τ2−t_{EL1su}−D_{CMP1}(Error!→Error)ₘₐₓⱼ−t_{fli}−tₕ

where t_{fli} is the instant of the falling edge of $1 during the clock cycle i, tₕ is the hold time of the latches, tᵣ₂ᵢ is the instant of the raising edge of clock signal Φ2 subsequent to the instant t_{fli}, t_{EL1su} is the set-up time of the Error Latch 1, and D_{CMP1}(Error!→Error)ₘₐₓⱼ is the maximum delay of the propagation of the fast transition (non-error state to error state) through the path of Comparator 1 that connects the output of latch L1j to the input of the Error Latch 1. Then, if a larger duration of detectable faults is required, a solution is to increase the value of τ2, but the maximum value allowed for τ2 is τ2=D_{CC1minj}+D_{CMP1}(Error!→Error)ₘᵢₙⱼ−t_{EL1h}+D_{Lmax}, as result from constraint (Z2) shown later in this text. Then, if we need to increase the duration of SETs guaranteed to be detected at a value larger than the duration allowed by this maximum value of τ2, we can increase the value of the difference tᵣ₂ᵢ−t_{fli}, where tᵣ₂ᵢ is the instant of the rising edge of a cycle i of Φ2 consecutive to the falling edge t_{fli} of cycle i of Φ1. One option for increasing this difference consists in increasing the period of the clock signals Φ1 and Φ2 in order to increase the difference between the falling edge of Φ1 and the consecutive rising edge of Φ2, as well as the difference between the falling edge of Φ2 and the consecutive rising edge of Φ1. However, this will reduce the circuit speed. Then, another option allowing to reduce the difference tᵣ₂ᵢ−t_{fli} consists in leaving unchanged the clock period but modify the duty cycle of the clock signals Φ1 and Φ2 by reducing the duration of their high levels. Thus, the architecture of FIG. 27 is of high interest for space applications, where high energy ions may induce SETs of large durations. Nevertheless, in such applications it is also very important to detect SEUs,

An SEU can occur in a latch at any instant of the clock cycle. Then, an SEU affecting during a clock cycle i any odd latch L1j of the stage of latches L1, may escape detection if the erroneous value induced by this SEU reaches the Error Latch 1 after the beginning of its setup time (i.e. after tᵣ₂ᵢ+τ2−t_{EL1su}). This can happen if this SEU occurs after the instant T_{ND}=tᵣ₂ᵢ+τ2−t_{EL1su}−D_{CMP1}(Error!→Error)ₘₐₓⱼ, where tᵣ₂ᵢ is the instant of the raising edge of clock signal Φ2 during the clock cycle i, t_{EL1su} is the set-up time of the Error Latch 1, and D_{CMP1}(Error!→Error)ₘₐₓⱼ is the maximum delay of the propagation of the fast transition (non-error state to error state) through the path of Comparator 1 that connects the output of latch L1j to the input of the Error Latch 1. This SEU may affect the values latched by the subsequent stage of latches (i.e. latch stage L2), if it reaches this stage of latches before the end of their hold time of clock cycle i (i.e. before t_{f2i}+tₕ). This can happen if the SEU occurs before the instant T_{LER}=t_{f2i}+tₕ−D_{CC2minj}, where t_{f2i} is the falling edge of Φ2, tₕ is the hold time of the latches, and D_{CC2minj} is the minimum delay of the paths connecting the output of latch L1j to the outputs of the combinational circuit CC2. Thus, an SEU affecting a latch L1j of the stage of latches L1, may remain undetectable and induce errors in the subsequent stage of latches L2 if it occurs during the time interval (T_{ND}, T_{LER}). Thus, the condition T_{ND}≥T_{LER} (i.e. tᵣ₂ᵢ+τ2−t_{EL1su}−D_{CMP1}(Error!→Error)ₘₐₓⱼ≥t_{f2i}+tₕ−D_{CC2minj}) guaranties that no undetectable SEU can affect the correct operation of the circuit, resulting in:

D_{CC2minj}−D_{CMP}1(Error!→Error)ₘₐₓⱼ≥T_{H}−τ2+tₕ+t_{EL1su} (Z1)

where T_{H} is the duration of the high level of the clock signal Φ2 (i.e. T_{H}=t_{f2i}−tᵣ₂ᵢ).

We note that, the higher is the value of τ2 the easier is the enforcement of constraint (Z1). Thus, for reducing the cost for enforcing this constraint, we have interest to maximize the value of τ2, but on the other hand we may have interest to reduce the value of τ2 for activating the error detection signal as early as possible, in order to simplify the error recovery process that should be activated after each error detection. Furthermore, the maximum value that can be allocated to τ2 is limited by the constraint (Z2), which is required for avoiding false alarms (i.e. the activation of the error detection signal in situations where no error has occurred in the circuit). Indeed, the new values present on the inputs of the stage of latches L0, start propagation through these latches at the rising edge tᵣ₂ᵢ of signal Φ2. Then, if after propagation through: the latches of stage L0, the combinational circuit CC1, and the Comparator 1; these new values reach the input of the Error Latch 1 before the end of its hold time (i.e. before tᵣ₂ᵢ+2+t_{EL2h}), a false error detection will be indicated on the output of the Error Latch 1. The avoidance of such false alarms is guaranteed if for each latch L1j of stage L1 the following the constraint is satisfied: tᵣ₂ᵢ+D_{Lmin}+D_{CC1minj}+D_{CMP1}(Error!→Error)ₘᵢₙⱼ≥tᵣ₂ᵢ+τ2+t_{EL2h}, which gives:

D_{CC1minj}+D_{CMP1}(Error!→Error)ₘᵢₙⱼ>τ2+t_{EL1h}−D_{Lmax} (Z2)

where D_{Lmin} is the minimum Ck-to-Q delay of the latches, D_{CC1minj} is the minimum delay of the propagation of the fast transition (non-error state to error state) through the paths of the combinational circuit CC1 connecting the outputs of the stage of latches L0 to the input of latch L1j, and D_{CMP1}(Error!→Error)ₘᵢₙⱼ is the minimum delay of the propagation of the fast transition (non-error state to error state) through the path of Comparator 1 that connects the input of latch L1j to the input of the Error Latch 1; and t_{EL1h} is the hold time of the Error Latch 1. To minimize

A last constraint concerning τ2 requires that the propagation through Comparator 1 of the new values captured by any latch Lj1 at the raising edge tᵣ₂ᵢ of Φ1 reach the inputs of the Error latch 1 before the starting instant of its setup time (i.e. before tᵣ₂ᵢ+τ2−t_{EL1su}). This is guaranteed by the constraint: tᵣ₂ᵢ+τ2−t_{EL1su}≥tᵣ₂ᵢ+t_{readymaxj}+D_{CMP1maxj}+D_{Lmax}, resulting in:

τ2≥D_{CMP1maxj}+t1_{ready.maxj}+D_{Lmax}+t_{EL1su} (Z3)

where D_{CMP1maxj} is the maximum delay of the path of Comparator 1 connecting the output of latch Lj1 to the input of the Error Latch 1, and t1_{ready.maxj} is the latest instant after the tᵣ₂ᵢ, at which the new value computed at cycle i by the combinational logic CC1 is ready on the input of latch Lj1. In latch-based implementations that not use time borrowing, the inputs of all latches are ready before the instant tᵣ₂ᵢ. Thus, in this case we will have t1_{ready.maxj}=0. In latch-based implementations that use time borrowing, for some latches we will have t1_{ready.maxj}=0 and for some other latches (those borrowing time from their subsequent pipeline stage) we will have 0<t1_{ready.maxj}≤t_{f2i}−tₛᵤ.

The constraints Z1, Z2, Z3, elaborated for SEUs affecting any latch Lj1 belonging to the stage of latches L1, are valid for any latch belonging to a stage of latches that is not on the board of the circuit. To express these constraints for SEUs affecting latches belonging to any stage of latches, let us represent by: L2k the stages of even latches, CC2k the stages of even combinational circuits; L2k+1 the stages of odd latches, and CC2k+1 the stages of odd combinational circuits.

Then constraints Z1, Z2, and Z3 for SEUs affecting any latch Lj2k+1 belonging to any odd stage of latches L2k+1, which is not on the border of the circuit, are expressed as:

D_{CC2k}+2minj−D_{CMP1}(Error!→Error)ₘₐₓⱼ≥T_{H}−τ2+tₕ+t_{EL1su} (O1)

D_{CC2k}+1minj+D_{CMP1}(Error!→Error)ₘᵢₙⱼ≥τ2+t_{EL1h}−D_{Lmax} (O2)

τ2≥D_{CMP1maxj}+t2k+1_{ready.maxj}+D_{Lmax}+t_{EL1su} (O3)

On the other hand, constraints Z1, Z2, and Z3 for SEUs affecting any latch Lj2k belonging to any even stage of latches L2k, which is not on the border of the circuit, are expressed as:

D_{CC2k}+1minj−D_{CMP2}(Error!→Error)ₘₐₓⱼ≥T_{H}−τ1+tₕ+t_{EL2su} (E1)

D_{CC2kminj}+D_{CMP2}(Error!→Error)ₘᵢₙⱼ≥τ1+t_{EL2h}−D_{Lmax} (E2)

τ1≥D_{CMP2maxj}+t2k_{ready.maxj}+D_{Lmax}+t_{EL2su} (E3)

To describe the way we can enforce these constraints at reduced cost, let as consider as example the constraints O1, O2, and O3, concerning SEUs affecting any latch Lj2k+1. The minimum value of τ2 allowed by constraint O3 is τ2−D_{CMP1maxj}+t2k+1_{ready.maxj}+D_{Lmax}+t_{EL1su}. Reducing as much as possible this value is of interest in order to activate the error detection signal err1 as early as possible. Reducing the value of τ2 is also of interest as it reduces the cost for enforcing constraint O2. To further reduce this value, a first option consists in reducing the maximum delay of signal propagation through the Comparator 1, during the normal operation of the circuit (i.e. when no errors occur) and during the cycle of error occurrence. This can be done by means of the approach described in this patent, which adds a hazards-blocking stage in the Comparator 1 tree, and reduces significantly this signal propagation delay in the part 2 of the Comparator 1 (the hazards-free part of the Comparator 1). In addition, the delay of this part is further reduced by implementing this comparator part by means of NOR gates having large number of inputs. Hence, these approaches enable both, reducing the cost for enforcing constraint O2 and activating earlier the error detection signal. An issue of the reduction of τ2 is however that it may increase the cost for enforcing constraint O1, as a smaller value of τ2 will require a larger value of D_{CC2k+1minj} for enforcing constraint O1. Nevertheless, as the approach using in the hazards-free part of the Comparator 1 NOR gates having large number of inputs, reduces the propagation delay of the transitions Error!→Error, this approach also reduces the value of D_{CMP1}(Error!→Error)ₘₐₓⱼ, and thus it reduces the value of D_{CC2k+1minj} required for enforcing constraint O1, and moderates this way the increase of the cost for enforcing constraint O1 induced by the reduction of τ2. Finally, to further reduce the total cost for enforcing constraints O1 and O2, we can employ the approach proposed earlier in the text of this patent for the double-sampling architecture illustrated in FIGS. 2, 3, 4, 5, 6, 7, 8, 9, which reduces the cost of constraint-enforcement, by using an unbalanced comparator as the one illustrated in FIG. 20. Using this approach for reducing the cost for enforcing the short-paths constraint O2 is possible for the architecture illustrated in FIG. 27, because similarly to the architecture illustrated in FIGS. 2, 3, . . . 9, the architecture of FIG. 27 does not use redundant sampling elements, and this way there are paths of the combinational logic connected directly to the comparator, resulting in a short-paths constraint O2, which uses the sum of delays of paths traversing the combinational logic and of paths traversing the comparator. Finally, we can also use an unbalanced implementation of the comparator, for reducing the cost required to enforce constraint O1, because this constraint too involves both, the delay of the comparator path starting from a latch Lj2k+1 and the delays of the paths of the subsequent combinational logic staring from the same latch Lj2k+1. This is because constraint O1 guaranties the detection of the SEUs that affect a latch Lj2k+1 and may induce errors in the subsequent stage of latches. Thus, it involves both: the delay of the comparator path starting from latch Lj2k+1 (due to the constraint concerning the detection of the SEU) and the delays of the paths of the subsequent combinational logic staring from latch Lj2k+1 (due to the constraint concerning the induction by the SEU of errors in the subsequent stage of latches). Note that, this is also the case for SEUs affecting any double-sampling architectures (i.e. those using redundant sampling elements and those not using such elements), and therefore, in all these architectures we can use unbalanced comparators for reducing the cost required to enforce the constraint that guaranties the detection of SEUs that can induce errors in the subsequent pipeline stage. Indeed, let us consider a circuit in which a set Scse of sampling elements (latches or flip-flops) are verified by a comparator COMP that compares the values present at the outputs of the sampling elements of set Scse against the values of other signals, which during fault-free operation are equal to the values present on the outputs of the sampling elements of set Scse. Then, let: SEj be any sampling element belonging to the set Scse; EL be the sampling element (latch or flip-flop) latching the output of COMP; t_{ELlatchingedge} be the clock latching edge of EL; t_{ELsu} be the setup time of EL; D_{CMP} (Error!→Error)ₘₐₓⱼ be the maximum delay of the propagation of transition Error!→Error through the comparator path connecting the output of SEj to the input of EL; S_{SEj} be the set of sampling elements such that there are paths staring from the output of SEj and ending at their inputs; t_{SEjlatchingedge} be the clock latching edge of the set S_{SEj} of sampling elements; t_{SEjh} be the hold time of the set S_{SEj} of sampling elements; and D_{CCminj} be the minimum delay of the paths connecting the output of SEj to the inputs of the sampling elements of the set S_{SEj} of sampling elements. Then, the following constraint ensures that any SEU occurring in any sampling element SEj is guaranteed to be detected if its propagation through the subsequent combinational logic induces errors in any other sapling elements:

D_{CCminj}−D_{CMP}(Error!→Error)ₘₐₓⱼ≥t_{SEjlatchingedge}−t_{ELlatchingedge}+t_{SEjh}+t_{ELsu} (G1)

For reducing the cost of constraint (G1), we can use an unbalanced comparator implementation such that the outputs of sampling elements for which the value D_{CCminj} is low are preferably connected to comparator inputs for which the value of D_{CMP}(Error!→Error)ₘₐₓⱼ is low, and vice versa, so that we increase the value of the sum

$${\sum }_{j : {SEj}_{\overline{G 1}}} {D}_{CCmin j} - {D}_{CMP} ( Error ! \to Error ) max j , which is summed$$

$$over the set of indexes j$$

corresponding to the sampling elements SEj for which constraint (G1) is not satisfied, as in this case we reduce the total sum of delays required for increasing the values of D_{CCminj} in order to enforce constraint (G1) for all the sampling elements of the set Sce. The same approach can be used for reducing the cost for enforcing constraint (O1). However, for a latch Lj2k+1 for which the value of D_{CC2k+1minj} is low, implementing an unbalanced comparator to reduce the value of D_{CMP1}(Error!→Error)ₘₐₓⱼ in order to reduce the cost for enforcing constraint (O1), will also increase the value of D_{CMP1}(Error!→Error)ₘᵢₙⱼ and may increase the cost for enforcing constraint (O2). Thus, to reduce the total cost for enforcing constraints (O1) and (O2), we can use an unbalanced comparator implementation such that we increase as much as possible the value of the sum

$${\sum }_{j : Lj 2 k + {1}_{\overline{O 1}}} {D}_{CC 2 k + 2 min j} - {D}_{CMP 1} ( Error ! \to Error ) max j + {\sum }_{j : Lj 2 k + {1}_{\overline{O 2}}} {D}_{CC 2 k + 1 min j} + {D}_{CMP 1} ( Error ! \to Error ) min j$$

where the first sum is summed over the indices j corresponding to latches Lj2k+1 for which constraint (O1) is not satisfied, and the second sum is summed over the indices j corresponding to latches Lj2k+1 for which constraint (O2) is not satisfied.

Another approach for reducing the cost required in order to enforce constraint (O1) is based on the fact that: in latch based designs, a latch Lj2k+2 belonging to an even stage of latches L2k+2 latches the value Vji present on its input at the instant t_{f2i} of the falling edge of cycle i of clock signal Φ2; but, as the latches of even pipeline stages are transparent during the high level of clock signal Φ2, this value starts propagation to the subsequent pipeline stage before t_{f2i}, i.e. at the instant of the high level of Φ2 of clock cycle i at which the input of Lj2k+2 has reached its steady state value Vji. Thus, synthesis tools of latch-based designs consider this timing aspect and the synthesized circuits may be such that, a modification of the state of a latch at a late instant of the high level of its clock may not have time to reach the subsequent stage of latches before the falling edge of their clock. Thus, an error affecting the input of a latch Lj2k+2 at a late instant of the high level of Φ2 can be latched by Lj2k+2, but not have time to reach the subsequent stage of latches L2k+3 before the falling edge of Φ1. In this case the error latched by Lj2k+2 will be masked. Furthermore, even if this error in Lj2k+2 reaches the stage L2k+3 before the falling edge of $1, its late arrival to L2k+3 may result in no error latched by the subsequent stage of latches L2k+4, and so on. This analysis shows that, an SEU occurring in a latch Lj2k+1 may induce errors to the subsequent stage of latches L2k+2, but masked in the subsequent latch stages. Based on these observations, timing analysis tools can be used to determine the instant t_{fli-1}+tⱼₑₘ belonging to the high level of clock cycle i−1 of Φ1, for which any value change on the input of latch Lj2k+1 is masked during its propagation through the subsequent pipeline stages before reaching the outputs of the latch-based design (e.g. its primary outputs or its outputs feeding a memory block internal to the design). Then, the constraint (O1) guarantying that SEUs affecting Lj2k+1 are either detected or do not induce errors in the system, can be relaxed by setting T_{ND}≥t_{fli-1}+tⱼₑₘ instead of T_{ND}≥T_{LER}, where T_{ND}=tᵣ₂ᵢ+τ2−t_{EL1su}−D_{CMP1}(Error!→Error)ₘₐₓⱼ and T_{LER}=t_{f2i}+tₕ−D_{CC2k+2minj}. Thus, the relaxed constraint (O1) becomes: tᵣ₂ᵢ+τ2−t_{EL1su}−D_{CMP1}(Error!→Error)ₘₐₓⱼ t_{fli-1}+tⱼₑₘ.

Finally an efficient approach for reducing the cost required to enforce constraint (O2), consists in modifying the clock signals Φ1 and Φ2 in order to increase the difference between the falling edge of Φ1 and the consecutive rising edge of Φ2, as well as the difference between the falling edge of Φ2 and the consecutive rising edge of 1. This approach has also the advantage to increase the duration of detectable SETs, as was shown earlier in this text.

Combining the above approaches will result in very significant reduction of the cost required to enforce constraints (O1), (O2), (O3).

Obviously, all these approaches are also valid for reducing the cost required to enforce constraints E1, E2, E3, as these constraints are similar (O1), (O2), (O3).

### Efficient Implementation of Latch-Based Double-Sampling Architecture Targeting Delay Faults.

In the previous discussion we addressed the improvement of the architecture of FIG. 27 for SETs and SEUs. Now, we consider the case of delay faults. Delay faults occur when a fault increases the delay of a circuit path.

As a delay fault is induced by the increase of the delay of a path, the higher is the delay of the path the higher the possible increase of its delay, and vice versa. So, it is realistic to consider that the maximum value of the delay fault that could affect a path is proportional to the maximum delay of this path.

In this discussion we consider latch-based designs such that the clock signals Φ1 and Φ2 are symmetric. That is, they have the same period Tck; they have the same duty cycle, meaning that their high levels have the same duration T_{H}, and their low levels have the same duration T_{L}; and the time separation the rising edge of Φ1 from the subsequent rising edge of Φ2 is equal to the time separation the rising edge of Φ2 from the subsequent rising edge of Φ1; and this is also the case for their falling edges. This also implies that the time separating subsequent rising edges of the two clocks is equal to Tk/2, and this is also the case for the time separating subsequent falling edges of the two clocks.

Double-sampling architectures can be synthesized to use or not use time borrowing. When no time borrowing is used, the maximum delay of any path connecting the input of a latch to the inputs of the subsequent stage of latches does not exceed the value Tck/2 (i.e. the half of the clock period). Thus, data on the inputs of any latch are ready no later than the rising edge of its clock.

When time borrowing is used, the data on the inputs of some latches are ready after the rising edge of its clock. This can happen when the delay of a path connecting the input of a latch to the inputs of the subsequent stage of latches exceeds the value Tck/2, or if a path from the previous pipeline stage borrows time from a path and the sum of the borrowed time and of the delay of the path exceeds Tck/2. On the other hand, as the circuit is synthesized so that in fault-free operation it does not to produce errors on the values captured by the latches, the data will be ready on the inputs of any latch no later than t_{F}−tₛᵤ, where t_{F} is the instant of the falling edge of the clock of this latch and tₛᵤ is the setup time of this latch. This also implies that the time borrowed from a pipeline stage by other pipeline stages can never exceed the value T_{H}−tₛᵤ; the sum of the maximum delay of any path of a pipeline stage plus the time that other paths can borrow from this path cannot exceed the value Dmax=1.5 T_{H}+0.5T_{L}−tₛᵤ; and if a path of a pipeline stage, which is not affected by time-borrowing, the theoretically admissible delay of this path cannot exceed the value Dmax=1.5T_{H}+0.5T_{L}−tₛᵤ. Considering designs where T_{H}=Tck/4, the maximum time that can be borrowed could never exceed Tck/4−tₛᵤ; the maximum delay of a path could not exceed 3Tck/4−tₛᵤ, and the maximum delay of a path plus the time that other paths can borrow from this path could not exceed 3Tck4−tₛᵤ. Note that, T_{H}−Tck/4, is the preferable value of T_{H} that we will consider in this analysis, as it maximizes the tolerable clock skews: which is important in designs targeting high reliability; and which also enables reducing the buffers of the clock trees and thus their power dissipation, making it very attractive in designs targeting low power.

Concerning the cost reduction of the implementation of the double-sampling architecture of FIG. 27, we observe that, if we consider faults of certain duration, then, when a latch is fed by paths that have short delays, the considered faults may not induce errors to these paths. Thus, this latch will not require to be protected. Then, our goal is to determine the latches, which do not need protection, in order to reduce cost. However, this task is not simple, because a delay fault which do not induce errors on a latch fed by the path affected by this fault, may induce timing borrowing from the subsequent pipeline stage, and this time borrowing may induce errors in this stage, or not induce errors in this stage but induce time borrowing from the next pipeline stage, and show on. The solutions presented next take also into account these cases.

Let us now consider a latch-based design, which does not uses time borrowing and which satisfies the following conditions:
a. the delays of the terminal pipeline stages of the design do not exceed Td/2 (where Td=Tck/2, and terminal pipeline stages means the stages whose outputs are primary outputs of the design or inputs to internal memories of the design);
b. the double-sampling architecture of FIG. 27 is used for protecting all latches fed by paths whose maximum delay is equal to or larger than 0.75×Td;
c. the constraints τ2≥D_{CMP1}(Error!→Error)ₘₐₓ+t_{EL1su} and τ1≥D_{CMP2}(Error!→Error)ₘₐₓ+t_{EL2su} are satisfied; Then for this design we show that all delay faults of duration Df≤Dmax−tₛᵤ that induce errors to any latch are detected, where Dmax is the maximum delay of the path affected by the fault and tₛᵤ is the setup time of the latches of the even and odd latch stages L0, L1, L2, L3, . . . .

Thus, in a latch-based design which does not uses time borrowing, the above results allows detecting delay faults of very large duration, by selecting any values for τ2 and τ1 that enforce the constraints of point c−, and reducing the cost of the architecture of FIG. 27, by using the comparators to check only the latches that are fed by paths whose maximum delay is equal to or larger than 0.75×Td.

Let us now consider any latch-based design using time-borrowing and which satisfies the conditions described above in points a), b), and c). Then, by considering that in such a design the maximum delay of some paths takes the maximum delay value 1.5×Td−tₛᵤ that is theoretically allowed in implementations using time-borrowing, we show that all delay faults of duration Df≤Dmax/3 that induce errors to any latch are detected, where Dmax is the maximum delay of the path affected by the fault and tₛᵤ is the setup time of the latches of the even and odd latch stages L0, L1, L2, L3, . . . .

Thus, for designs using time borrowing the same conditions as for the designs not using time borrowing lead to lower duration of detectable faults. This is a disadvantage, however, using time-borrowing allows other improvements with respect to designs not using time-borrowing, such as speed increase or power reduction.

An important remark concerning the above results for time borrowing implementation, is that the above results for implementations using time-borrowing, were obtained by considering that the maximum delay of some paths take the theoretically admissible maximum delay value 1.5×Td−tₛᵤ. However, in most practical implementations, the maximum path delay will take a value lower than 1.5×Td−tₛᵤ. Thus, in most practical cases, the above results will give pessimistic values for the duration of covered faults. Thus, to determine the actual durations of covered faults, we now consider that the maximum path-delay value is equal to c×Td, with c×Td<1.5 Td−tₛᵤ. In this case we obtain the following results.

Let us consider a latch-based design, which uses time borrowing and which satisfies the following conditions:
a. the delays of the terminal pipeline stages of the design do not exceed Td/2;
b. the maximum delay of any path does not exceed the value c×Td, with c×Td<1.5 Td−tₛᵤ;
c. the double-sampling architecture of FIG. 27 is used for protecting all latches fed by paths whose maximum delay is larger than or equal to 2c/(2c+1)×Td;
d. the constraints τ2≥D_{CMP1}(Error!→Error)ₘₐₓ+t_{EL1su} and τ1≥D_{CMP2}(Error!→Error)ₘₐₓ+t_{EL2su} are satisfied;

Then for this design we show that all delay faults of duration Df≤(½c)×Dmax that induce errors to any latch are detected.

We observe that, by considering more realistic maximum durations of delay faults which are shorter than the theoretically admissible maximum path delay we find that the duration of covered faults is Df≤(½c)×Dmax, which is higher than the duration of faults covered when we consider that the maximum path delays are equal to their theoretically admissible maximum value. For instance, if the maximum delay c×Td is equal to 1.2×Td (i.e. c=1.2), the duration of covered faults is Df=(½c)×Dmax=0.4166×Dmax, which is 25% larger than the duration Df=Dmax/3 of faults covered when considering the theoretically admissible maximum path delay.

Thanks to the above results, obtained for implementations of latch-based designs using or not using time borrowing, the designer can reduce significantly the cost for implementing the double-sampling architecture in these designs, while achieving high fault coverage.

### Detection of SEUs in the Architecture of FIG. 3

To determine the constraint guarantying that all SEUs affecting any regular flip-flop FF2j 20 checked by the double-sampling architecture of FIG. 3, we can replace in the generic constraint (G1) the values corresponding to the architecture of FIG. 3. As described earlier, in the architecture of FIG. 3 the instant t_{ELk} of the latching edge of the Error Latch at which this latch latches the result of the comparison of the data latched by the regular flip-flops FF2 20 at the instant tᵣᵢ₊₁ of the rising edge of cycle i of clock signal Ck, is equal to t_{ELk}=τ+(k−1)T_{CK}+tᵣᵢ₊₁. Then, if S_{FFj} is the set of flip-flops such that there are paths staring from the output of FF2j and ending at their inputs, the values resulting from the propagation through these paths of the values captured by FF2j at the rising edged of clock cycle i+1, will be captured by the flip-flops of the set S_{FFj} at the rising edge of clock cycle i+2. Thus, in constraint (G1) we can set t_{ELlatchingedge}=t_{ELk}=τ+(k−1)T_{CK}+tᵣᵢ₊₁, and t_{SEjlatchingedge}=tᵣᵢ₊₂. We also have t_{SEjh}=t_{FFh} (the hold time of the regular flip-flops). Thus, we obtaining the constraint: D_{CCminj}−D_{CMP}(Error!→Error)ₘₐₓⱼ≥tᵣᵢ₊₂−τ−(k−1)T_{CK}−tᵣᵢ₊₁+t_{FFh}+t_{ELsu}, where D_{CMP} (Error!→Error)ₘₐₓⱼ is the maximum delay of the propagation of transition Error!→Error through the comparator path connecting the output of the regular flip-flop FF2j 20 to the input of the error Latch 40, and D_{CCminj} is the minimum delay of the paths connecting the output of the regular flip-flop FF2j 20 to the inputs of the flip-flops of the set S_{FFj}.

Then as tᵣᵢ₊₂−tᵣᵢ₊₁−T_{CK} (i.e. the time difference between the rising edge of clock cycles i+2 and i+1 is equal to the clock period), we obtain the constraint:

D_{CCminj}−D_{CMP}(Error!→Error)ₘₐₓⱼ≥−τ−(k−2)T_{CK}+t_{FFh}+t_{ELsu} (F)

which ensures that any SEU occurring in any flip-flop FF2 20 checked by the architecture of FIG. 3, is guaranteed to be detected if its propagation through the subsequent combinational logic induces errors in any other flip-flops.

### REFERENCES

[1] A. Drake, R. Senger, H. Deogun et al., “A Distributed Critical-Path Timing Monitor for a 65 nm High-Performance Microprocessor,” ISSCC Dig. Tech. Papers, February 2007
[2] T. Burd, T. Pering, A. Stratakos, R. Brodersen, “A Dynamic Voltage Scaled Microprocessor System,” IEEE J. Solid-State Circuits, vol. 35, no. 11, November 2000
[3] M. Nakai, S. Akui, K. Seno et al., “Dynamic Voltage and Frequency Management for a Low-Power Embedded Microprocessor,” IEEE J. Solid-State Circuits, vol. 40, no. 1, January 2005
[4] K. Nowka, et al., “A 32-bit PowerPC System-on-a-chip With Support for Dynamic Voltage Scaling and Dynamic Frequency Scaling,” IEEE J. Solid-State Circuits, vol. 37, no. 11, November 2002
[5] Nicolaidis M., “Time Redundancy Based Soft-Error Tolerant Circuits to Rescue Very Deep Submicron”, 17th IEEE VLSI Test Symposium”, April 1999, Dana Point, Calif.
[6] Nicolaidis M., “Circuit Logique protégé contre des perturbations transitoires”, French patent, filed Mar. 9, 1999—US patent version “Logic Circuit Protected Against Transient Disturbances”, filed Mar. 8, 2000
[7] L. Anghel, M. Nicolaidis, “Cost Reduction and Evaluation of a Temporary Faults Detecting Technique”, Design Automation and Test in Europe Conference (DATE), March 2000, Paris
[8] D. Ernst et al, “Razor: A Low-Power Pipeline Based on Circuit-Level Timing Speculation”, Proc. 36th Intl. Symposium on Microarchitecture, December 2003
[9] D. Ernst et al, “Razor: Circuit-Level Correction of Timing Errors for Low-Power Operation”, IEEE Micro, Vol. 24, No 6, November-December 2003, pp. 10-20
[10]S. Das et al, “A Self-Tuning DVS Processor Using Delay-Error Detection and Correction” IEEE Symp. on VLSI Circuits, June 2005.
[11]M. Agarwal, B. C. Paul, M. Zhang et S. Mitra, “Circuit Failure Prediction and Its Application to Transistor Aging”, 5th IEEE VLSI tests Symposium, May 6-10, 2007 Berkeley, Calif.
[12]M. Nicolaidis, “GRAAL: A New Fault-tolerant Design Paradigm for Mitigating the Flaws of Deep-Nanometric Technologies”, Proceedings IEEE International Test Conference (ITC), Oct. 23-25, 2007, Santa Clara, Calif.
[13]K. A. Bowman, et al., “Energy-Efficient and Metastability-Immune Resilient Circuits for Dynamic Variation Tolerance,” IEEE JSSC, pp. 49-63, January 2009
[14] S. Das et al. “Razorll: In Situ Error Detection and Correction for PVT and SER Tolerance”, IEEE Journal of Solid-State Circuits, vol. 44, no. 1, January 2009
[15] H. Yu, M. Nicolaidis, L. Anghel, N. Zergainoh, “Efficient Fault Detection Architecture Design of Latch-Based Low Power DSP/MCU Processor”, Proc. of 16th IEEE European Test Symposium (ETS'11), Mai 2011, Trondheim, Norvege
[16] Franco P., McCluskey E. J., “On-Line Delay Testing of Digital Circuits”, 12th IEEE VLSI Test Symp., Cherry Hill, N.J., April 1994.
[17] Nicolaidis M., “Double Sampling Architectures”, 2014 International Reliability Physiscs Symp. (IRPS), Jun. 1-5, 2014, Waikoloa, Hi.
[18] F. Pappalardo, G. Notarangelo, E. Guidetti, US patent no 20110060975 A1 “System for detecting operating errors in integrated circuits”, Deposant STMIcroelectronics”
[19] G. L. Frenkil, “Asynchronous to synchronous particularly CMOS synchronizers.” U.S. Pat. No. 5,418,407. 23 May 1995
[20] S. Das et al., “Razorll: In situ error detection and correction for PVT and SER tolerance”, IEEE J. Solid-State Circuits, January 2009, Vol. 44, Issue1, pp. 32-48.
[21] M. Nicolaidis, “Electronic circuitry protected against transient disturbances and method for simulating disturbances”, U.S. Pat. No. 7,274,235 B2, Publication date Sep. 25, 2007
[22] M. Nicolaidis, “Double-Sampling Design Paradigm—A Compendium of Architectures”, IEEE Transactions on Device and Materials Reliability, Pages 10-23, Volume: 15 Issue: 1, March 2015

1. A circuit protected against delay faults and transient faults of selected duration, the circuit comprising:
a combinatory logic circuit having at least one input and one output;
at least a first sampling element having its output connected to said at least one input and activated by a clock, wherein the period of the clock is selected to be larger than the maximum delay of said combinatory logic circuit plus the maximum delay of said first sampling element;
at least a second sampling element having its input connected to said at least one output and activated by said clock;
a comparator circuit for analyzing the input and output of each said second sampling element and providing on its output an error detection signal, the comparator circuit setting said error detection signal at said pre-determined value if the input and output of at least one said second sampling element are different; and
a third sampling element having its input connected to the output of said comparator and activated by said clock delayed by a first predetermined delay, say first predetermined delay is equal to:
a first integer value equal to the Integer part of the division of said selected fault duration by: the maximum delay of said comparator, minus the maximum delay of said comparator for the transitions from the non error to the error state, plus the maximum delay of said second sampling element plus the setup time of said second sampling element plus a selected timing margin;
multiplied by: the fractional part of a second division, say second division is the division of: said selected fault duration, plus the maximum delay of said comparator for the transitions from the non error to the error state, plus the setup time of said third sampling element, minus the setup time of said second sampling element; by the period of said clock;
plus the difference of the integer value 1 minus said first integer value, multiplied by the fractional part of a third division, say third division is the division of: the maximum delay of said second sampling element, plus the maximum delay of said comparator, plus the setup time of said third sampling element, plus said selected timing margin; by the period of said clock;
whereby the minimum value of: the minimum delay of said first sampling element plus the minimum delay of each path of said combinatory logic circuit plus the minimum delay of the path of said comparator circuit connecting the output of said this path of said combinatory circuit to the output of said comparator plus a selected timing delay; is larger than said first predetermined delay, plus the hold time of said third sampling element, plus said first integer value multiplied by the integer part of said second division, plus the difference of the integer value 1 minus said first integer value, multiplied by the fractional part of said third division.

2. The circuit protected against timing errors and parasitic disturbances of claim 1, wherein: said fourth sampling element is driven by the opposite edge of the same clock signal as said first and second sampling elements delayed by a second predetermined delay, say second predetermined delay is equal to said first predetermined delay minus the duration of the high level of said clock signal.

3. A circuit protected against timing errors and parasitic disturbances, the circuit comprising:
a combinatory logic circuit having at least one input and one output;
at least a first sampling element having its output connected to said at least one input and activated by the rising edge of a clock signal;
at least a second sampling element having its input connected to said at least one output and activated by the rising edge of said clock signal;
at least a third sampling element having its input connected to the input of said at least first sampling element and activated by the falling edge of said clock signal;
at least a fourth sampling element having its input connected to the input of said at least second sampling element and activated by the falling edge of said clock signal;
a comparator circuit for comparing the outputs of each pair of said first and said second sampling elements and the outputs of each pair of said second and said fourth sampling elements and providing on its output an error detection signal, the comparator circuit setting said error detection signal at predetermined value if the outputs of any pair of said first and said second sampling elements or the outputs of any pair of said second and said fourth sampling elements are different; and
at least a fifth sampling element having its input connected to the output of said comparator and activated by said clock signal delayed by a predetermined delay, say predetermined delay is shorter than: the duration of the high level of said clock signal, plus the minimum delay of said comparator for the transitions from the non error to the error state, plus the minimum delay of said third and said fourth sampling elements, minus the hold time of the fifth sampling
Whereby: the duration of the low level period of said clock signal is selected to be larger than a selected duration of detectable faults; the duration of the high level of said clock signal is larger than the largest delay of said combinatory logic circuit plus the propagation delay of a said first sampling element plus the setup time of a said fourth sampling element; and the minimum propagation delay of said combinatory logic circuit plus the minimum propagation delay of a said first sampling element is larger than the duration of the high level of said clock signal minus the said predetermined delay plus the hold time of the fourth sampling element plus the maximum delay of the comparator for the transitions from the non error to the error state

4. The circuit protected against timing errors and parasitic disturbances of claim 3, wherein: the minimum propagation delay of said combinatory logic circuit plus the minimum propagation delay of a said first sampling element is larger than the period of said clock signal, minus the said predetermined delay, plus the hold time+t_{FFh} of the sampling element, plus the setup time of the fifth sampling element, plus the maximum delay of the comparator for the transitions from the non error to the error state.
